(19) United States
(12) Patent Application Publication
(10) Pub. No.: US 2025/0109331 A1
(43) Pub. Date: Apr. 3, 2025

(54) ORGANIC ELECTRONIC ELEMENT COMPRISING COMPOUND FOR ORGANIC ELECTRONIC ELEMENT AND AN ELECTRONIC DEVICE THEREOF

(71) Applicant: DUK SAN NEOLUX CO., LTD., Cheonan-si (KR)

(72) Inventors: Hyung Dong LEE, Cheonan-si (KR); Hyeng Gun SONG, Cheonan-si (KR)

(73) Assignee: DUK SAN NEOLUX CO., LTD., Cheonan-si (KR)

(21) Appl. No.: 18/783,983

(22) Filed: Jul. 25, 2024

(30) Foreign Application Priority Data
Sep. 15, 2023 (KR) 10-2023-0123076

(51) Int. Cl. C09K 11/06; H10K 50/15; H10K 50/16; H10K 50/805; H10K 85/60

(52) U.S. Cl. CPC C09K 11/06; H10K 50/15; H10K 50/16; H10K 50/805; H10K 85/615; C09K 2211/1011; C09K 2211/1018

(57) ABSTRACT

Provided is an organic electronic element comprising a first electrode; a second electrode; and an emitting layer formed between the first electrode and the second electrode; and an electronic device comprising the organic electronic element, wherein the organic material layer comprises a compound represented by Formula 1 and a compound represented by Formula 2, thereby lowering the driving voltage of the organic electronic element and improving luminous efficiency and lifespan

### BACKGROUND

### Technical Field

The present invention relates to organic electronic elements using compounds for organic electronic elements, and an electronic device thereof.

### Background Art

In general, organic light emitting phenomenon refers to a phenomenon that converts electric energy into light energy by using an organic material. An organic electronic element using an organic light emitting phenomenon usually has a structure including an anode, a cathode, and an organic material layer interposed therebetween. Here, in order to increase the efficiency and stability of the organic electronic element, the organic material layer is often composed of a multi-layered structure composed of different materials, and for example, may include a hole injection layer, a hole transport layer, an emitting layer, an electron transport layer, an electron injection layer etc.

A material used as an organic material layer in an organic electronic element may be classified into a light emitting material and a charge transport material, such as a hole injection material, a hole transport material, an electron transport material, an electron injection material etc. depending on its function.

The most problematic issues with organic electroluminescent devices are lifespan and efficiency, and as displays become larger in area, these efficiency and lifespan issues must be resolved. Efficiency, lifespan and driving voltage are related to each other, and when the efficiency is increased, the driving voltage is relatively decreased, and as the driving voltage is decreased, crystallization of organic materials due to Joule heating generated during driving decreases, and consequently, the lifespan tends to increase.

However, the efficiency cannot be maximized simply by improving the organic material layer. This is because, when the energy level and T1 value between each organic material layer, and the intrinsic properties (mobility, interfacial properties, etc.) of materials are optimally combined, long lifespan and high efficiency can be achieved at the same time.

Further, recently, in organic electroluminescent devices, in order to solve the emission problem in the hole transport layer, an emitting-auxiliary layer must be present between the hole transport layer and an emitting layer, and it is necessary to develop different emitting-auxiliary layers according to each of the emitting layers (R, G, B).

In general, electrons are transferred from the electron transport layer to the emitting layer, and holes are transferred from the hole transport layer to the emitting layer to generate excitons by recombination.

However, the material used for the hole transport layer has a low HOMO value and therefore has mostly low T1 value, therefore the exciton generated in the emitting layer is transferred to the hole transport layer, resulting in charge unbalance in the emitting layer, and light is emitted at the interface of the hole transport layer.

When light is emitted at the interface of the hole transport layer, the color purity and efficiency of the organic electronic element are lowered and the life span is shortened. Therefore, it is urgently required to develop an emitting-auxiliary layer having a high T1 value and a HOMO level between the HOMO energy level of the hole transport layer and the HOMO energy level of the emitting layer.

Meanwhile, it is necessary to develop a hole injection layer material having stable characteristics, that is, a high glass transition temperature, against Joule heating generated when the device is driven, while delaying penetration of the metal oxide from the anode electrode (ITO), which is one of the causes of shortening the lifespan of the organic electronic element, into the organic layer. The low glass transition temperature of the hole transport layer material has a characteristic that when the device is driven, the uniformity of the surface of the thin film is lowered, which has been reported to have a great influence on the lifespan of the device. In addition, OLED devices are mainly formed by a deposition method, and it is necessary to develop a material that can withstand long time in deposition, that is, a material having high heat resistance characteristics.

That is, in order to sufficiently exhibit the excellent characteristics of the organic electronic element, a material for forming an organic material layer in an element such as a hole injection material, a hole transport material, a light emitting material, an electron transport material, an electron injection material, an emitting-auxiliary layer material should be supported by stable and efficient materials. However, such a stable and efficient organic material layer material for an organic electronic element has not been sufficiently developed yet. Therefore, development of new materials is continuously required.

Therefore, the development of new materials continues to be required, and in particular, the development of materials for the emitting-auxiliary layer is urgently required.

### PRIOR ART LITERATURE

### [Patent Document]

(patent document 1) Korean document 10-2023-0014596 A
(patent document 2) Korean document 10-2023-0113120 A
(patent document 3) Korean document 10-2023-0112776 A
(patent document 4) Korean document 10-2428232 B
(patent document 5) Korean document 10-2428237 B

### DETAILED DESCRIPTION OF THE INVENTION

### Summary

The purpose of the present invention is to provide an organic electronic element comprising a compound that can lower the driving voltage of the element and improve the luminous efficiency, color purity, stability, and lifespan of the element, and electronic device thereof

### Technical Solution

In one aspect, the present invention provides an organic electronic element comprising a first electrode; a second electrode; and an organic material layer comprising an emitting layer formed between the first electrode and the second electrode, wherein the organic material layer comprises a hole transport layer formed between the first electrode and the emitting layer, and comprises a plurality of emitting-auxiliary layers formed between the hole transport layer and the emitting layer, wherein the plurality of emitting-auxiliary layers comprise a first emitting-auxiliary layer and a second emitting-auxiliary layer, wherein the first emitting-auxiliary layer is adjacent to the hole transport layer, wherein the second emitting-auxiliary layer is adjacent to the emitting layer, wherein the first emitting-auxiliary layer comprises a compound represented by Formula (1), and the second emitting-auxiliary layer comprises a compound represented by Formula (2).

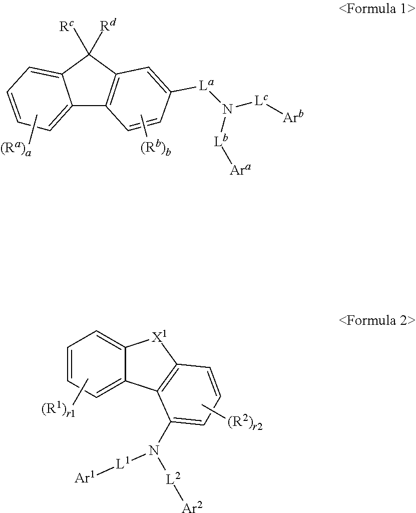

### Effects of the Invention

By using the compound according to the present invention, it is possible to achieve a high luminous efficiency, a low driving voltage, and a high heat resistance of the element, and can greatly improve the color purity and lifespan of the element.

### BRIEF DESCRIPTION OF THE DRAWINGS

FIG. 1 to FIG. 3 illustrate an example of an organic electronic element according to the present invention.

### DESCRIPTION OF THE NUMERALS

100, 200, 300: organic electronic element
110: the first electrode
120: hole injection layer
130: hole transport layer
140: emitting layer
150: electron transport layer
160: electron injection layer
170: second electrode
180: light efficiency enhancing Layer
210: buffer layer
220: emitting auxiliary layer
320: first hole injection layer
330: first hole transport layer
340: first emitting layer
350: first electron transport layer
360: first charge generation layer
361: second charge generation layer
420: second hole injection layer
430: second hole transport layer
440: second emitting layer
450: second electron transport layer
CGL: charge generation layer
ST1: first stack
ST2: second stack

### DETAILED DESCRIPTION

Hereinafter, some embodiments of the present invention will be described in detail. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). It should be noted that if a component is described as being “connected”, “coupled”, or “connected” to another component, the component may be directly connected or connected to the other component, but another component may be “connected”, “coupled” or “connected” between each component.

As used in the specification and the accompanying claims, unless otherwise stated, the following is the meaning of the term as follows.

Unless otherwise stated, the term “halo” or “halogen”, as used herein, includes fluorine (F), bromine (Br), chlorine (Cl), or iodine (I).

Unless otherwise stated, the term “alkyl” or “alkyl group”, as used herein, has a single bond of 1 to 60 carbon atoms, and means saturated aliphatic functional radicals including a linear alkyl group, a branched chain alkyl group, a cycloalkyl group (alicyclic), an cycloalkyl group substituted with a alkyl or an alkyl group substituted with a cycloalkyl.

Unless otherwise stated, the term “alkenyl” or “alkynyl”, as used herein, has double or triple bonds of 2 to 60 carbon atoms, but is not limited thereto, and includes a linear or a branched chain group.

Unless otherwise stated, the term “cycloalkyl”, as used herein, means alkyl forming a ring having 3 to 60 carbon atoms, but is not limited thereto.

Unless otherwise stated, the term “alkoxyl group”, “alkoxy group” or “alkyloxy group”, as used herein, means an oxygen radical attached to an alkyl group, but is not limited thereto, and has 1 to 60 carbon atoms.

Unless otherwise stated, the term “aryloxyl group” or “aryloxy group”, as used herein, means an oxygen radical attached to an aryl group, but is not limited thereto, and has 6 to 60 carbon atoms.

Unless otherwise stated, the term “aryl group” or “arylene group”, as used herein, has 6 to 60 carbon atoms, but is not limited thereto. Herein, the aryl group or arylene group means a monocyclic and polycyclic aromatic group, and may also be formed in conjunction with an adjacent group. Examples of “aryl group” may include a phenyl group, a biphenyl group, a fluorene group, or a spirofluorene group.

The prefix “aryl” or “ar” means a radical substituted with an aryl group. For example, an arylalkyl may be an alkyl substituted with an aryl, and an arylalkenyl may be an alkenyl substituted with aryl, and a radical substituted with an aryl has a number of carbon atoms as defined herein.

Also, when prefixes are named subsequently, it means that substituents are listed in the order described first. For example, an arylalkoxy means an alkoxy substituted with an aryl, an alkoxylcarbonyl means a carbonyl substituted with an alkoxyl, and an arylcarbonylalkenyl also means an alkenyl substituted with an arylcarbonyl, wherein the arylcarbonyl may be a carbonyl substituted with an aryl.

Unless otherwise stated, the term “heterocyclic group”, as used herein, contains one or more heteroatoms, but is not limited thereto, has 2 to 60 carbon atoms, includes any one of monocyclic and polycyclic rings, and may include heteroaliphatic ring and/or heteroaromatic ring. Also, the heterocyclic group may also be formed in conjunction with an adjacent group.

Unless otherwise stated, the term “heteroatom”, as used herein, represents at least one of N, O, S, P, or Si.

Also, the term “heterocyclic group” may include a ring including SO₂ instead of carbon consisting of cycle. For example, “heterocyclic group” includes compound below.

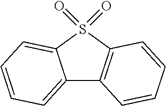 [SMILES: O=S1(=O)c2ccccc2-c2ccccc21]

Unless otherwise stated, the term “fluorenyl group” or “fluorenylene group”, as used herein, means a monovalent or divalent functional group, in which R, R′ and R″ are all hydrogen in the following structures, and the term “substituted fluorenyl group” or “substituted fluorenylene group” means that at least one of the substituents R, R′, R″ is a substituent other than hydrogen, and include those in which R and R′ are bonded to each other to form a spiro compound together with the carbon to which they are bonded.

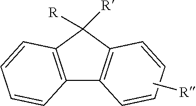

The term “spiro compound”, as used herein, has a ‘spiro union’, and a spiro union means a connection in which two rings share only one atom. At this time, atoms shared in the two rings are called ‘spiro atoms’, and these compounds are called ‘monospiro-’, ‘di-spiro-’ and ‘tri-spiro-’, respectively, depending on the number of atoms in a compound.

Unless otherwise stated, the term “aliphatic”, as used herein, means an aliphatic hydrocarbon having 1 to 60 carbon atoms, and the term “aliphatic ring”, as used herein, means an aliphatic hydrocarbon ring having 3 to 60 carbon atoms.

Unless otherwise stated, the term “ring”, as used herein, means an aliphatic ring having 3 to 60 carbon atoms, or an aromatic ring having 6 to 60 carbon atoms, or a hetero ring having 2 to 60 carbon atoms, or a fused ring formed by the combination of them, and includes a saturated or unsaturated ring.

Other hetero compounds or hetero radicals other than the above-mentioned hetero compounds include one or more heteroatoms, but are not limited thereto.

Unless otherwise stated, the term “substituted or unsubstituted”, as used herein, means that substitution is substituted by at least one substituent selected from the group consisting of deuterium, halogen, an amino group, a nitrile group, a nitro group, a C₁-C₂₀ alkyl group, a C₁-C₂₀ alkoxyl group, a C₁-C₂₀ alkylamine group, a C₁-C₂₀ alkylthiophen group, a C₆-C₂₀ arylthiophen group, a C₂-C₂₀ alkenyl group, a C₂-C₂₀ alkynyl group, a C₃-C₂₀ cycloalkyl group, a C₆-C₂₀ aryl group, a C₆-C₂₀ aryl group substituted by deuterium, a C₈-C₂₀ arylalkenyl group, a silane group, a boron group, a germanium group, and a C₂-C₂₀ heterocyclic group, but is not limited thereto.

Unless otherwise expressly stated, the Formula used in the present invention, as used herein, is applied in the same manner as the substituent definition according to the definition of the exponent of the following Formula:

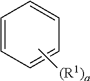

wherein, when a is an integer of 0, the substituent R¹ is absent, when a is an integer of 1, the sole substituent R¹ is linked to any one of the carbon constituting the benzene ring, when a is an integer of 2 or 3, each substituent R¹s may be the same and different, when a is an integer of 4 to 6, and is linked to the benzene ring in a similar manner, whereas the indication of hydrogen bound to the carbon forming the benzene ring is omitted.

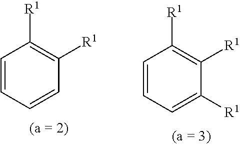

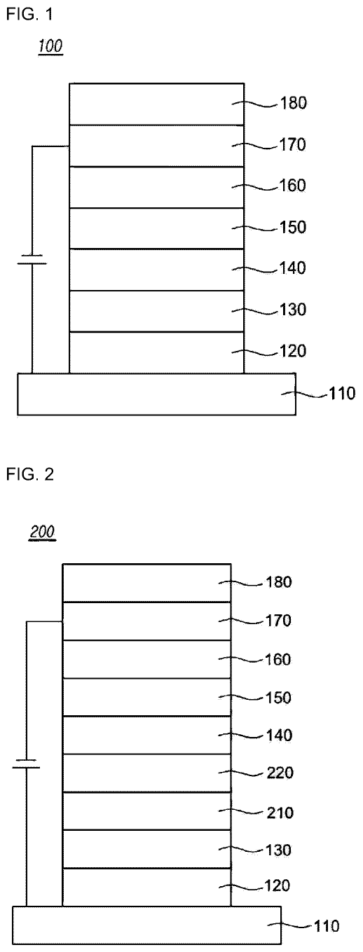

Hereinafter, the layered structure of an organic electronic element comprising the compound of the present invention will be described with reference to FIGS. 1 to 3.

When adding reference numerals to components in each drawing, it should be noted that identical components are given the same reference numerals as much as possible even if they are shown in different drawings. Additionally, in describing the present invention, if it is determined that a detailed description of a related known configuration or function may obscure the gist of the present invention, the detailed description will be omitted.

FIGS. 1 to 3 are exemplary diagrams of organic electronic elements according to embodiments of the present invention.

Referring to FIG. 1, the organic electric element (100) according to the present invention comprises a first electrode (110) formed on a substrate (not shown), a second electrode (170), an organic material layer formed between the first electrode (110) and the second electrode (170).

Wherein, the first electrode (110) may be an anode (a positive electrode), and the second electrode (170) may be a cathode (a negative electrode), and in the case of an inverted organic electric element, the first electrode may be a cathode, and the second electrode may be an anode.

The organic material layer may comprise a hole injection layer (120), a hole transport layer (130), an emitting layer (140), an electron transport layer (150), and an electron injection layer (160). Specifically, the organic material layer may comprise a hole injection layer (120), a hole transport layer (130), an emitting layer (140), an electron transport layer (150), and an electron injection layer (160) formed in sequence on the first electrode (110).

Preferably, the light efficiency enhancing layer (180) may be formed on a surface of both surfaces of the first electrode (110) or the second electrode (120), the surface not in contact with the organic material layer, when the light efficiency enhancing layer (180) is formed, the light efficiency of the organic electronic element can be improved.

For example, the light efficiency enhancing layer (180) may be formed on the second electrode (170), and in the case of a top emission organic light emitting device, the light efficiency enhancing layer (180) is formed, thereby reducing optical energy loss due to surface plasmon polaritons (SPPs) in the second electrode (170), and in the case of a bottom emission organic light emitting device, the light efficiency enhancing layer (180) may function as a buffer for the second electrode (170).

A buffer layer (210) or an emitting auxiliary layer (220) may be further formed between the hole transport layer (130) and the emitting layer (140), which will be described with reference to FIG. 2.

Referring to FIG. 2, an organic electric device (200) according to another embodiment of the present invention includes a hole injection layer (120), a hole transport layer (130), a buffer layer (210), an emitting auxiliary layer (220), an emitting layer (140), an electron transport layer (150), an electron injection layer (160), a second electrode (170), sequentially formed on the first electrode (110), and a light efficiency enhancing layer (180) formed on the second electrode.

Although not shown in FIG. 2, an electron transport auxiliary layer may be further formed between the emitting layer (140) and the electron transport layer (150).

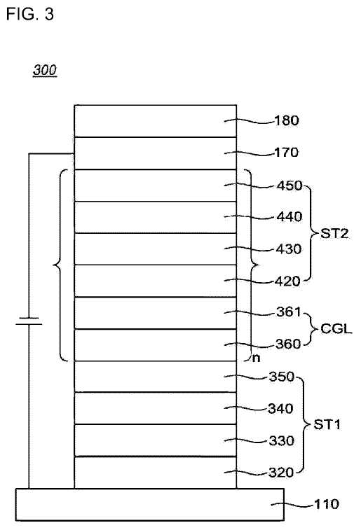

Also, according to another embodiment of the present invention, the organic material layer may have a plurality of stacks comprising a hole transport layer, an emitting layer and an electron transport layer. This will be described with reference to FIG. 3.

Referring to FIG. 3, in the organic electronic element (300) according to another embodiment of the present invention, 2 or more sets of stacks (ST1 and ST2) made of a multi-layered organic material layer may be formed between the first electrode (110) and the second electrode (170), and a charge generation layer (CGL) may be formed between the stacks of organic material layers.

Specifically, the organic electronic element according to an embodiment of the present invention may include a first electrode (110), a first stack (ST1), a charge generation layer (CGL), a second stack (ST2), and a second electrode (170) and a light efficiency enhancing layer (180).

The first stack (ST1) is an organic material layer formed on the first electrode (110) and may include a first hole injection layer (320), a first hole transport layer (330), a first emitting layer (340) and a first electron transport layer (350), and the second stack (ST2) may include a second hole injection layer (420), a second hole transport layer (430), a second emitting layer (440) and a second electron transport layer (450). Like this, the first stack and the second stack may be organic material layers having the same laminated structure, but may be organic material layers having different laminated structures.

A charge generation layer (CGL) may be formed between the first stack (ST1) and the second stack (ST2). The charge generation layer (CGL) may include a first charge generation layer (360) and a second charge generation layer (361). The charge generation layer (CGL) is formed between the first emitting layer (340) and the second emitting layer (440) to increase the current efficiency generated in each emitting layer and smoothly distribute charge.

When a plurality of emitting layers are formed by the multilayer stack structure method as shown in FIG. 3, an organic electronic element that emits white light by a mixing effect of light emitted from each emitting layer can be manufactured, as well as an organic electronic element that emits light of various colors.

The compounds represented by Formula 1 and Formula 2 of the present invention may be used as a material for a hole injection layer (120, 320, 420), a hole transport layer (130, 330, 430), a buffer layer (210), an emitting auxiliary layer (220), and an electron transport layer (150, 350, 450), the electron injection layer (160), the emitting layer (140, 340, 440), or the light efficiency enhancing layer (180), but preferably a compound represented by Formula 1 or Formula 2 of the present invention can be used as the emitting auxiliary layer (220).

Even if the same or similar core is used, the band gap, the electrical characteristics, the interface characteristics, and the like may vary depending on which substituent is bonded at which position, therefore it is necessary to study the selection of the core and the combination of sub-substituents bonded thereto, and in particular, when the optimal combination of energy levels and T1 values of each organic material layer and unique properties of materials (mobility, interfacial characteristics, etc.) is achieved, a long lifespan and high efficiency can be achieved at the same time.

The organic light emitting device according to an embodiment of the present invention may be manufactured using various deposition methods. It can be manufactured using a vapor deposition method such as PVD or CVD. For example, an anode (110) is formed by depositing a metal or a conductive metal oxide or an alloy thereof on a substrate, and after forming an organic material layer including the hole injection layer (120), the hole transport layer (130), the emitting layer (140), the electron transport layer (150) and the electron injection layer (160) thereon, the organic electroluminescent device according to an embodiment of the present invention can be manufactured by depositing a material that can be used as a cathode (170) thereon. Also, an emitting auxiliary layer (220) may be further formed between the hole transport layer (130) and the emitting layer (140), and an electron transport auxiliary layer (not shown) may be further formed between the emitting layer (140) and the electron transport layer (150), and as described above, may be formed in a stack structure.

Also, the organic material layer may be manufactured with a smaller number of layers by using various polymer materials and not by a deposition method, but by a solution process or a solvent process, such as a spin coating process, a nozzle printing process, an inkjet printing process, a slot coating process, a dip coating process or a roll-to-roll process, doctor blading process, screen printing process, or a thermal transfer method, etc. Since the organic material layer according to the present invention can be formed by various methods, the scope of the present invention is not limited by the forming method.

Additionally, the organic electronic element according to an embodiment of the present invention may be selected from the group consisting of an organic electroluminescent device, an organic solar cell, an organic photoreceptor, an organic transistor, a monochromatic lighting device, and a quantum dot display device.

Another embodiment of the present invention may comprise an electronic device comprising a display device including the organic electronic element of the present invention; and a control unit for driving the display device. At this time, the electronic device may be a current or future wired/wireless communication terminal, and covers all kinds of electronic devices including a mobile communication terminal such as a cellular phone, a personal digital assistant (PDA), an electronic dictionary, a point-to-multipoint (PMP), a remote controller, a navigation unit, a game player, various kinds of TVs, and various kinds of computers.

Hereinafter, an organic electronic element according to an aspect of the present invention will be described.

An organic electronic element according to an embodiment of the present invention comprises a first electrode; a second electrode; and an organic material layer formed between the first electrode and the second electrode; wherein the organic material layer comprises a hole transport layer formed between the first electrode and the emitting layer, and comprises a plurality of emitting-auxiliary layers formed between the hole transport layer and the emitting layer, wherein the plurality of emitting-auxiliary layers comprise a first emitting-auxiliary layer and a second emitting-auxiliary layer, wherein the first emitting-auxiliary layer is adjacent to the hole transport layer, wherein the second emitting-auxiliary layer is adjacent to the emitting layer, wherein the first emitting-auxiliary layer comprises a compound represented by Formula 1, and the second emitting-auxiliary layer comprises a compound represented by Formula 2:

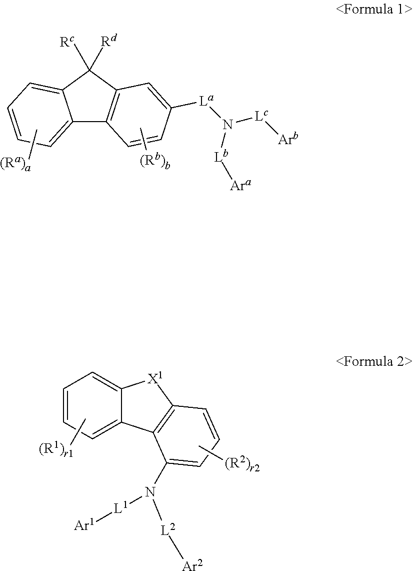

In Formula (1) and Formula (2), each symbol may be defined as follows:
R^{a}, R^{b}, R¹ and R² are each independently the same or different, and each independently selected from the group consisting of a hydrogen; deuterium; an C₆-C₆₀ aryl group; fluorenyl group; a C₂-C₆₀ heterocyclic group including at least one heteroatom of O, N, S, Si or P; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group; or an adjacent plurality of R^{a} and a plurality of R^{b} can be bonded to each other to form a ring,
Wherein when R^{a}, R^{b}, R¹ and R² are an aryl group, preferably a C₆-C₃₀ aryl group, more preferably a C₆-C₂₅ aryl group, a C₆-C₂₀ aryl group, a C₆-C₁₈ aryl group, C₆-C₁₆ aryl group, C₆-C₁₄ aryl group, C₆-C₁₂ aryl group, C₆-C₁₀ aryl group, C₆ aryl group, for example, it may be phenyl, biphenyl, terphenyl, naphthalene, phenanthrene, etc,
Wherein when R^{a}, R^{b}, R¹ and R² are a heterocyclic group, preferably a C₂˜C₃₀ heterocyclic group, more preferably a C₂˜C₂₄ heterocyclic group, a C₂˜C₂₀ heterocyclic group, C₂˜C₁₈ heterocyclic group, C₂˜C₁₆ heterocyclic group, C₂˜C₁₂ heterocyclic group, C₁₂ heterocyclic group, for example, pyrazine, thiophene, pyridine, pyrimidoindole, 5-phenyl-5H-pyrimido[5,4-b]indole, quinazoline, benzoquinazoline, dibenzoquinazoline, dibenzofuran, dibenzothiophene, naphthobenzofuran, naphthobenzothiophene, benzothienopyrimidine, benzofuropyrimidine, phenothiazine, phenylphenothiazine, etc.,
Wherein when R^{a}, R^{b}, R¹ and R² are a fused ring group, preferably a fused ring group of a C₃-C₃₀ aliphatic ring and a C₆-C₃₀ aromatic ring, more preferably a fused ring group of a C₃-C₂₄ aliphatic ring and a C₆-C₂₄ aromatic ring.
Wherein when R^{a}, R^{b}, R¹ and R² are an alkyl group, preferably a C₁-C₃₀ alkyl group, more preferably a C₁-C₂₄ alkyl group, a C₁-C₁₀ alkyl group, a C₁-C₄ alkyl group, for example, methyl, ethyl, i-propyl, t-butyl, etc.
Wherein when R^{a}, R^{b}, R¹ and R² are alkoxyl groups, preferably C₁˜C₂₄ alkoxyl groups, more preferably a C₁-C₁₀ alkoxyl group, a C₁-C₄ alkoxyl group group, for example, methoxyl, ethoxyl, i-propoxyl, t-butoxyl, etc.
Wherein when R^{a}, R^{b}, R¹ and R² are an aryloxy group, preferably an C₆˜C₂₄ aryloxy group, more preferably a C₆-C₁₈ aryloxy group, C₆-C₁₆ aryloxy group, C₆-C₁₄ aryloxy group, C₆-C₁₂ aryloxy group, C₆-C₁₀ aryloxy group, C₆ aryloxy group
R^{c} and R^{d} are each independently selected from the group consisting of an C₆-C₆₀ aryl group; fluorenyl group; a C₂-C₆₀ heterocyclic group including at least one heteroatom of O, N, S, Si or P; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group; alternatively, R^{c} and R^{d} can be bonded to each other to form a spiro ring,
Wherein when R^{c} and R^{d} are an aryl group, preferably a C₆-C₃₀ aryl group, more preferably a C₆-C₂₅ aryl group, C₆-C₂₀ aryl group, a C₆-C₁₈ aryl group, C₆-C₁₆ aryl group, C₆-C₁₄ aryl group, C₆-C₁₂ aryl group, C₆-C₁₀ aryl group, C₆ aryl group, for example, phenyl, biphenyl, terphenyl, naphthalene, phenanthrene, etc,
Wherein when R^{c} and R^{d} are a heterocyclic group, preferably a C₂˜C₃₀ heterocyclic group, more preferably a C₂˜C₂₄ heterocyclic group, a C₂˜C₂₀ heterocyclic group, C₂˜C₁₈ heterocyclic group, C₂˜C₁₆ heterocyclic group, C₂˜C₁₂ heterocyclic group, C₁₂ heterocyclic group, for example, pyrazine, thiophene, pyridine, pyrimidoindole, 5-phenyl-5H-pyrimido[5,4-b]indole, quinazoline, benzoquinazoline, dibenzoquinazoline, dibenzofuran, dibenzothiophene, naphthobenzofuran, naphthobenzothiophene, benzothienopyrimidine, benzofuropyrimidine, phenothiazine, phenylphenothiazine, etc.,
Wherein when R^{c} and R^{d} are a fused ring group, preferably a fused ring group of a C₃-C₃₀ aliphatic ring and a C₆-C₃₀ aromatic ring, more preferably a fused ring group of a C₃-C₂₄ aliphatic ring and a C₆-C₂₄ aromatic ring.
Wherein when R^{c} and R^{d} are an alkyl group, preferably a C₁-C₃₀ alkyl group, more preferably a C₁-C₂₄ alkyl group, a C₁-C₁₀ alkyl group, a C₁-C₄ alkyl group, for example, methyl, ethyl, i-propyl, t-butyl.
Wherein when R^{c} and R^{d} are alkoxyl groups, preferably C₁˜C₂₄ alkoxyl groups.
Wherein when R^{c} and R^{d} are an aryloxy group, preferably an C₆˜C₂₄ aryloxy group.
L^{a}, L^{b}, L^{c}, L¹ and L² are each independently selected from the group consisting of a single bond; a C₆-C₆₀ arylene group; fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
Wherein when L^{a}, L^{b}, L^{c}, L¹ and L² are an arylene group, preferably a C₆-C₃₀ arylene group, more preferably a C₆-C₂₅ arylene group, C₆-C₂₀ arylene group, a C₆-C₁₈ arylene group, C₆-C₁₆ arylene group, C₆-C₁₄ arylene group, C₆-C₁₂ arylene group, C₆-C₁₀ arylene group, C₆ arylene group, for example, phenylene, biphenylene, naphthylene, terphenylene, anthracenylene, etc.
Wherein when L^{a}, L^{b}, L^{c}, L¹ and L² are a heterocyclic group, preferably a C₂˜C₃₀ heterocyclic group, more preferably a C₂˜C₂₄ heterocyclic group, a C₂˜C₂₀ heterocyclic group, C₂˜C₁₈ heterocyclic group, C₂˜C₁₆ heterocyclic group, C₂˜C₁₂ heterocyclic group, C₁₂ heterocyclic group, for example, pyridine, pyrimidine, quinoline, quinazoline, quinoxaline, dibenzofuran, dibenzothiophene, naphthobenzothiophene, naphthobenzofuran, benzofuran, benzothiophene, etc.
Wherein when L^{a}, L^{b}, L^{c}, L¹ and L² are a fused ring group, preferably a fused ring group of a C₃-C₃₀ aliphatic ring and a C₆-C₃₀ aromatic ring, more preferably a fused ring group of a C₃-C₂₄ aliphatic ring and a C₆-C₂₄ aromatic ring.
Ar^{a}, Ar^{b}, Ar¹ and Ar² are each independently selected from the group consisting of an C₆-C₆₀ aryl group; fluorenyl group; a C₂-C₆₀ heterocyclic group including at least one heteroatom of O, N, S, Si or P; a C₃-C₆₀ cycloalkyl group; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group;
Wherein when Ar^{a}, Ar^{b}, Ar¹ and Ar² are an aryl group, preferably a C₆-C₃₀ aryl group, more preferably a C₆-C₂₅ aryl group, C₆-C₂₀ aryl group, a C₆-C₁₈ aryl group, C₆-C₁₆ aryl group, C₆-C₁₄ aryl group, C₆-C₁₂ aryl group, C₆-C₁₀ aryl group, C₆ aryl group, for example, phenyl, biphenyl, terphenyl, naphthalene, phenanthrene, etc.
Wherein when Ar^{a}, Ar^{b}, Ar¹ and Ar² are a heterocyclic group, it may be preferably a C₂˜C₃₀ heterocyclic group, and more preferably a C₂˜C₂₄ heterocyclic group, a C₂˜C₂₀ heterocyclic group, C₂˜C₁₈ heterocyclic group, C₂˜C₁₆ heterocyclic group, C₂˜C₁₂ heterocyclic group, C₁₂ heterocyclic group, for example, pyrazine, thiophene, pyridine, pyrimidoindole, 5-phenyl-5H-pyrimido[5,4-b]indole, quinazoline, benzoquinazoline, dibenzoquinazoline, dibenzofuran, dibenzothiophene, naphthobenzofuran, naphthobenzothiophene, benzothienopyrimidine, benzofuropyrimidine, phenothiazine, phenylphenothiazine, etc.
Wherein when Ar^{a}, Ar^{b}, Ar¹ and Ar² are cycloalkyl groups, preferably C₃-C₃₀ cycloalkyl groups; more preferably a C₃-C₂₄ cycloalkyl group, a C₃-C₁₈ cycloalkyl group, a C₃-C₁₄ cycloalkyl group, a C₃-C₁₀ cycloalkyl group, a C₆-C₁₀ cycloalkyl group, for example, cyclohexyl, norbornyl, adamantly, etc.
Wherein when Ar^{a}, Ar^{b}, Ar¹ and Ar² are a fused ring group, preferably a fused ring group of a C₃-C₃₀ aliphatic ring and a C₆-C₃₀ aromatic ring, more preferably a fused ring group of a C₃-C₂₄ aliphatic ring and a C₆-C₂₄ aromatic ring.
Wherein when Ar^{a}, Ar^{b}, Ar¹ and Ar² are an alkyl group, preferably a C₁-C₃₀ alkyl group, and more preferably a C₁-C₂₄ alkyl group, a C₁-C₁₀ alkyl group, a C₁-C₄ alkyl group, for example, methyl, ethyl, i-propyl, t-butyl.
Wherein when Ar^{a}, Ar^{b}, Ar¹ and Ar² are alkoxyl groups, preferably C₁˜C₂₄ alkoxyl groups.
Wherein when Ar^{a}, Ar^{b}, Ar¹ and Ar² are an aryloxy group, preferably an C₆˜C₂₄ aryloxy group.
X¹ is O or S,
a and r1 are independently integers from 0 to 4, b and r2 are independently integers from 0 to 3,

However, r1+r2≥1,
wherein the aryl group, arylene group, heterocyclic group, fluorenyl group, fluorenylene group, cycloalkyl group, fused ring group, alkyl group, alkenyl group, alkynyl group, alkoxy group and aryloxy group may be substituted with one or more substituents selected from the group consisting of deuterium; halogen; silane group; siloxane group; boron group; germanium group; cyano group; nitro group; C₁-C₂₀ alkylthio group; C₁-C₂₀ alkoxyl group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; a fluorenyl group; C₂-C₂₀ heterocyclic group; C₃-C₂₀ cycloalkyl group; C₇-C₂₀ arylalkyl group; and C₈-C₂₀ arylalkenyl group; and additionally, the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

However, Formula 2 comprises at least one deuterium.

Also, Formula 1 is represented by any one of the following Formulas 1-1 to 1-4:

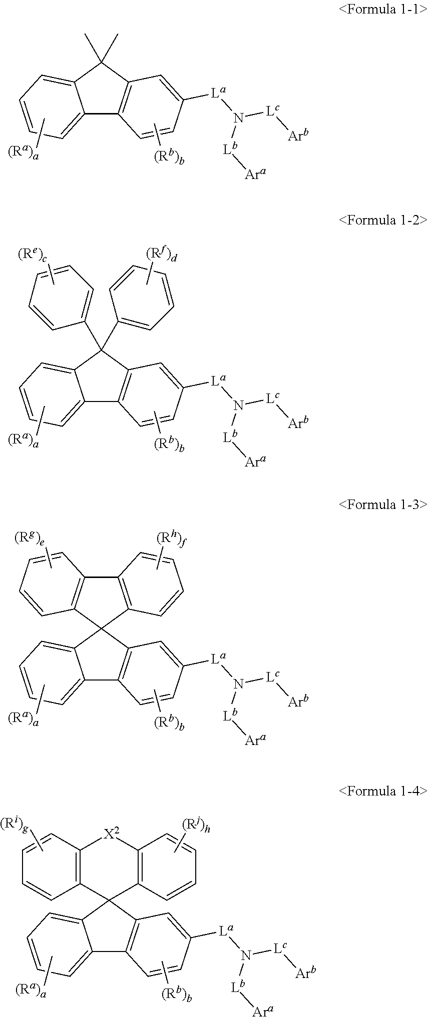

Wherein:
R^{a}, R^{b}, a, b, L^{a}, L^{b}, L^{c}, Ar^{a} and Ar^{b} are the same as defined above,
R^{e}, R^{f}, R^{g}, R^{h}, Rⁱ and R^{j} are the same as the definition of R^{a},
X² is O or S,
c and d are independently integers from 0 to 5, e, f, g and h are independently integers from 0 to 4.

At least one of Ar^{a} and Ar^{b} may be represented by Formula A-1.

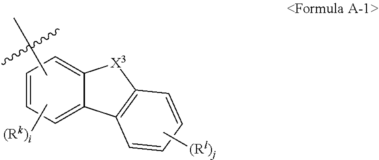

Wherein:
R^{k} and R^{l} are the same as the definition of R^{a}, or an adjacent plurality of R^{k} or a plurality of R^{l} can be bonded to each other to form a ring,
X³ is O, S or CR′R″,
Wherein R′ and R″ are the same as the definition of R^{c}, or R′ and R″ can be bonded to each other to form a spiro,
i is an integer from 0 to 3, j is an integer from 0 to 3.

Formula A-1 is represented by any one of the following Formulas A-1-1 to formula A-1-4.

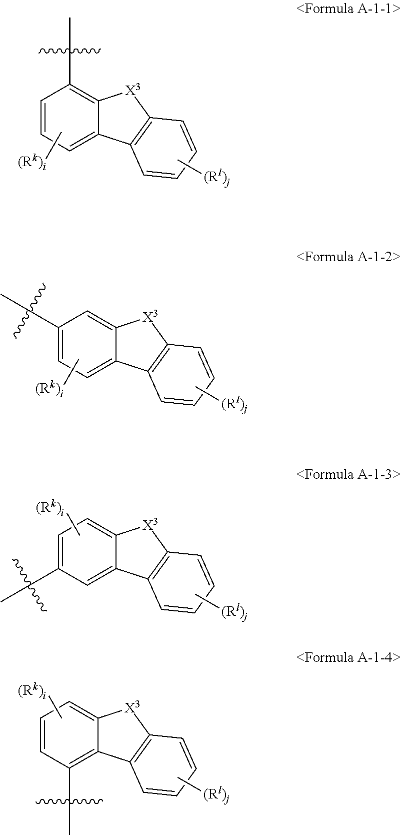

Wherein, X³, R^{k}, R^{l}, i and j are the same as defined in Formula A-1.

At least one of Ar¹ and Ar² is represented by the following Formula A-2 or Formula A-3.

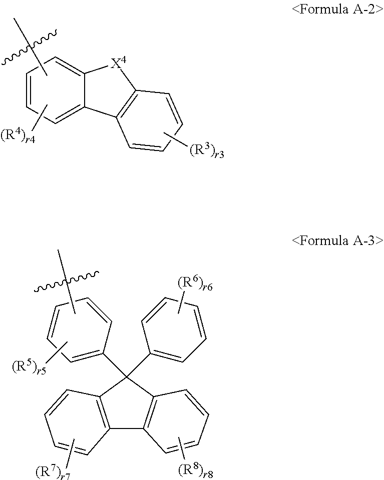

Wherein:
R³, R⁴, R⁵, R⁶, R⁷ and R⁸ are the same as the definition of R^{a}, alternatively, adjacent groups can be bonded to each other to form a ring,

However, when R⁵ and R⁶ combine with each other to form a ring, they are formed as a single bond,
X⁴ is O, S or CR′R″,
Wherein R′ and R″ are the same as the definition of R^{c}, or R′ and R″ can be bonded to each other by a single bond to form a spiro,
r3, r5, r7 and r8 are each independently an integer from 0 to 4, r4 is an integer from 0 to 3, r6 is an integer from 0 to 5.

However, when at least one of Ar¹ and Ar² is a compound represented by Formula A-2, the case where X⁴ is NR′ is preferably excluded.

However, it is preferable to exclude the case where at least one of Ar¹ and Ar² is represented by Formula A-4.

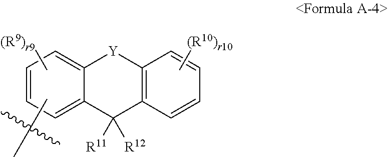

Wherein:
Y is O or S,
R⁹, R¹⁰, R¹¹ and R¹² are the same as the definition of R¹, or R¹¹ and R¹² can be bonded to each other to form a ring,
r9 is an integer from 0 to 3, r10 is an integer from 0 to 4.

Formula A-2 is represented by any one of the following formulas A-2-1 to formula A-2-4.

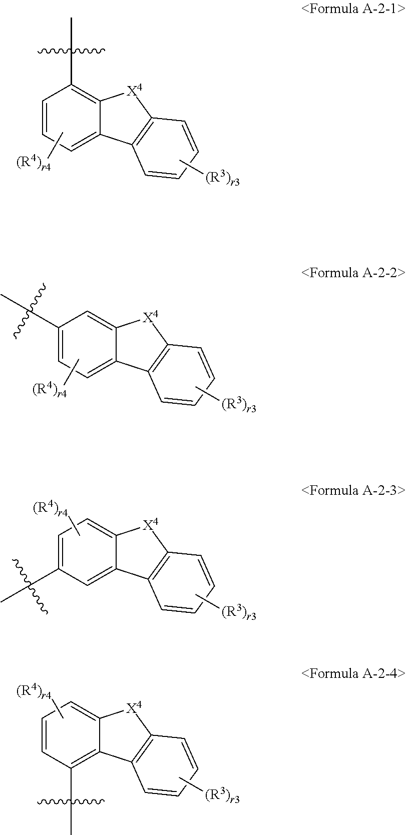

Wherein, X⁴, R³, R⁴, r3 and r4 are the same as defined in Formula A-2.

Formula A-3 is represented by the following formulas A-3-1 to formula A-3-3.

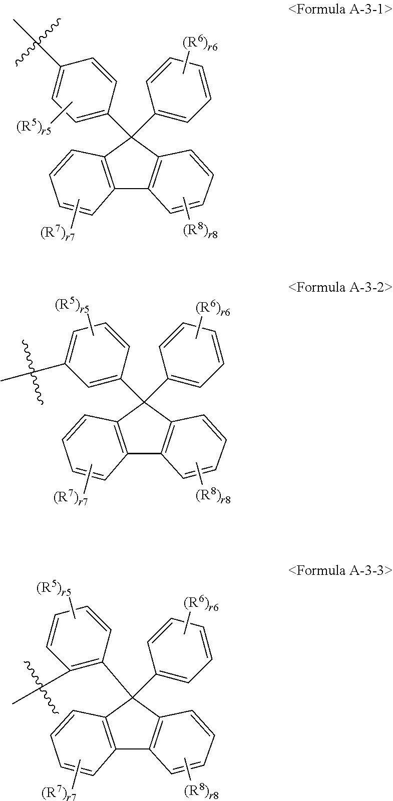

Wherein, R⁵, R⁶, R⁷, R⁸, r5, r6, r7 and r8 are the same as defined in Formula A-3.
L^{a}, L^{b}, L^{c}, L¹ and L² may be independently represented by a single bond or any one of the following formulas L-1 to L-4.

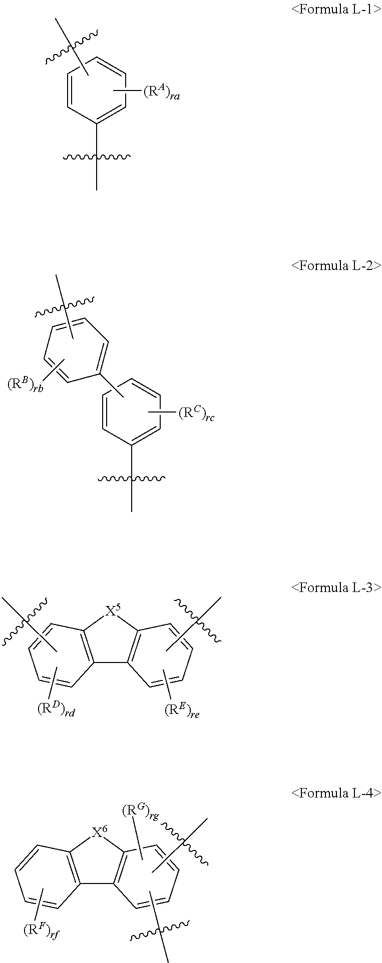

Wherein:
R^{A}, R^{B}, R^{C}, R^{D}, R^{E}, R^{F} and R^{G} are the same as the definition of R^{a}, alternatively, adjacent groups can be bonded to each other to form a ring,
X⁵ and X⁶ are each independently O or S,
ra, rb, rc and rf are each independently an integer from 0 to 4, rd and re are each independently an integer from 0 to 3, rg is an integer from 0 to 2.

Formula L-1 is represented by any one of the following formulas L-1-1 to formula L-1-3.

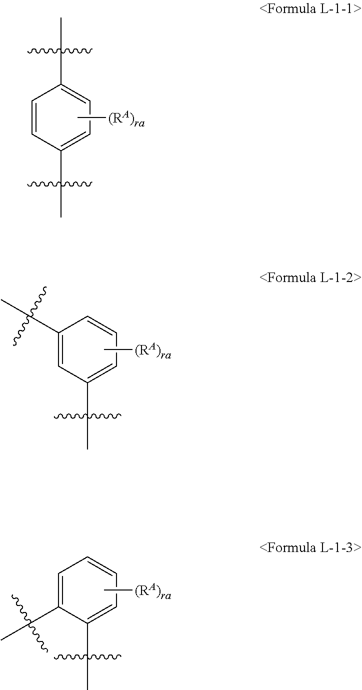

Wherein, R^{A} and ra are the same as defined in Formula L-1.

Formula L-2 is represented by any one of the following formulas L-2-1 to formula L-2-6.

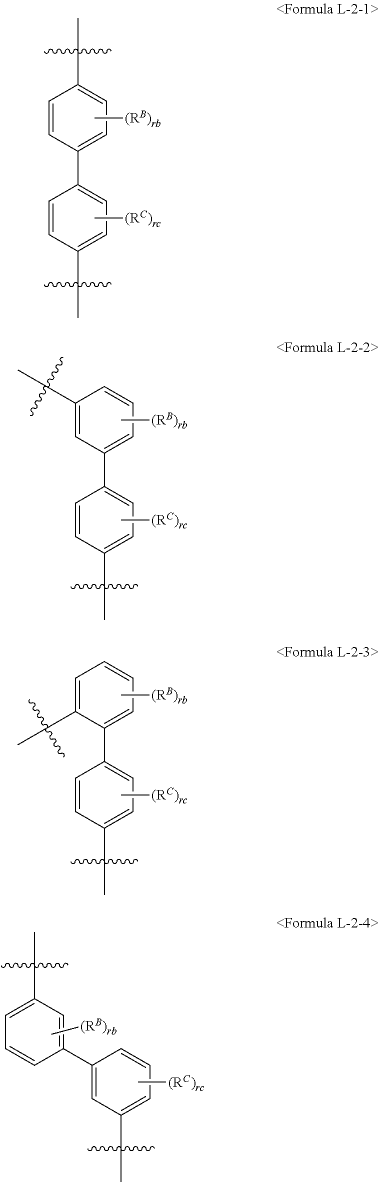

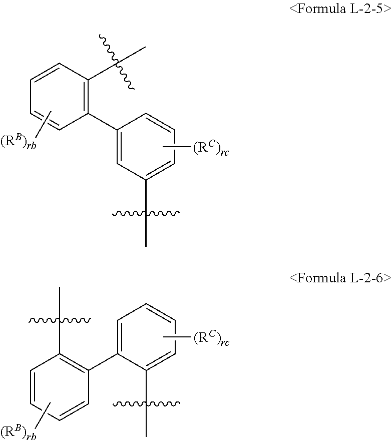

Wherein, R^{B}, R^{C}, rb and rc are the same as defined in Formula L-2.

Formula L-3 is represented by any one of the following formulas L-3-1 to formula L-3-9.

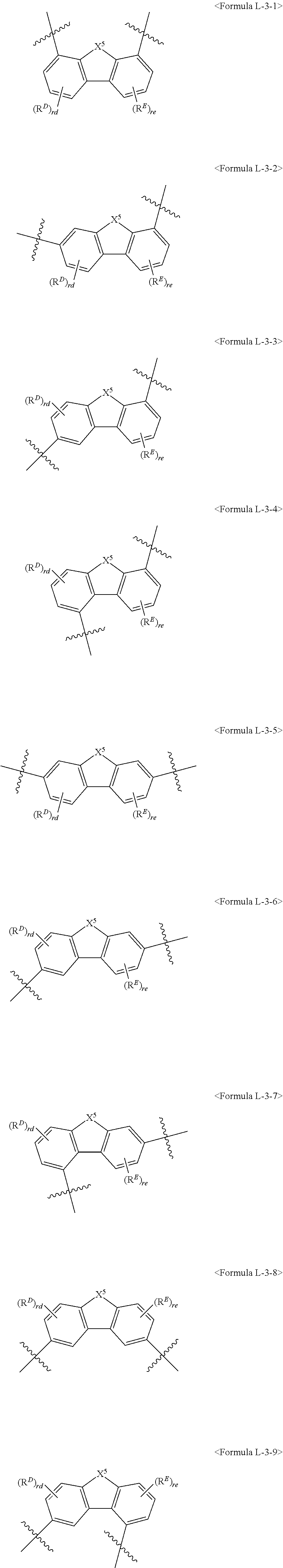

Wherein, X⁵, R^{D}, R^{E}, rd and re are the same as defined in Formula L-3.

Formula L-43 is represented by any one of the following formulas L-4-1 to formula L-4-3.

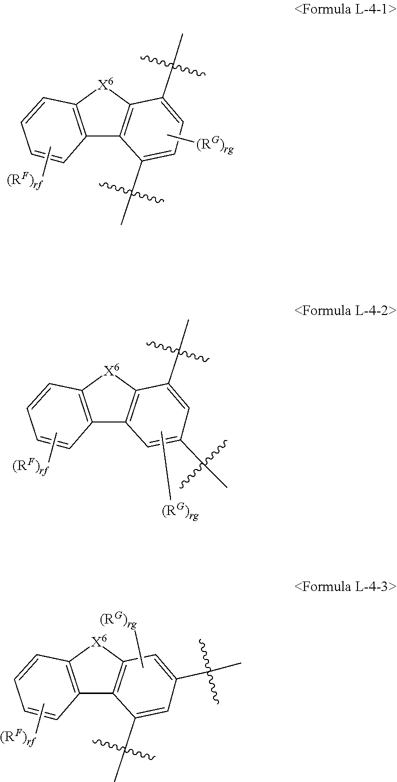

Wherein, X⁶, R^{F}, R^{G}, rf and rg are the same as defined in Formula L-4.

Also, the present invention provides an organic electronic element comprising a compound wherein at least one of R¹ and R² is deuterium; or a substituent comprising deuterium;

Specifically, the compound represented by Formula 1 may be any one of the following compounds, but is not limited thereto.

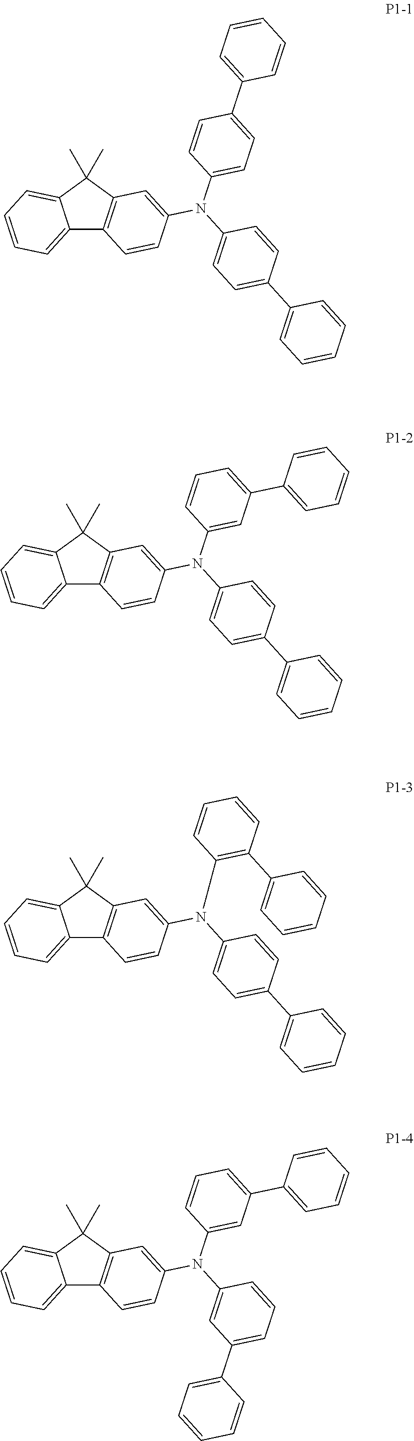 [SMILES: CC1(C)c2ccccc2-c2ccc(N(c3ccc(-c4ccccc4)cc3)c3ccc(-c4ccccc4)cc3)cc21 ; CC1(C)c2ccccc2-c2ccc(N(c3ccc(-c4ccccc4)cc3)c3cccc(-c4ccccc4)c3)cc21 ; CC1(C)c2ccccc2-c2ccc(N(c3ccc(-c4ccccc4)cc3)c3ccccc3-c3ccccc3)cc21 ; CC1(C)c2ccccc2-c2ccc(N(c3cccc(-c4ccccc4)c3)c3cccc(-c4ccccc4)c3)cc21]

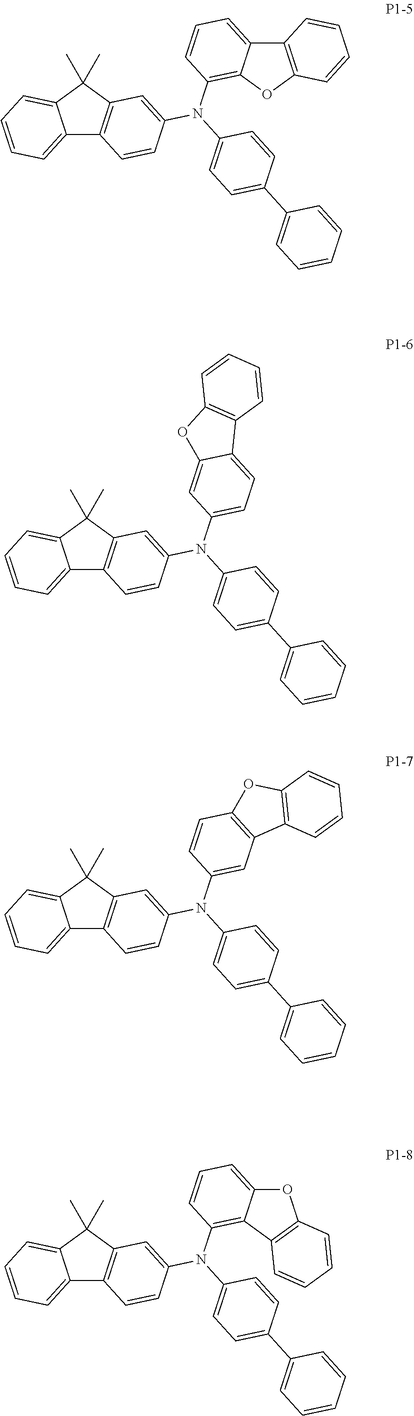 [SMILES: CC1(C)c2ccccc2-c2ccc(N(c3ccc(-c4ccccc4)cc3)c3cccc4c3oc3ccccc34)cc21 ; CC1(C)c2ccccc2-c2ccc(N(c3ccc(-c4ccccc4)cc3)c3ccc4c(c3)oc3ccccc34)cc21 ; CC1(C)c2ccccc2-c2ccc(N(c3ccc(-c4ccccc4)cc3)c3ccc4oc5ccccc5c4c3)cc21 ; CC1(C)c2ccccc2-c2ccc(N(c3ccc(-c4ccccc4)cc3)c3cccc4oc5ccccc5c34)cc21]

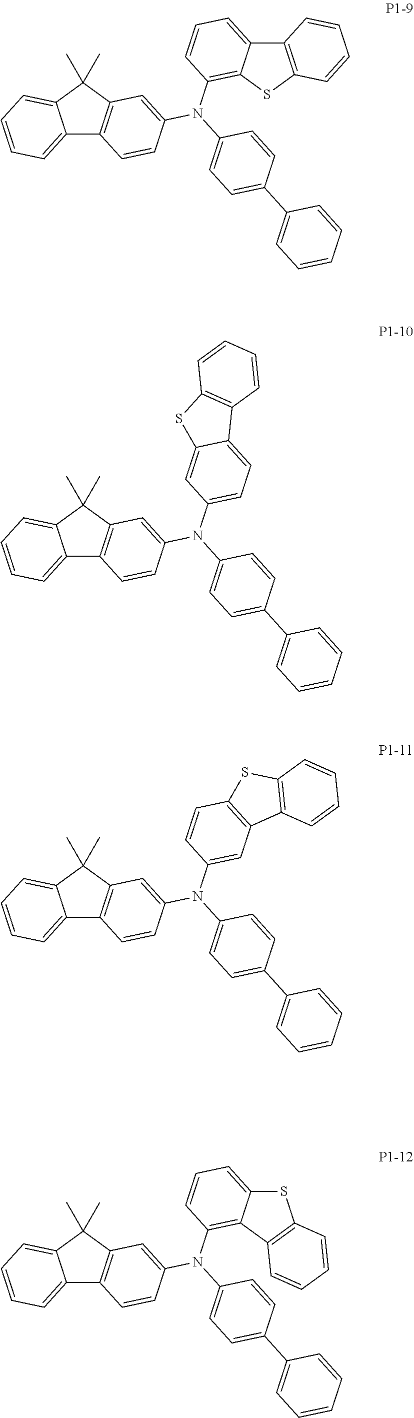 [SMILES: CC1(C)c2ccccc2-c2ccc(N(c3ccc(-c4ccccc4)cc3)c3cccc4c3sc3ccccc34)cc21 ; CC1(C)c2ccccc2-c2ccc(N(c3ccc(-c4ccccc4)cc3)c3ccc4c(c3)sc3ccccc34)cc21 ; CC1(C)c2ccccc2-c2ccc(N(c3ccc(-c4ccccc4)cc3)c3ccc4sc5ccccc5c4c3)cc21 ; CC1(C)c2ccccc2-c2ccc(N(c3ccc(-c4ccccc4)cc3)c3cccc4sc5ccccc5c34)cc21]

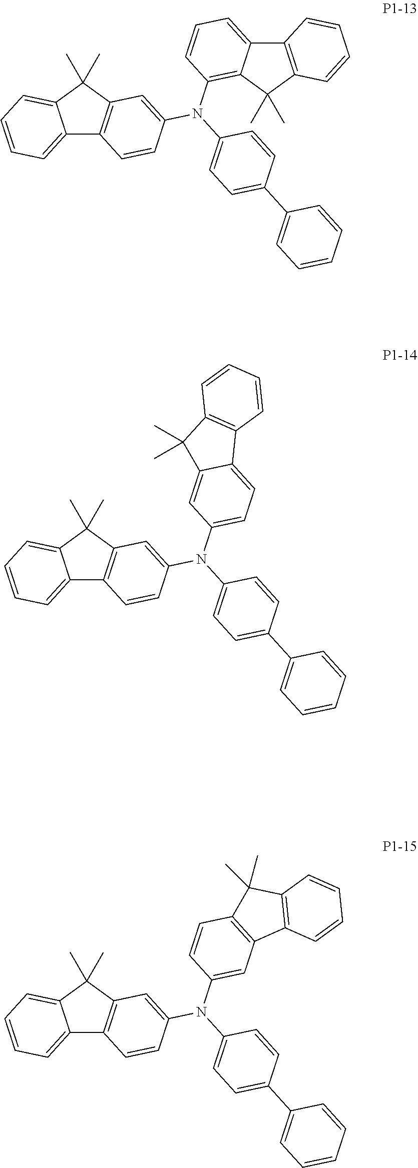 [SMILES: CC1(C)c2ccccc2-c2ccc(N(c3ccc(-c4ccccc4)cc3)c3cccc4c3C(C)(C)c3ccccc3-4)cc21 ; CC1(C)c2ccccc2-c2ccc(N(c3ccc(-c4ccccc4)cc3)c3ccc4c(c3)C(C)(C)c3ccccc3-4)cc21 ; CC1(C)c2ccccc2-c2cc(N(c3ccc(-c4ccccc4)cc3)c3ccc4c(c3)C(C)(C)c3ccccc3-4)ccc21]

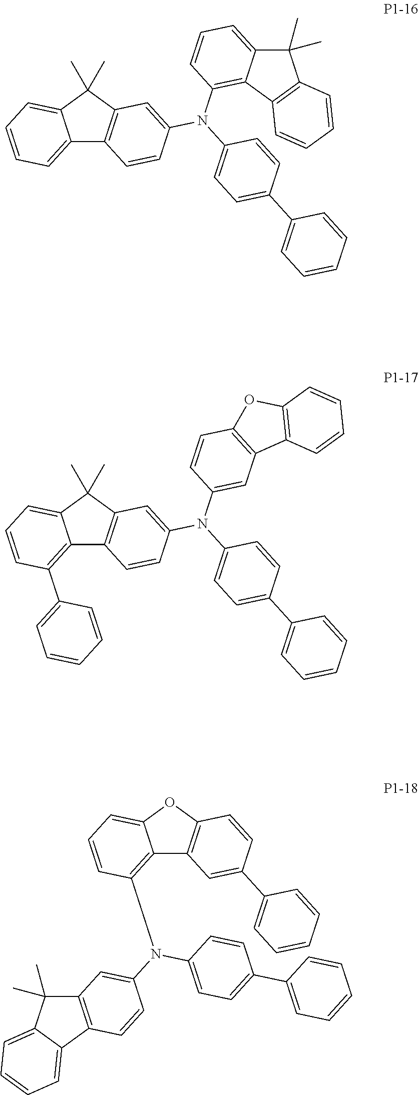 [SMILES: CC1(C)c2ccccc2-c2ccc(N(c3ccc(-c4ccccc4)cc3)c3cccc4c3-c3ccccc3C4(C)C)cc21 ; CC1(C)c2cc(N(c3ccc(-c4ccccc4)cc3)c3ccc4oc5ccccc5c4c3)ccc2-c2c(-c3ccccc3)cccc21 ; CC1(C)c2ccccc2-c2ccc(N(c3ccc(-c4ccccc4)cc3)c3cccc4oc5ccc(-c6ccccc6)cc5c34)cc21]

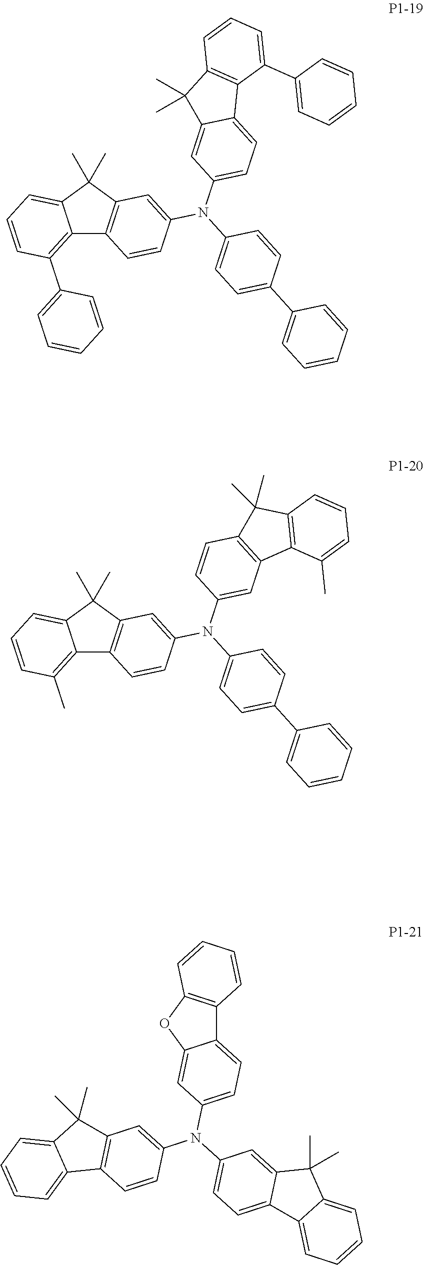 [SMILES: CC1(C)c2cc(N(c3ccc(-c4ccccc4)cc3)c3ccc4c(c3)C(C)(C)c3cccc(-c5ccccc5)c3-4)ccc2-c2c(-c3ccccc3)cccc21 ; Cc1cccc2c1-c1cc(N(c3ccc(-c4ccccc4)cc3)c3ccc4c(c3)C(C)(C)c3cccc(C)c3-4)ccc1C2(C)C ; CC1(C)c2ccccc2-c2ccc(N(c3ccc4c(c3)C(C)(C)c3ccccc3-4)c3ccc4c(c3)oc3ccccc34)cc21]

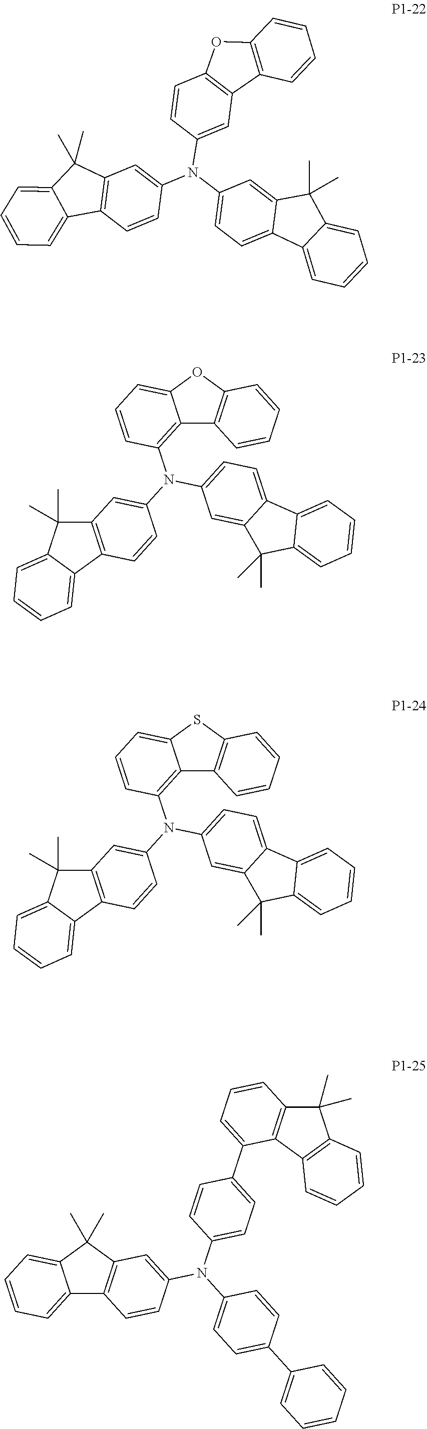 [SMILES: CC1(C)c2ccccc2-c2ccc(N(c3ccc4c(c3)C(C)(C)c3ccccc3-4)c3ccc4oc5ccccc5c4c3)cc21 ; CC1(C)c2ccccc2-c2ccc(N(c3ccc4c(c3)C(C)(C)c3ccccc3-4)c3cccc4oc5ccccc5c34)cc21 ; CC1(C)c2ccccc2-c2ccc(N(c3ccc4c(c3)C(C)(C)c3ccccc3-4)c3cccc4sc5ccccc5c34)cc21 ; CC1(C)c2ccccc2-c2ccc(N(c3ccc(-c4ccccc4)cc3)c3ccc(-c4cccc5c4-c4ccccc4C5(C)C)cc3)cc21]

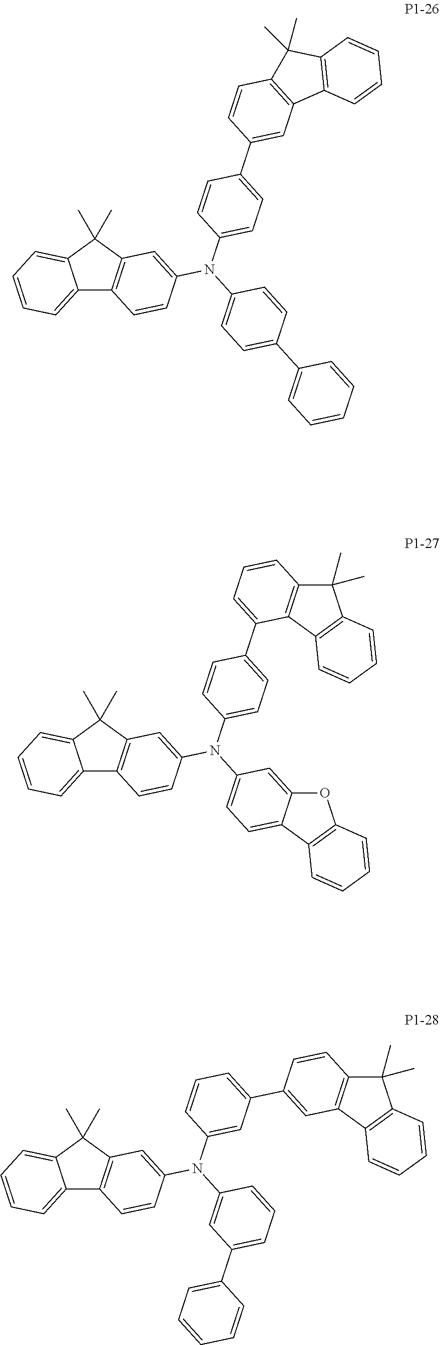 [SMILES: CC1(C)c2ccccc2-c2cc(-c3ccc(N(c4ccc(-c5ccccc5)cc4)c4ccc5c(c4)C(C)(C)c4ccccc4-5)cc3)ccc21 ; CC1(C)c2ccccc2-c2ccc(N(c3ccc(-c4cccc5c4-c4ccccc4C5(C)C)cc3)c3ccc4c(c3)oc3ccccc34)cc21 ; CC1(C)c2ccccc2-c2cc(-c3cccc(N(c4cccc(-c5ccccc5)c4)c4ccc5c(c4)C(C)(C)c4ccccc4-5)c3)ccc21]

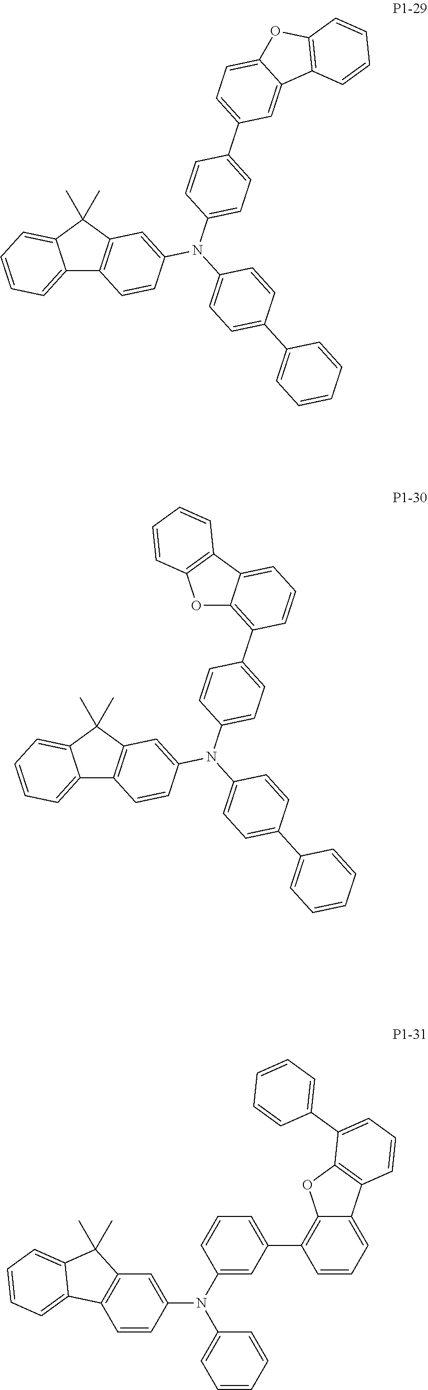 [SMILES: CC1(C)c2ccccc2-c2ccc(N(c3ccc(-c4ccccc4)cc3)c3ccc(-c4ccc5oc6ccccc6c5c4)cc3)cc21 ; CC1(C)c2ccccc2-c2ccc(N(c3ccc(-c4ccccc4)cc3)c3ccc(-c4cccc5c4oc4ccccc45)cc3)cc21 ; CC1(C)c2ccccc2-c2ccc(N(c3ccccc3)c3cccc(-c4cccc5c4oc4c(-c6ccccc6)cccc45)c3)cc21]

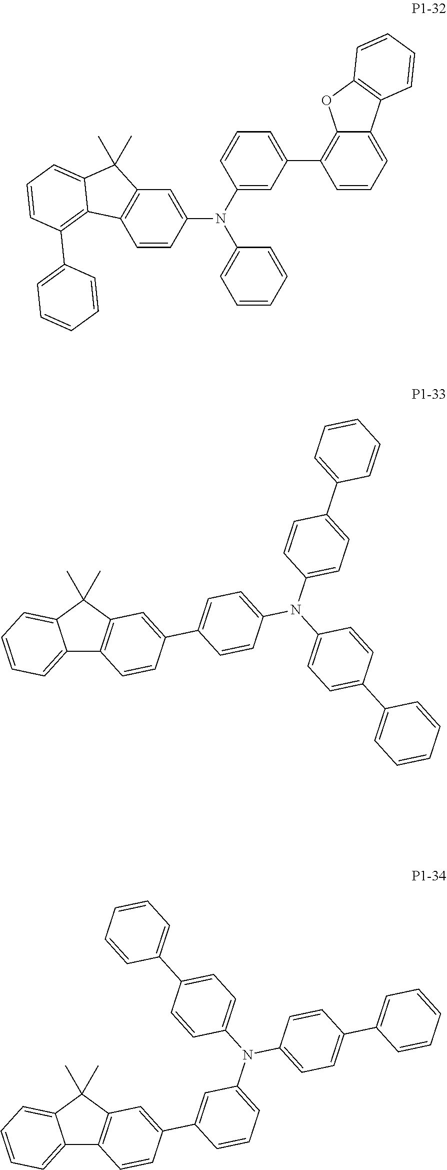 [SMILES: CC1(C)c2cc(N(c3ccccc3)c3cccc(-c4cccc5c4oc4ccccc45)c3)ccc2-c2c(-c3ccccc3)cccc21 ; CC1(C)c2ccccc2-c2ccc(-c3ccc(N(c4ccc(-c5ccccc5)cc4)c4ccc(-c5ccccc5)cc4)cc3)cc21 ; CC1(C)c2ccccc2-c2ccc(-c3cccc(N(c4ccc(-c5ccccc5)cc4)c4ccc(-c5ccccc5)cc4)c3)cc21]

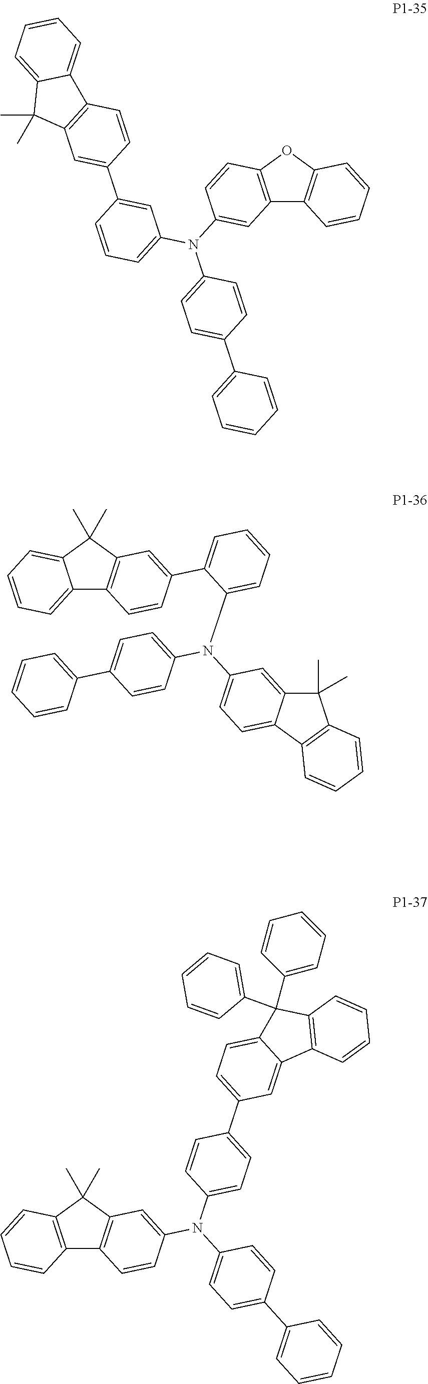 [SMILES: CC1(C)c2ccccc2-c2ccc(-c3cccc(N(c4ccc(-c5ccccc5)cc4)c4ccc5oc6ccccc6c5c4)c3)cc21 ; CC1(C)c2ccccc2-c2ccc(-c3ccccc3N(c3ccc(-c4ccccc4)cc3)c3ccc4c(c3)C(C)(C)c3ccccc3-4)cc21 ; CC1(C)c2ccccc2-c2ccc(N(c3ccc(-c4ccccc4)cc3)c3ccc(-c4ccc5c(c4)-c4ccccc4C5(c4ccccc4)c4ccccc4)cc3)cc21]

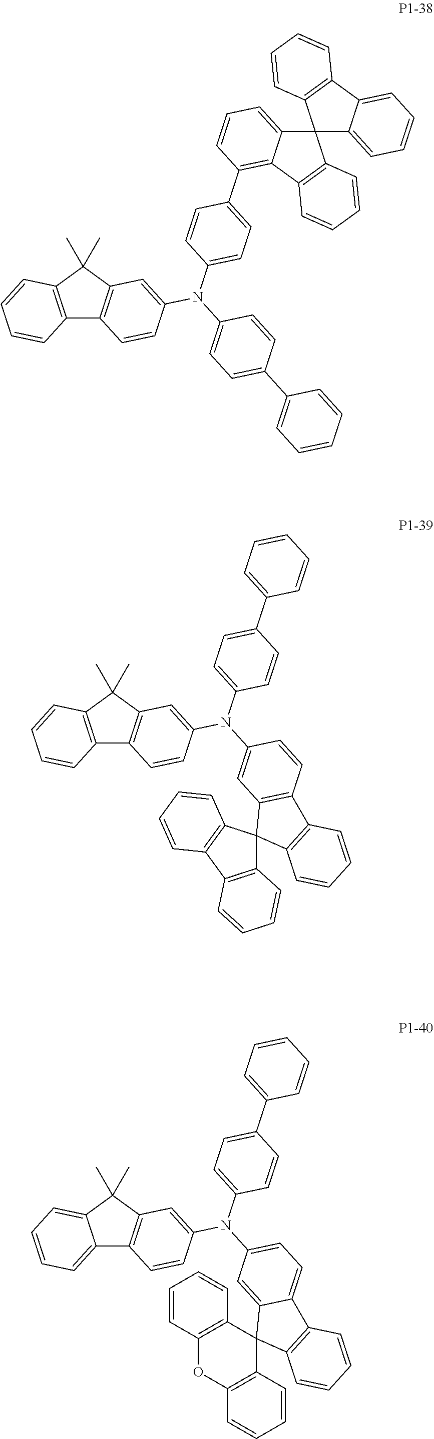 [SMILES: CC1(C)c2ccccc2-c2ccc(N(c3ccc(-c4ccccc4)cc3)c3ccc(-c4cccc5c4-c4ccccc4C54c5ccccc5-c5ccccc54)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5Oc5ccccc53)c3ccccc3-4)cc21]

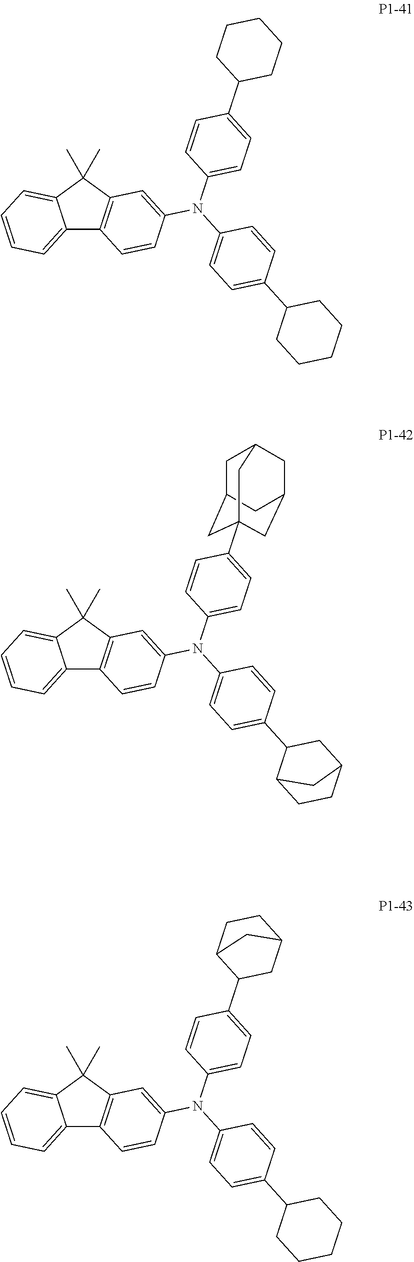 [SMILES: CC1(C)c2ccccc2-c2ccc(N(c3ccc(C4CCCCC4)cc3)c3ccc(C4CCCCC4)cc3)cc21 ; CC1(C)c2ccccc2-c2ccc(N(c3ccc(C4CC5CCC4C5)cc3)c3ccc(C45CC6CC(CC(C6)C4)C5)cc3)cc21 ; CC1(C)c2ccccc2-c2ccc(N(c3ccc(C4CCCCC4)cc3)c3ccc(C4CC5CCC4C5)cc3)cc21]

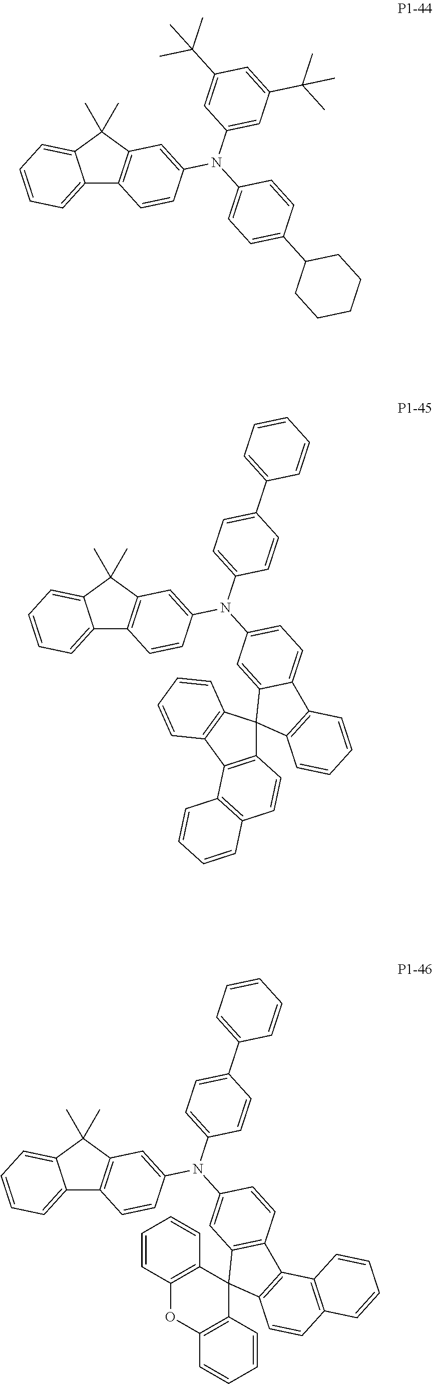 [SMILES: CC(C)(C)c1cc(N(c2ccc(C3CCCCC3)cc2)c2ccc3c(c2)C(C)(C)c2ccccc2-3)cc(C(C)(C)C)c1 ; CC1(C)c2ccccc2-c2ccc(N(c3ccc(-c4ccccc4)cc3)c3ccc4c(c3)C3(c5ccccc5-4)c4ccccc4-c4c3ccc3ccccc43)cc21 ; CC1(C)c2ccccc2-c2ccc(N(c3ccc(-c4ccccc4)cc3)c3ccc4c(c3)C3(c5ccccc5Oc5ccccc53)c3ccc5ccccc5c3-4)cc21]

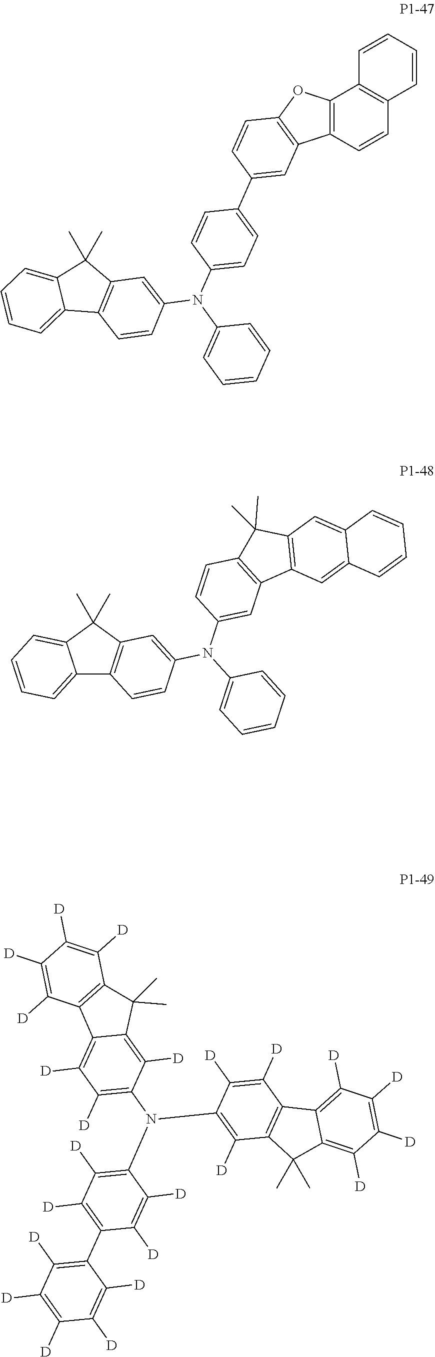 [SMILES: CC1(C)c2ccccc2-c2ccc(N(c3ccccc3)c3ccc(-c4ccc5oc6c7ccccc7ccc6c5c4)cc3)cc21 ; CC1(C)c2ccccc2-c2ccc(N(c3ccccc3)c3ccc4c(c3)-c3cc5ccccc5cc3C4(C)C)cc21 ; [2H]c1c([2H])c([2H])c(-c2c([2H])c([2H])c(N(c3c([2H])c([2H])c4c(c3[2H])C(C)(C)c3c([2H])c([2H])c([2H])c([2H])c3-4)c3c([2H])c([2H])c4c(c3[2H])C(C)(C)c3c([2H])c([2H])c([2H])c([2H])c3-4)c([2H])c2[2H])c([2H])c1[2H]]

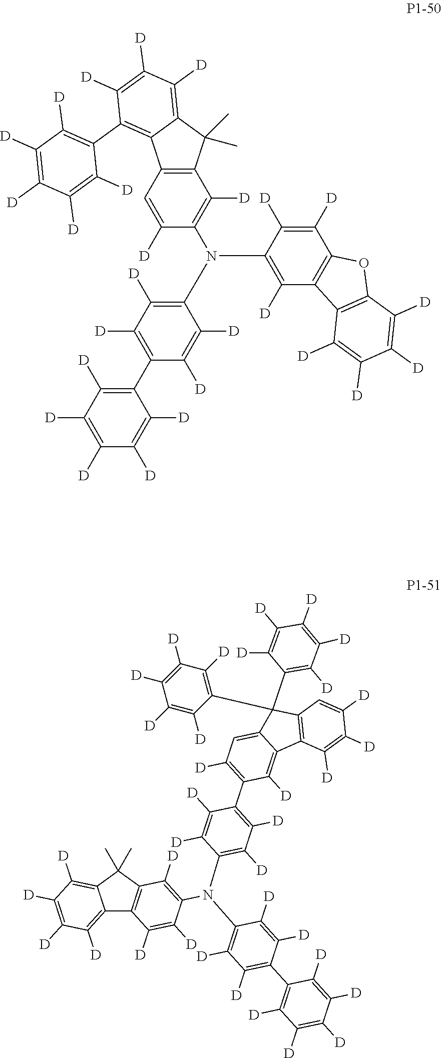

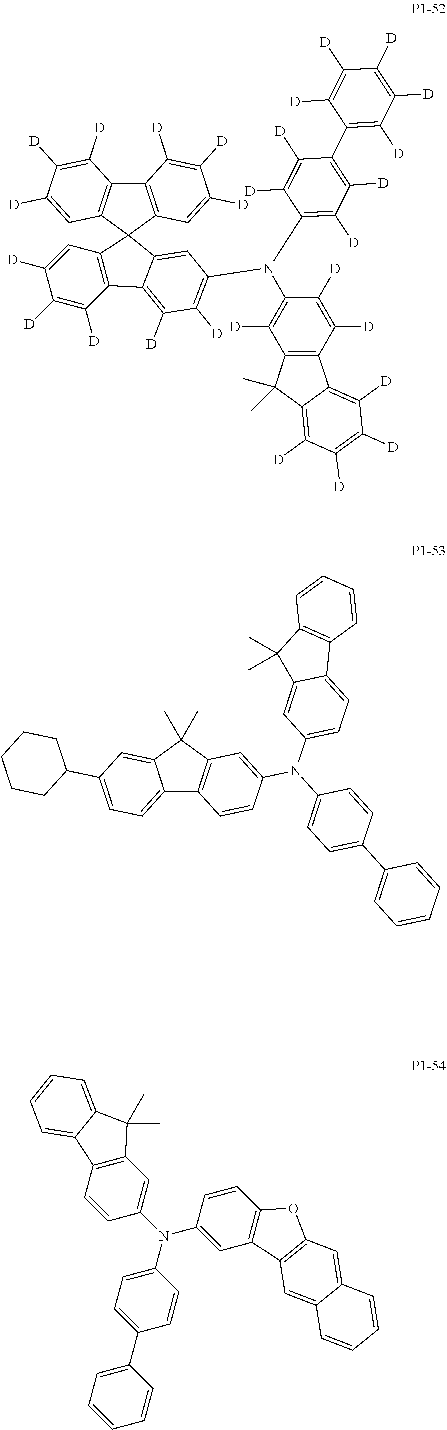 [SMILES: [2H]c1cc2c(c([2H])c1[2H])-c1c(cc([2H])c([2H])c1[2H])C21c2cc([2H])c([2H])c([2H])c2-c2c1cc(N(c1c([2H])c([2H])c(-c3c([2H])c([2H])c([2H])c([2H])c3[2H])c([2H])c1[2H])c1c([2H])c([2H])c3c(c1[2H])C(C)(C)c1c([2H])c([2H])c([2H])c([2H])c1-3)c([2H])c2[2H] ; CC1(C)c2ccccc2-c2ccc(N(c3ccc(-c4ccccc4)cc3)c3ccc4c(c3)C(C)(C)c3cc(C5CCCCC5)ccc3-4)cc21 ; CC1(C)c2ccccc2-c2ccc(N(c3ccc(-c4ccccc4)cc3)c3ccc4oc5cc6ccccc6cc5c4c3)cc21]

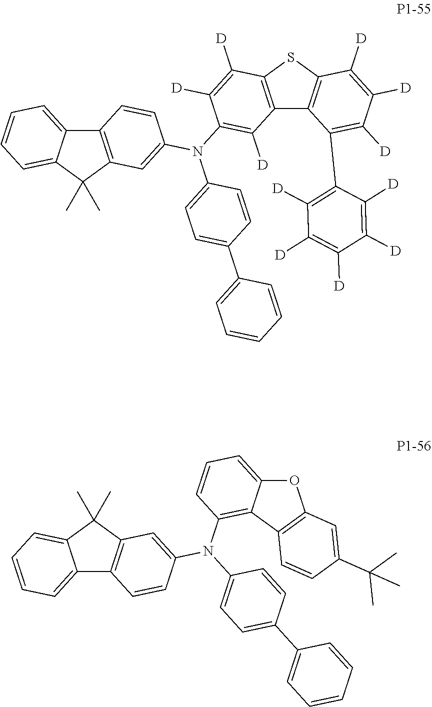 [SMILES: [2H]c1c([2H])c([2H])c(-c2c([2H])c([2H])c([2H])c3sc4c([2H])c([2H])c(N(c5ccc(-c6ccccc6)cc5)c5ccc6c(c5)C(C)(C)c5ccccc5-6)c([2H])c4c23)c([2H])c1[2H] ; CC(C)(C)c1ccc2c(c1)oc1cccc(N(c3ccc(-c4ccccc4)cc3)c3ccc4c(c3)C(C)(C)c3ccccc3-4)c12]

Specifically, the compound represented by Formula 2 may be any one of the following compounds, but is not limited thereto.

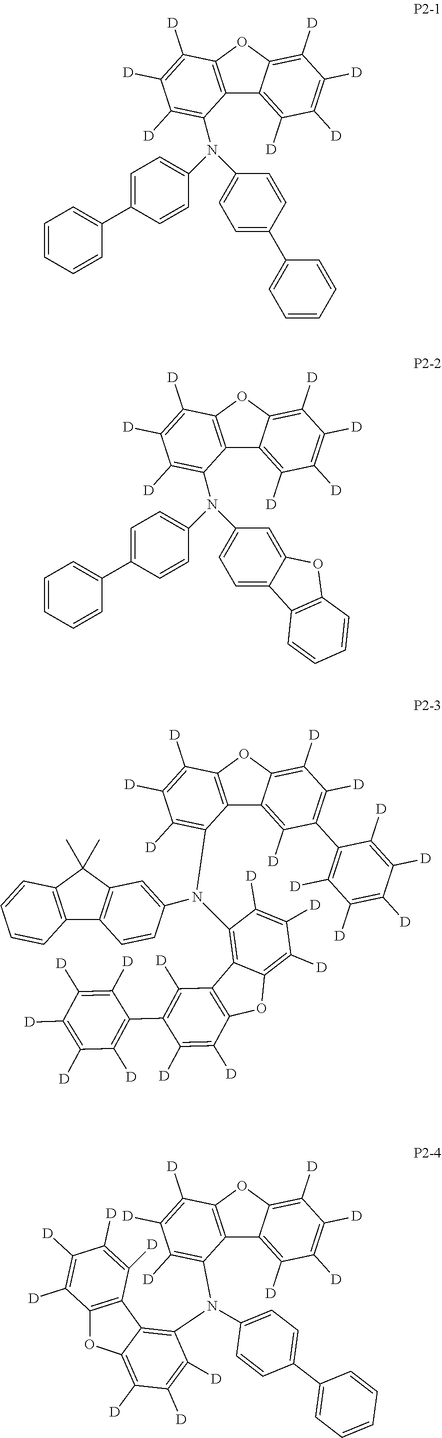

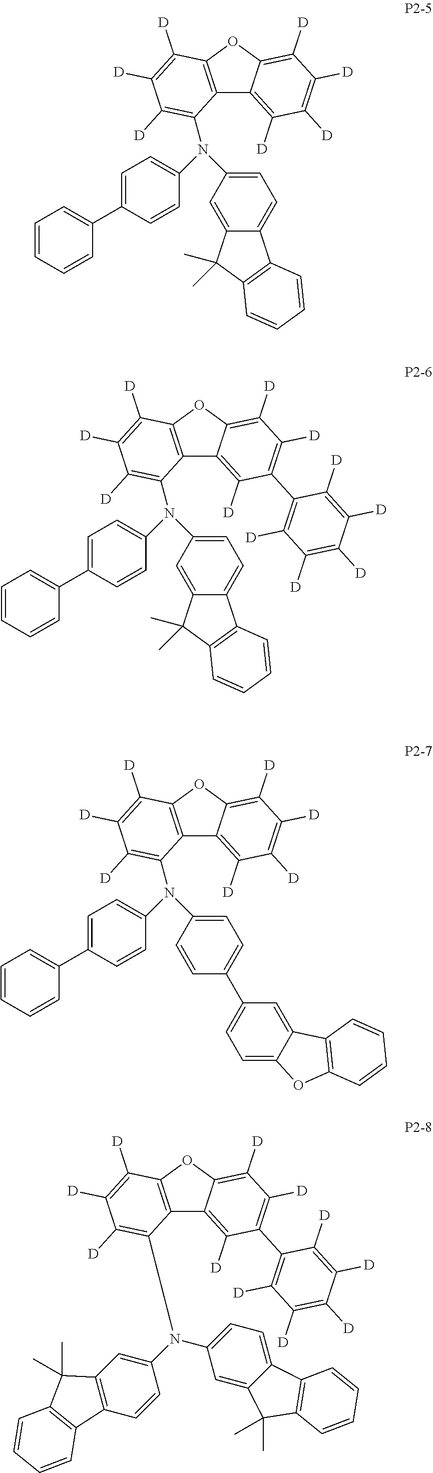

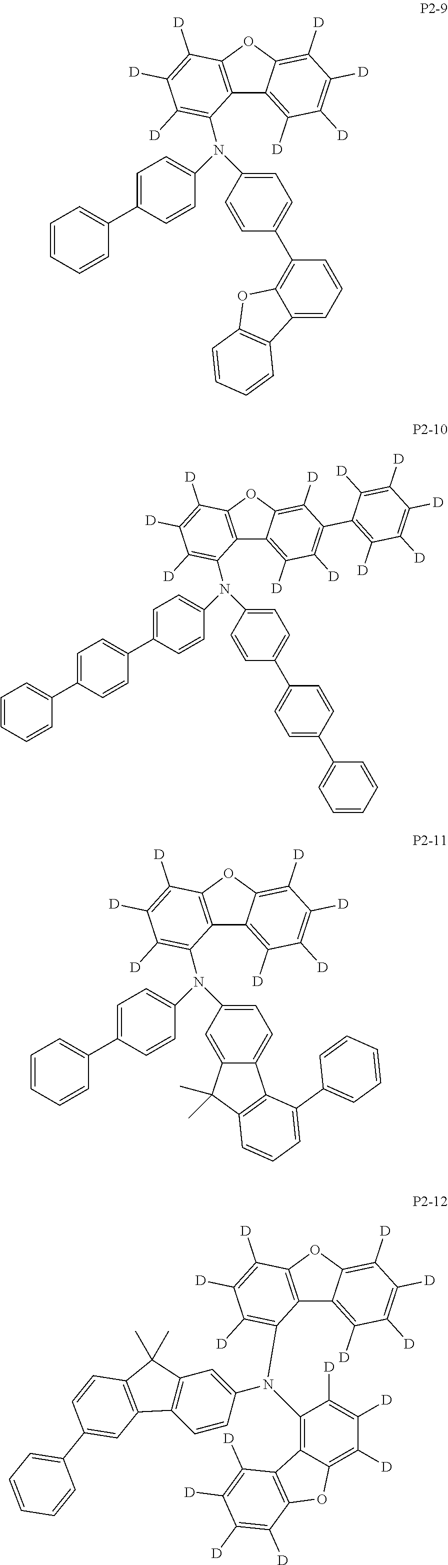

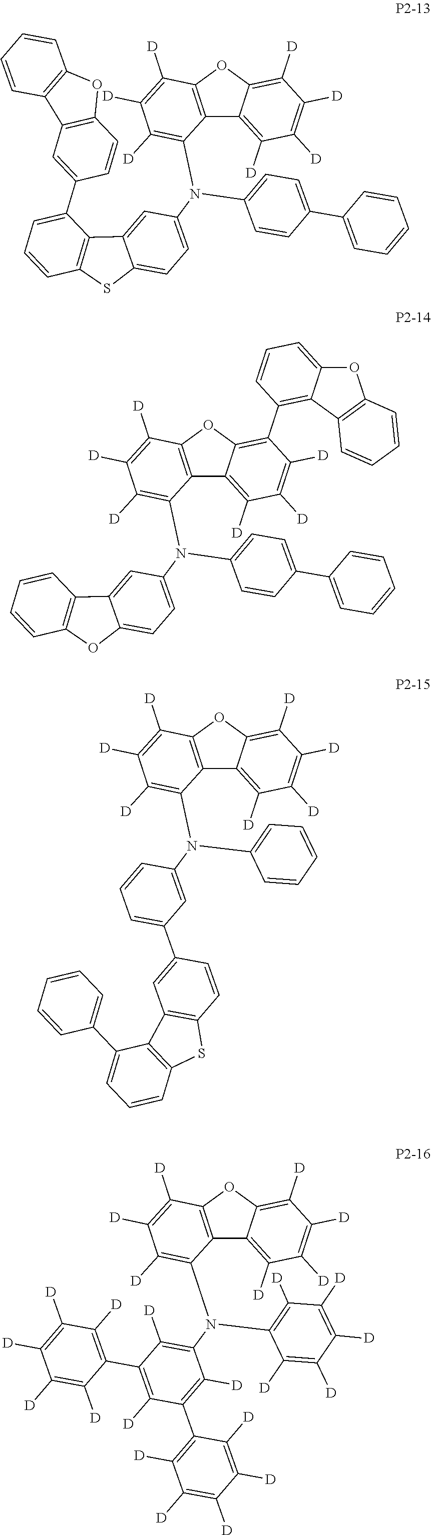

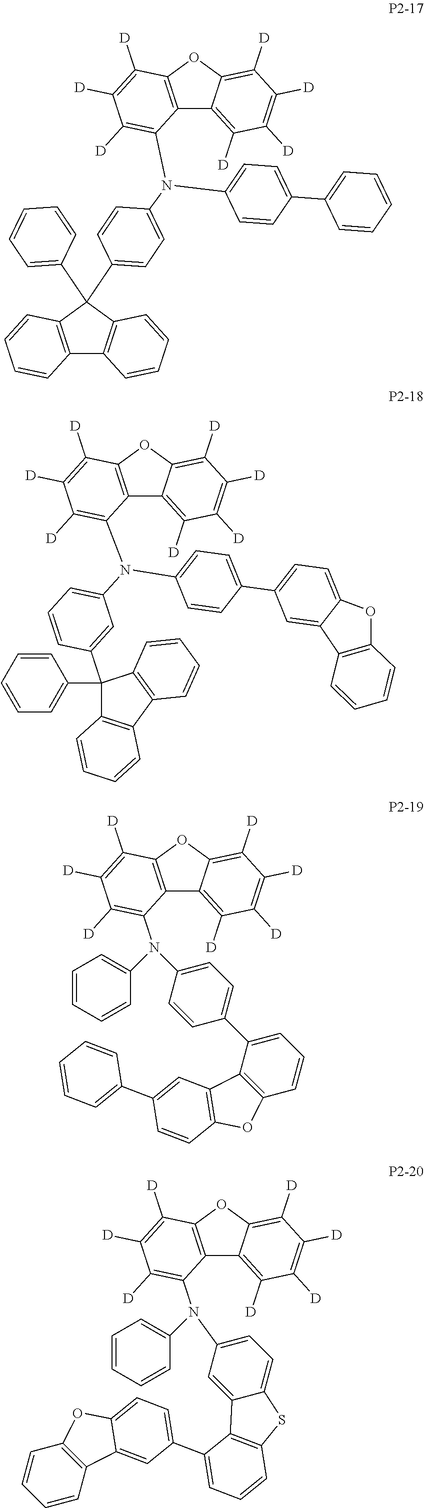

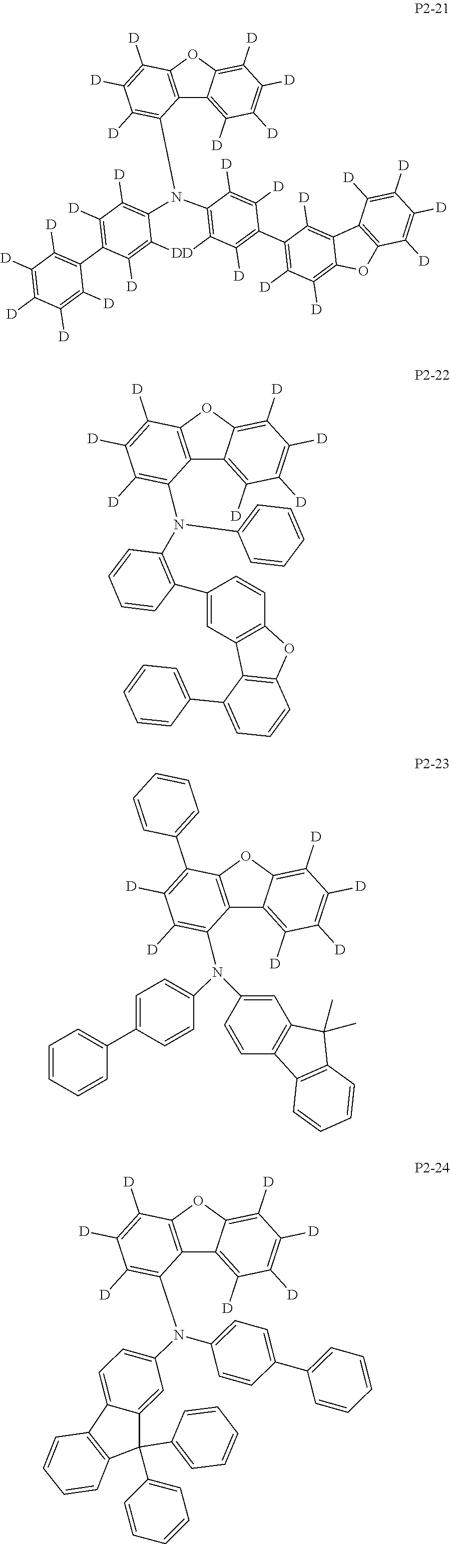

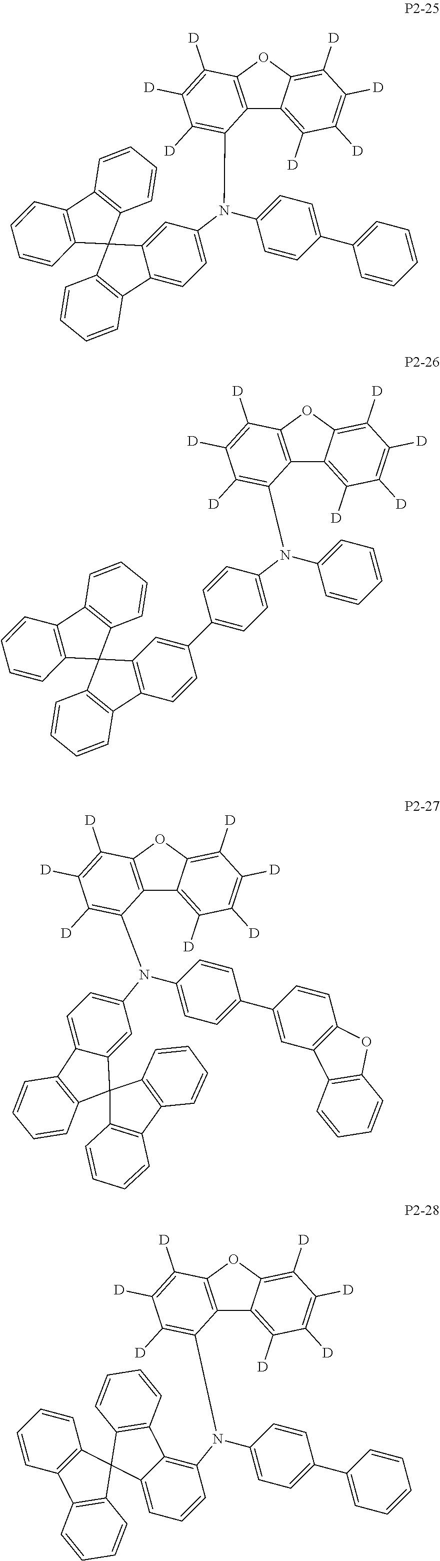

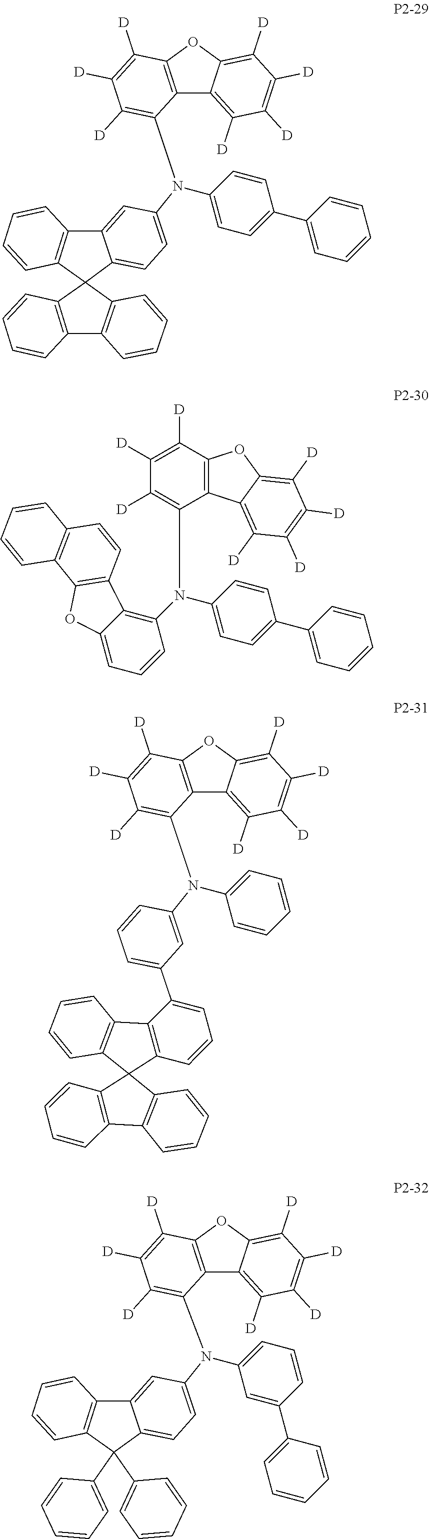 [SMILES: [2H]c1c([2H])c([2H])c2c(oc3c([2H])c([2H])c([2H])c(N(c4ccc(-c5ccccc5)cc4)c4ccc5c(c4)-c4ccccc4C54c5ccccc5-c5ccccc54)c32)c1[2H] ; [2H]c1c([2H])c([2H])c2c(oc3c([2H])c([2H])c([2H])c(N(c4ccc(-c5ccccc5)cc4)c4cccc5oc6c7ccccc7ccc6c45)c32)c1[2H] ; [2H]c1c([2H])c([2H])c2c(oc3c([2H])c([2H])c([2H])c(N(c4ccccc4)c4cccc(-c5cccc6c5-c5ccccc5C65c6ccccc6-c6ccccc65)c4)c32)c1[2H] ; [2H]c1c([2H])c([2H])c2c(oc3c([2H])c([2H])c([2H])c(N(c4cccc(-c5ccccc5)c4)c4ccc5c(c4)-c4ccccc4C5(c4ccccc4)c4ccccc4)c32)c1[2H]]

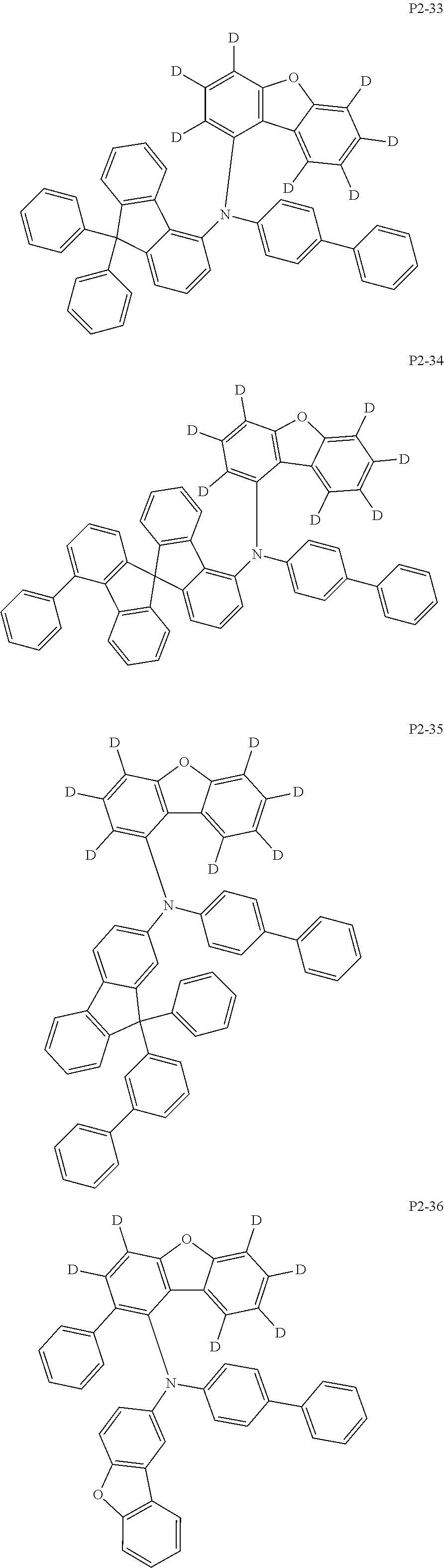

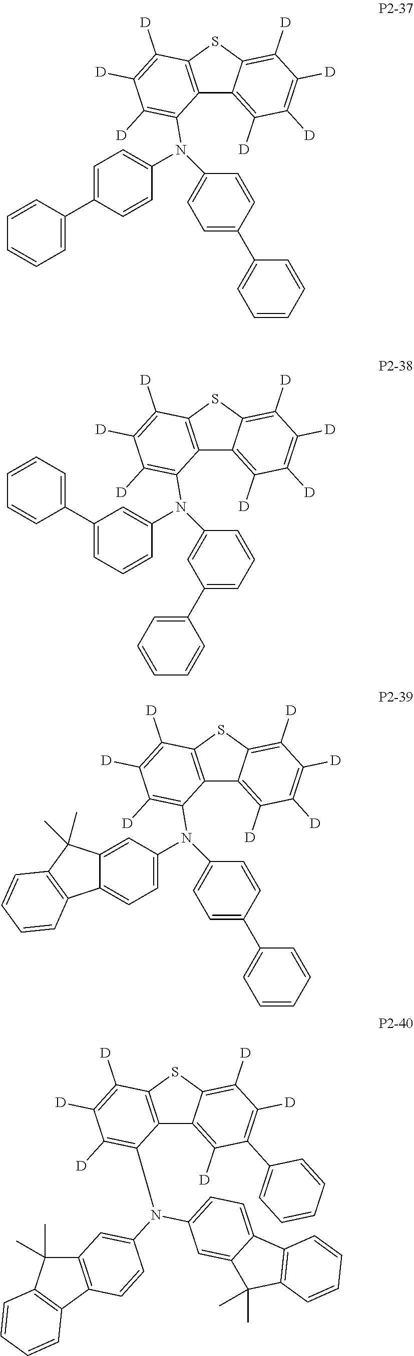

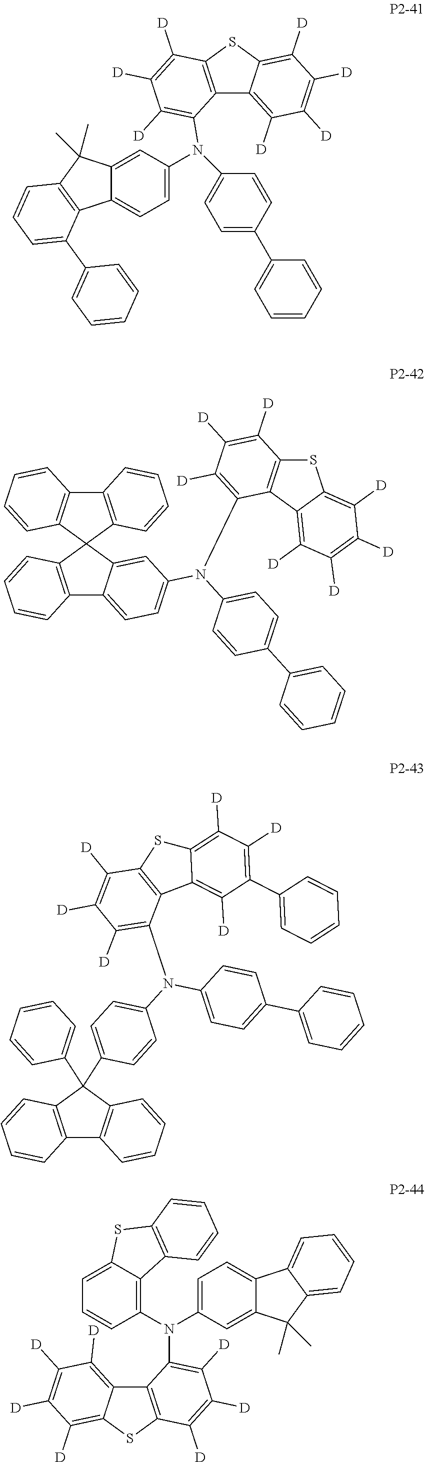 [SMILES: [2H]c1c([2H])c([2H])c2c(sc3c([2H])c([2H])c([2H])c(N(c4ccc(-c5ccccc5)cc4)c4ccc5c(c4)C(C)(C)c4cccc(-c6ccccc6)c4-5)c32)c1[2H] ; [2H]c1c([2H])c([2H])c2c(sc3c([2H])c([2H])c([2H])c(N(c4ccc(-c5ccccc5)cc4)c4ccc5c(c4)C4(c6ccccc6-c6ccccc64)c4ccccc4-5)c32)c1[2H] ; [2H]c1c(-c2ccccc2)c([2H])c2c(sc3c([2H])c([2H])c([2H])c(N(c4ccc(-c5ccccc5)cc4)c4ccc(C5(c6ccccc6)c6ccccc6-c6ccccc65)cc4)c32)c1[2H] ; [2H]c1c([2H])c([2H])c2c(sc3c([2H])c([2H])c([2H])c(N(c4ccc5c(c4)C(C)(C)c4ccccc4-5)c4cccc5sc6ccccc6c45)c32)c1[2H]]

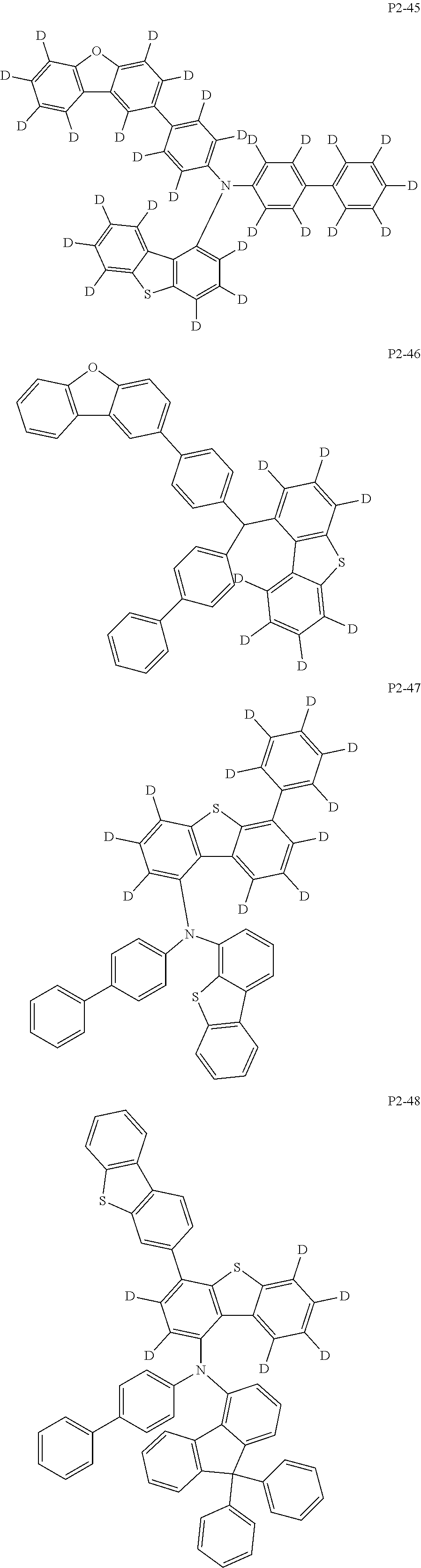

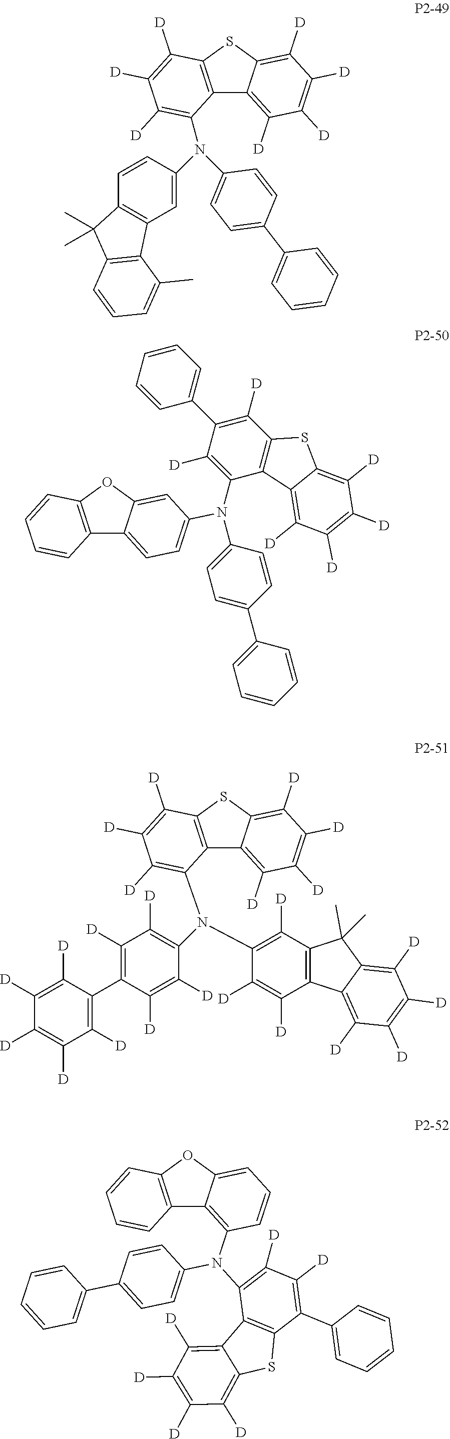

The present invention may further comprise a light efficiency enhancing layer formed on at least one surface of the first electrode and the second electrode, the surface being opposite to the organic material layer.

Also, the organic material layer may comprise 2 or more stacks comprising a hole transport layer, an emitting layer, and an electron transport layer sequentially formed on the anode and may further comprise a charge generation layer formed between the 2 or more stacks

Also, the present invention provides an electronic device comprising a display device comprising the organic electronic element; and a control unit for driving the display device. wherein, the organic electronic element is at least one of an OLED, an organic solar cell, an organic photo conductor, an organic transistor (organic TFT) and an element for monochromic or white illumination.

Hereinafter, examples of synthesis of compounds represented by Formulas according to the present invention and examples of manufacturing organic electronic elements will be described in detail through examples, but the present invention is not limited to the following examples.

### Synthesis Example 1

The compound represented by Formula 1 (Final Product 1) according to the present invention is synthesized by reacting Sub1 and Sub2 as shown in Reaction Scheme 1, but is not limited thereto.

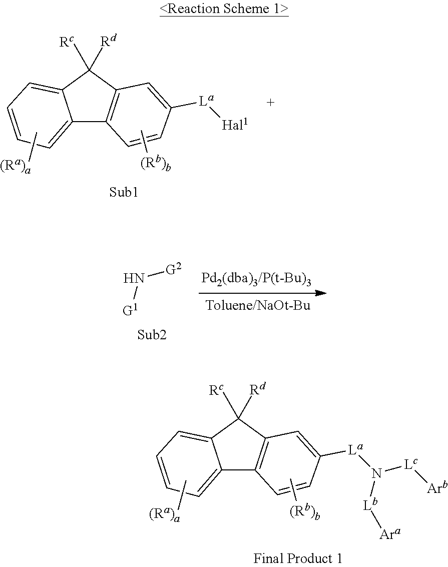

Wherein,
Hal¹ is Cl, Br or I,
G¹ is =L^{b}-Ar^{a},
G² is -L^{c}-Ar^{b}.

### I. Synthesis of Sub1

The compounds belonging to Sub 1 of Reaction Scheme 1 may be the following compounds, but is not limited thereto, and Table 1 shows the FD-MS (Field Desorption-Mass Spectrometry) values of the compounds belonging to Sub 1.

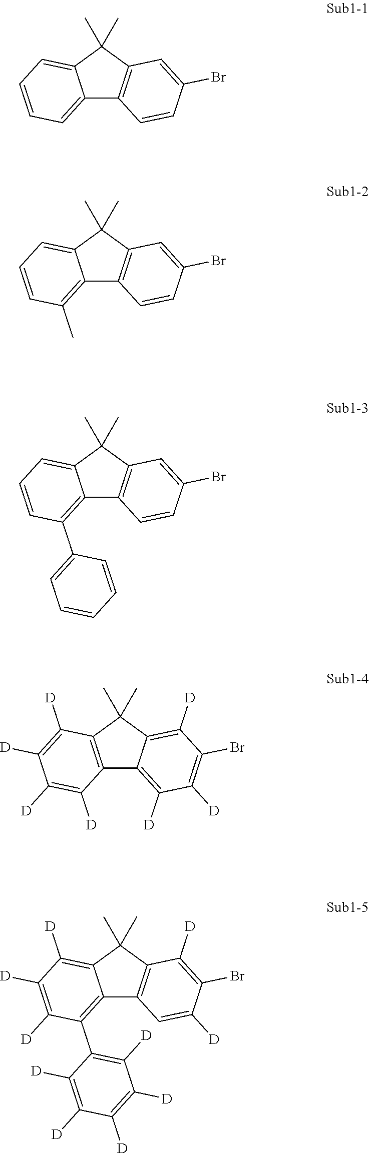 [SMILES: CC1(C)c2ccccc2-c2ccc(Br)cc21 ; Cc1cccc2c1-c1ccc(Br)cc1C2(C)C ; CC1(C)c2cc(Br)ccc2-c2c(-c3ccccc3)cccc21 ; [2H]c1c([2H])c([2H])c2c(c1[2H])-c1c([2H])c([2H])c(Br)c([2H])c1C2(C)C ; [2H]c1cc2c(c([2H])c1Br)C(C)(C)c1c([2H])c([2H])c([2H])c(-c3c([2H])c([2H])c([2H])c([2H])c3[2H])c1-2]

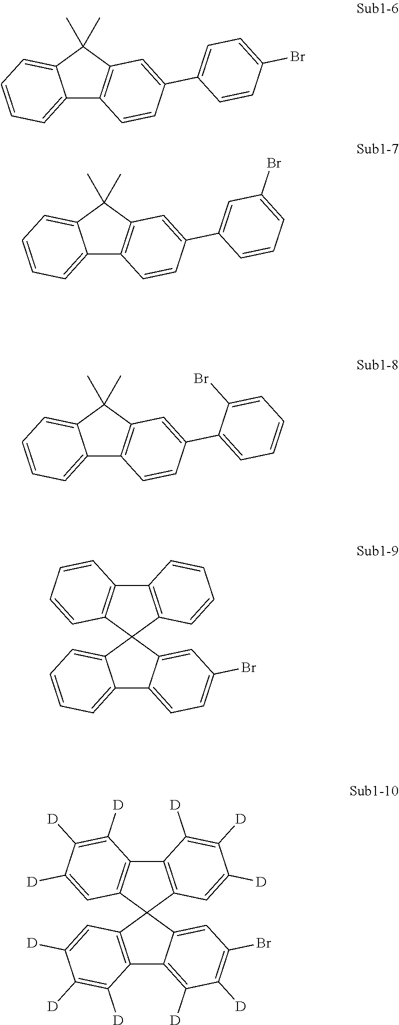 [SMILES: CC1(C)c2ccccc2-c2ccc(-c3ccc(Br)cc3)cc21 ; CC1(C)c2ccccc2-c2ccc(-c3cccc(Br)c3)cc21 ; CC1(C)c2ccccc2-c2ccc(-c3ccccc3Br)cc21 ; Brc1ccc2c(c1)C1(c3ccccc3-c3ccccc31)c1ccccc1-2 ; [2H]c1cc2c(c([2H])c1[2H])-c1c(cc([2H])c([2H])c1[2H])C21c2cc([2H])c([2H])c([2H])c2-c2c1cc(Br)c([2H])c2[2H]]

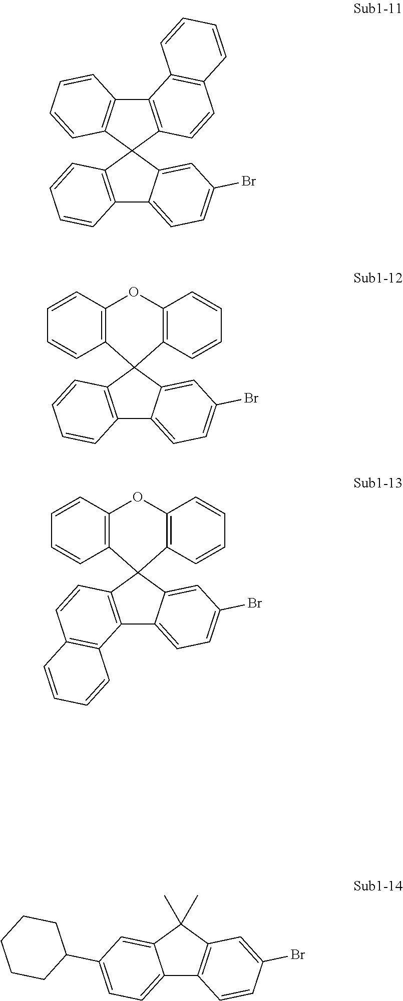 [SMILES: Brc1ccc2c(c1)C1(c3ccccc3-2)c2ccccc2-c2c1ccc1ccccc21 ; Brc1ccc2c(c1)C1(c3ccccc3Oc3ccccc31)c1ccccc1-2 ; Brc1ccc2c(c1)C1(c3ccccc3Oc3ccccc31)c1ccc3ccccc3c1-2 ; CC1(C)c2cc(Br)ccc2-c2ccc(C3CCCCC3)cc21]

TABLE 1

| Com- | | Com- | |
|---|---|---|---|
| pound | FD-MS | pound | FD-MS |
| Sub1-1 | m/z = 272.02(C₁₅H₁₃Br = 273.17) | Sub1-2 | m/z = 286.04(C₁₆H₁₅Br = 287.2) |
| Sub1-3 | m/z = 348.05(C₂₁H₁₇Br = 349.27) | Sub1-4 | m/z = 279.06(C₁₅H₆D₇Br = 280.22) |
| Sub1-5 | m/z = 358.11(C₂₁H₇D₁₀Br = 359.33) | Sub1-6 | m/z = 348.05(C₂₁H₁₇Br = 349.27) |
| Sub1-7 | m/z = 348.05(C₂₁H₁₇Br = 349.27) | Sub1-8 | m/z = 348.05(C₂₁H₁₇Br = 349.27) |
| Sub1-9 | m/z = 394.04(C₂₅H₁₅Br = 395.3) | Sub1-10 | m/z = 405.1(C₂₅H₄D₁₁Br = 406.37) |
| Sub1-11 | m/z = 444.05(C₂₉H₁₇Br = 445.36) | Sub1-12 | m/z = 410.03(C₂₅H₁₅BrO = 411.3) |
| Sub1-13 | m/z = 460.05(C₂₉H₁₇BrO = 461.36) | Sub1-14 | m/z = 354.1(C₂₁H₂₃Br = 355.32) |

### II. Synthesis of Sub2

The compounds belonging to Sub 2 of Reaction Scheme 1 may be the following compounds, but is not limited thereto, and Table 2 shows the FD-MS values of the compounds belonging to Sub 2.

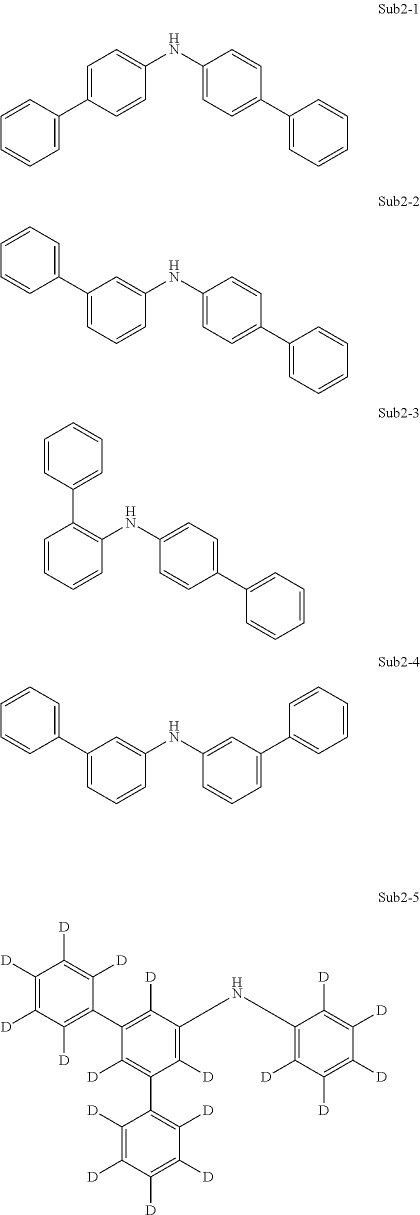 [SMILES: c1ccc(-c2ccc(Nc3ccc(-c4ccccc4)cc3)cc2)cc1 ; c1ccc(-c2ccc(Nc3cccc(-c4ccccc4)c3)cc2)cc1 ; c1ccc(-c2ccc(Nc3ccccc3-c3ccccc3)cc2)cc1 ; c1ccc(-c2cccc(Nc3cccc(-c4ccccc4)c3)c2)cc1 ; [2H]c1c([2H])c([2H])c(CNCc2c([2H])c(-c3c([2H])c([2H])c([2H])c([2H])c3[2H])c([2H])c(-c3c([2H])c([2H])c([2H])c([2H])c3[2H])c2[2H])c([2H])c1[2H]]

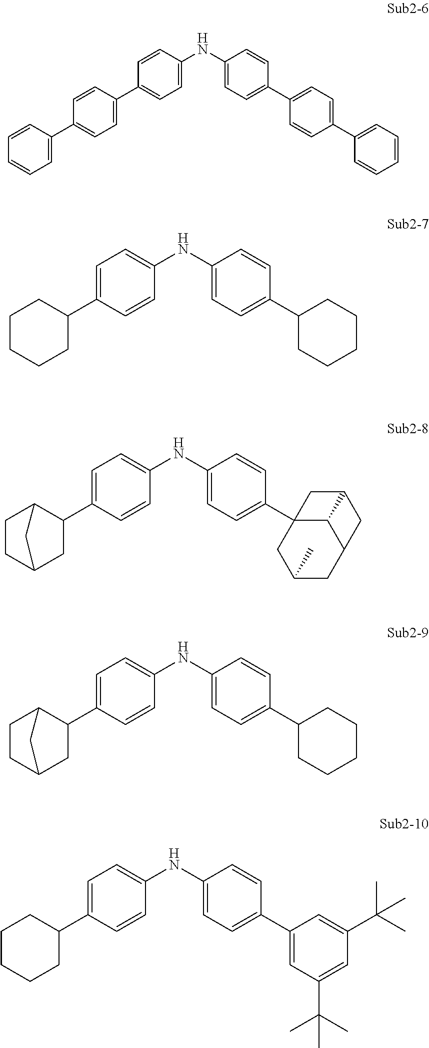

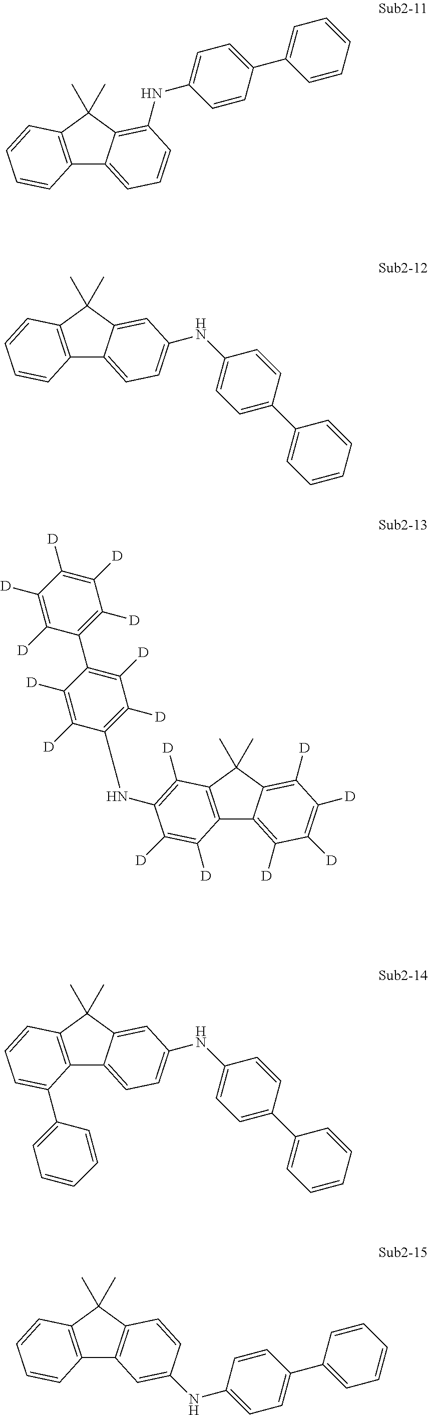 [SMILES: CC1(C)c2ccccc2-c2cccc(Nc3ccc(-c4ccccc4)cc3)c21 ; CC1(C)c2ccccc2-c2ccc(Nc3ccc(-c4ccccc4)cc3)cc21 ; [2H]c1c([2H])c([2H])c(-c2c([2H])c([2H])c(CNc3c([2H])c([2H])c4c(c3[2H])C(C)(C)c3c([2H])c([2H])c([2H])c([2H])c3-4)c([2H])c2[2H])c([2H])c1[2H] ; CC1(C)c2cc(Nc3ccc(-c4ccccc4)cc3)ccc2-c2c(-c3ccccc3)cccc21 ; CC1(C)c2ccccc2-c2cc(Nc3ccc(-c4ccccc4)cc3)ccc21]

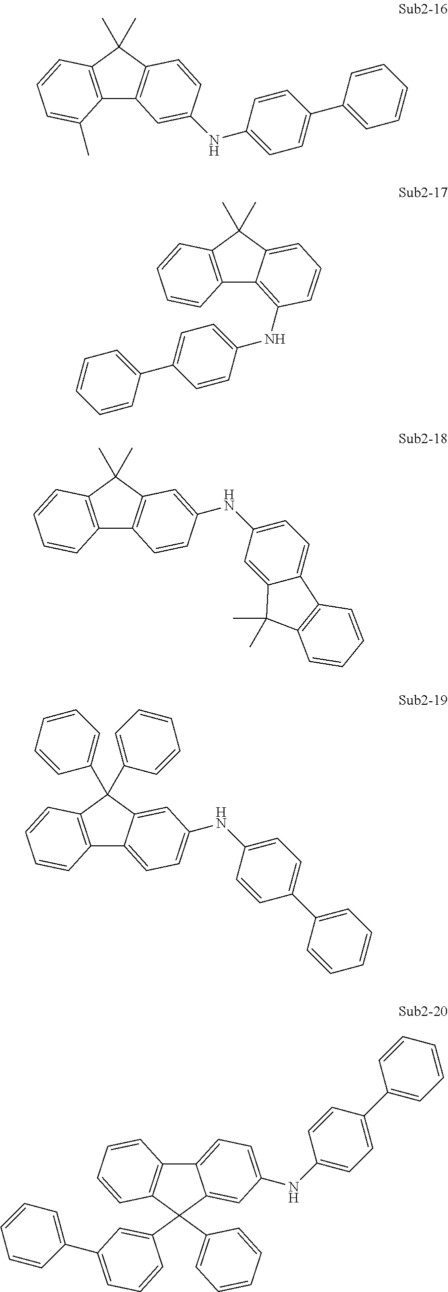

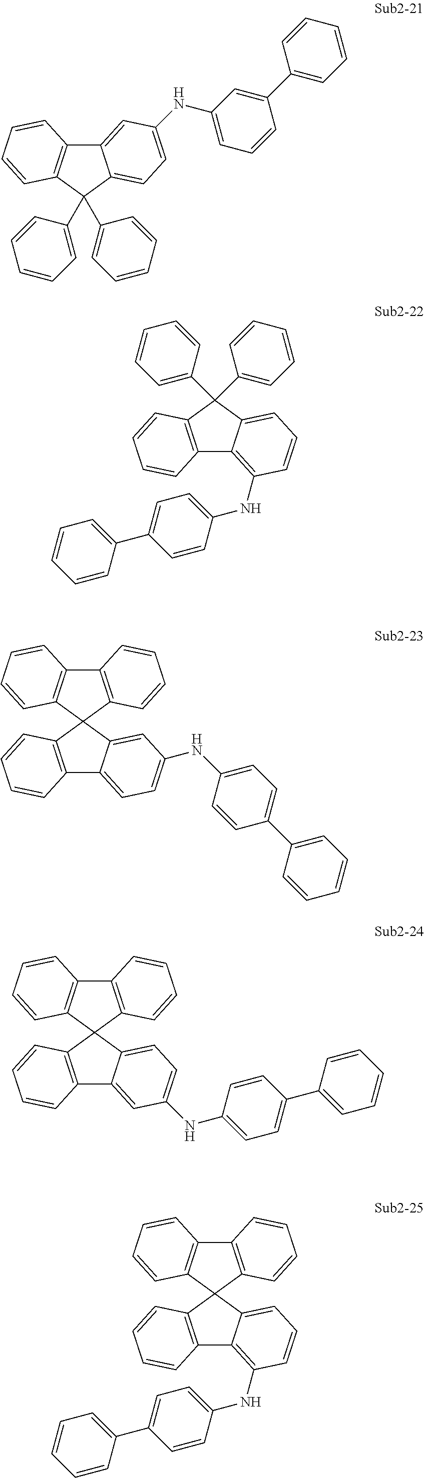 [SMILES: c1ccc(-c2cccc(Nc3ccc4c(c3)-c3ccccc3C4(c3ccccc3)c3ccccc3)c2)cc1 ; c1ccc(-c2ccc(Nc3cccc4c3-c3ccccc3C4(c3ccccc3)c3ccccc3)cc2)cc1 ; c1ccc(-c2ccc(Nc3ccc4c(c3)C3(c5ccccc5-c5ccccc53)c3ccccc3-4)cc2)cc1 ; c1ccc(-c2ccc(Nc3ccc4c(c3)-c3ccccc3C43c4ccccc4-c4ccccc43)cc2)cc1 ; c1ccc(-c2ccc(Nc3cccc4c3-c3ccccc3C43c4ccccc4-c4ccccc43)cc2)cc1]

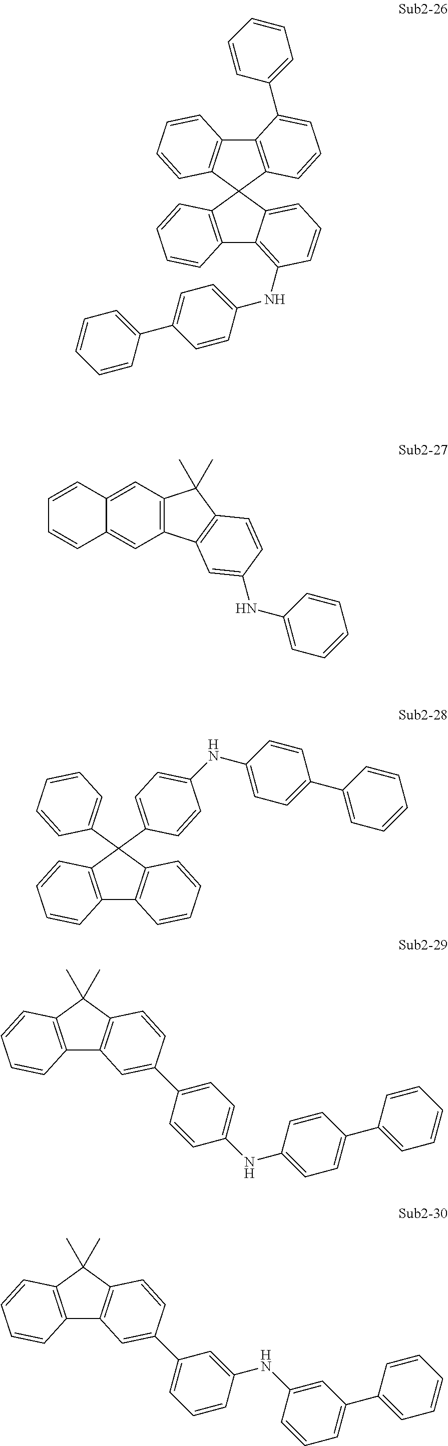 [SMILES: c1ccc(-c2ccc(Nc3cccc4c3-c3ccccc3C43c4ccccc4-c4c(-c5ccccc5)cccc43)cc2)cc1 ; CC1(C)c2ccc(Nc3ccccc3)cc2-c2cc3ccccc3cc21 ; c1ccc(-c2ccc(Nc3ccc(C4(c5ccccc5)c5ccccc5-c5ccccc54)cc3)cc2)cc1 ; CC1(C)c2ccccc2-c2cc(-c3ccc(Nc4ccc(-c5ccccc5)cc4)cc3)ccc21 ; CC1(C)c2ccccc2-c2cc(-c3cccc(Nc4cccc(-c5ccccc5)c4)c3)ccc21]

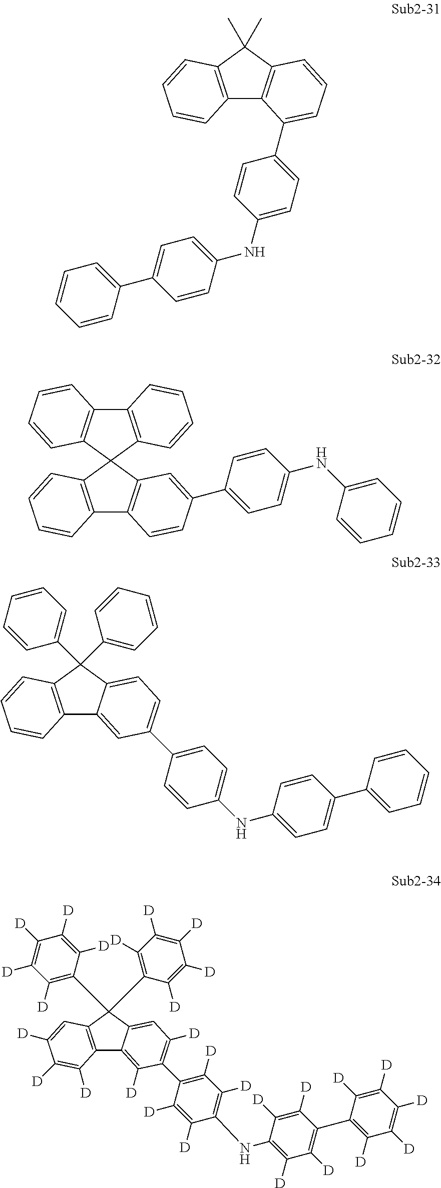 [SMILES: CC1(C)c2ccccc2-c2c(-c3ccc(Nc4ccc(-c5ccccc5)cc4)cc3)cccc21 ; c1ccc(Nc2ccc(-c3ccc4c(c3)C3(c5ccccc5-c5ccccc53)c3ccccc3-4)cc2)cc1 ; c1ccc(-c2ccc(Nc3ccc(-c4ccc5c(c4)-c4ccccc4C5(c4ccccc4)c4ccccc4)cc3)cc2)cc1 ; [2H]c1cc2c(c([2H])c1[2H])-c1c(cc([2H])c(-c3c([2H])c([2H])c(Nc4c([2H])c([2H])c(-c5c([2H])c([2H])c([2H])c([2H])c5[2H])c([2H])c4[2H])c([2H])c3[2H])c1[2H])C2(Cc1c([2H])c([2H])c([2H])c([2H])c1[2H])Cc1c([2H])c([2H])c([2H])c([2H])c1[2H]]

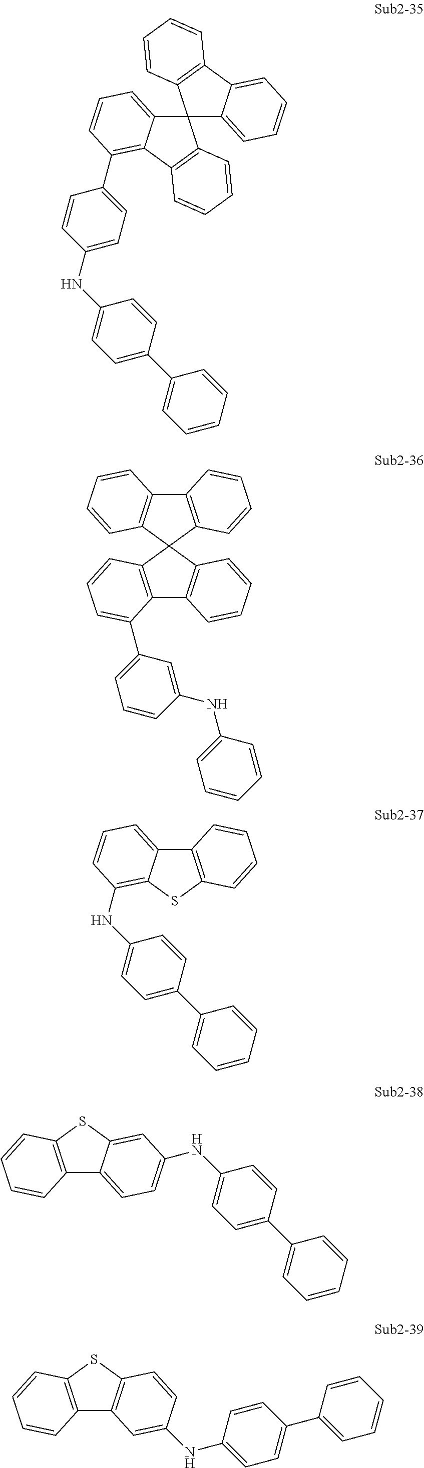

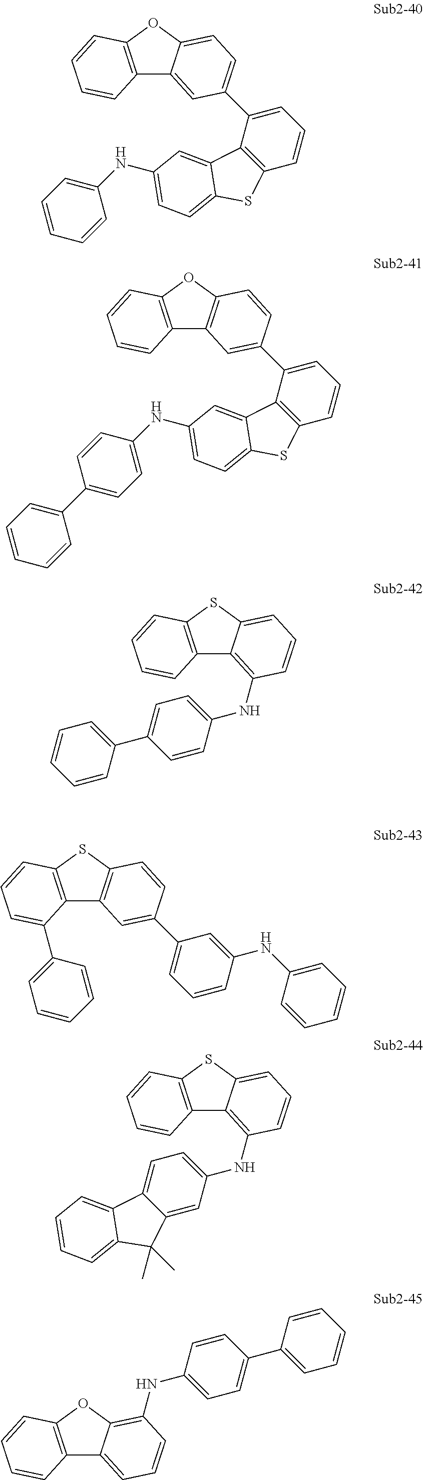 [SMILES: c1ccc(Nc2ccc3sc4cccc(-c5ccc6oc7ccccc7c6c5)c4c3c2)cc1 ; c1ccc(-c2ccc(Nc3ccc4sc5cccc(-c6ccc7oc8ccccc8c7c6)c5c4c3)cc2)cc1 ; c1ccc(-c2ccc(Nc3cccc4sc5ccccc5c34)cc2)cc1 ; c1ccc(Nc2cccc(-c3ccc4sc5cccc(-c6ccccc6)c5c4c3)c2)cc1 ; CC1(C)c2ccccc2-c2ccc(Nc3cccc4sc5ccccc5c34)cc21 ; c1ccc(-c2ccc(Nc3cccc4c3oc3ccccc34)cc2)cc1]

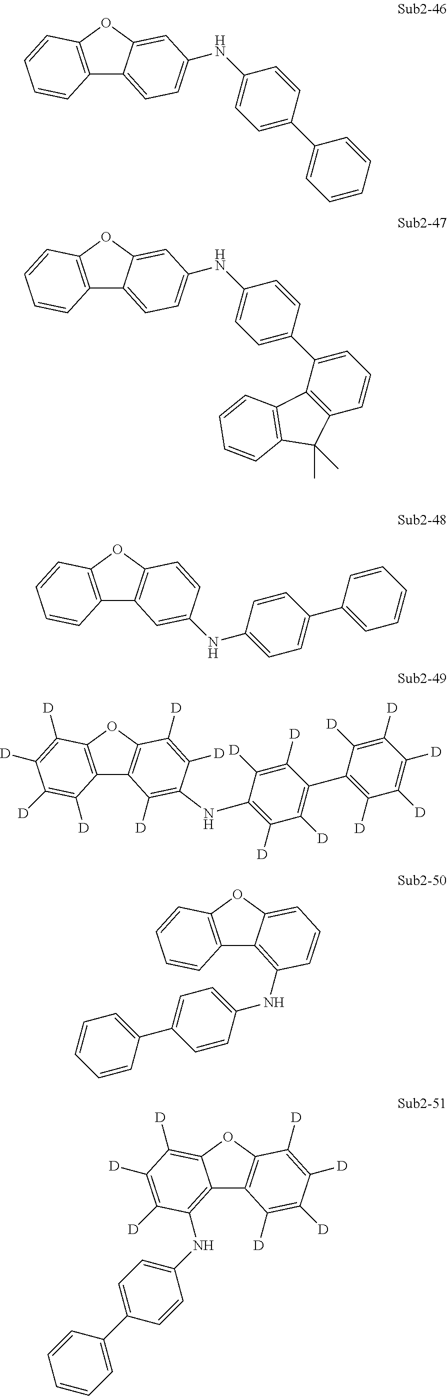

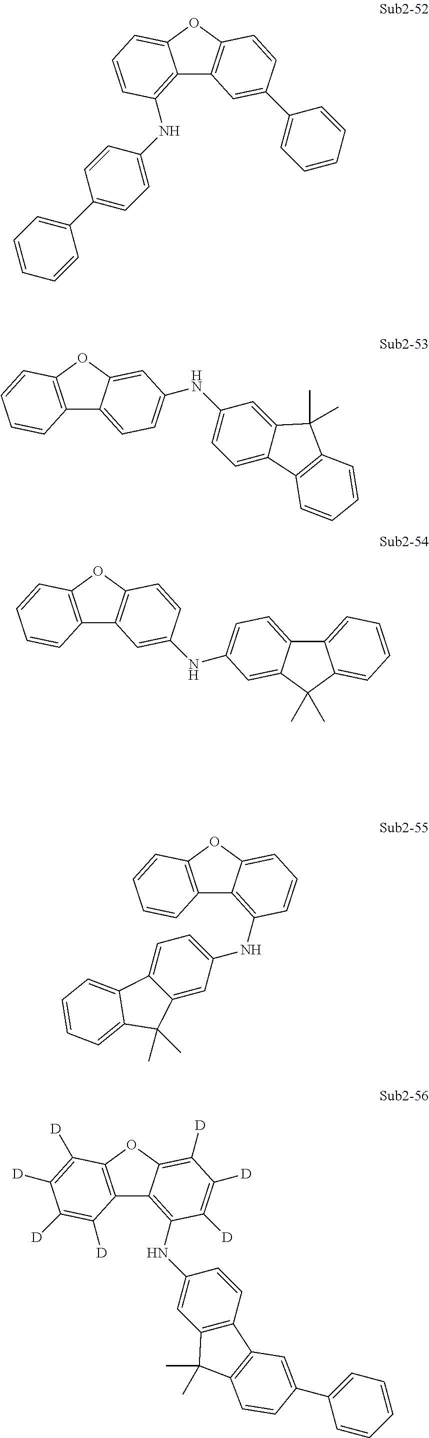 [SMILES: c1ccc(-c2ccc(Nc3cccc4oc5ccc(-c6ccccc6)cc5c34)cc2)cc1 ; CC1(C)c2ccccc2-c2ccc(Nc3ccc4c(c3)oc3ccccc34)cc21 ; CC1(C)c2ccccc2-c2ccc(Nc3ccc4oc5ccccc5c4c3)cc21 ; CC1(C)c2ccccc2-c2ccc(Nc3cccc4oc5ccccc5c34)cc21 ; [2H]c1c([2H])c([2H])c2c(oc3c([2H])c([2H])c([2H])c(Nc4ccc5c(c4)C(C)(C)c4ccc(-c6ccccc6)cc4-5)c32)c1[2H]]

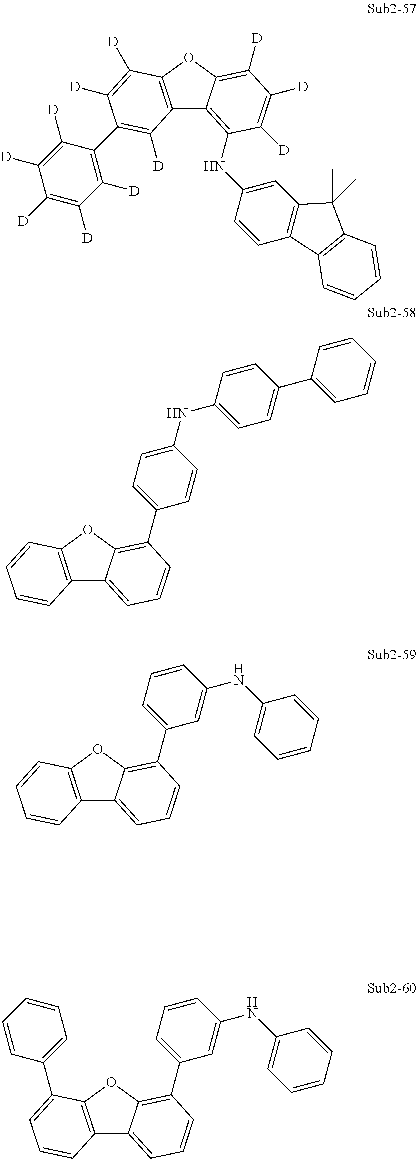

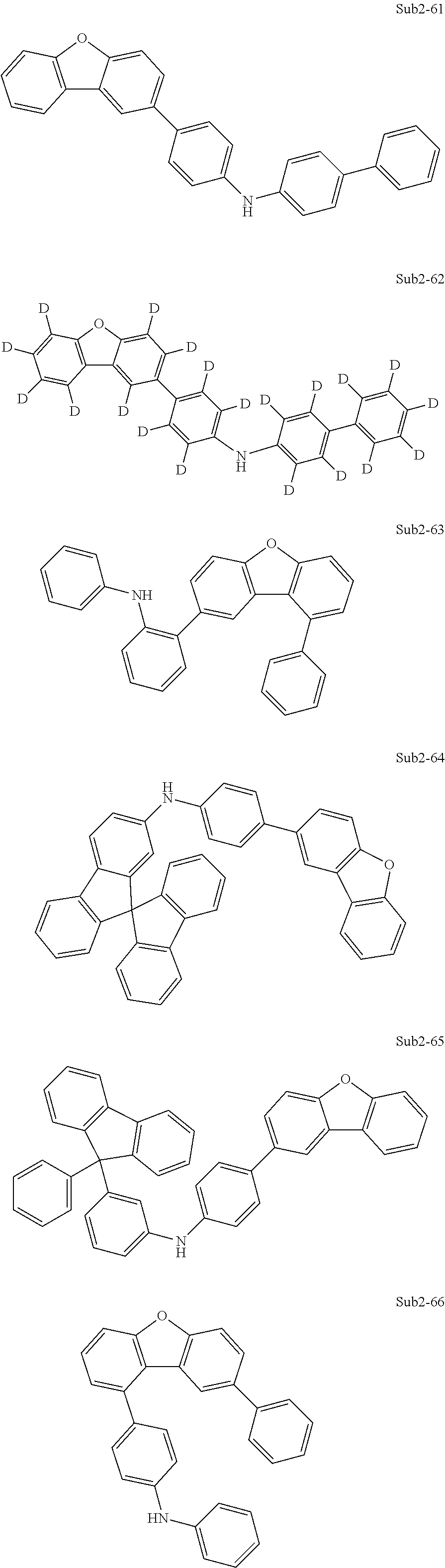 [SMILES: c1ccc(-c2ccc(Nc3ccc(-c4ccc5oc6ccccc6c5c4)cc3)cc2)cc1 ; [2H]c1c([2H])c([2H])c(-c2c([2H])c([2H])c(Nc3c([2H])c([2H])c(-c4c([2H])c([2H])c5oc6c([2H])c([2H])c([2H])c([2H])c6c5c4[2H])c([2H])c3[2H])c([2H])c2[2H])c([2H])c1[2H] ; c1ccc(Nc2ccccc2-c2ccc3oc4cccc(-c5ccccc5)c4c3c2)cc1 ; c1ccc2c(c1)-c1ccccc1C21c2ccccc2-c2ccc(Nc3ccc(-c4ccc5oc6ccccc6c5c4)cc3)cc21 ; c1ccc(C2(c3cccc(Nc4ccc(-c5ccc6oc7ccccc7c6c5)cc4)c3)c3ccccc3-c3ccccc32)cc1 ; c1ccc(Nc2ccc(-c3cccc4oc5ccc(-c6ccccc6)cc5c34)cc2)cc1]

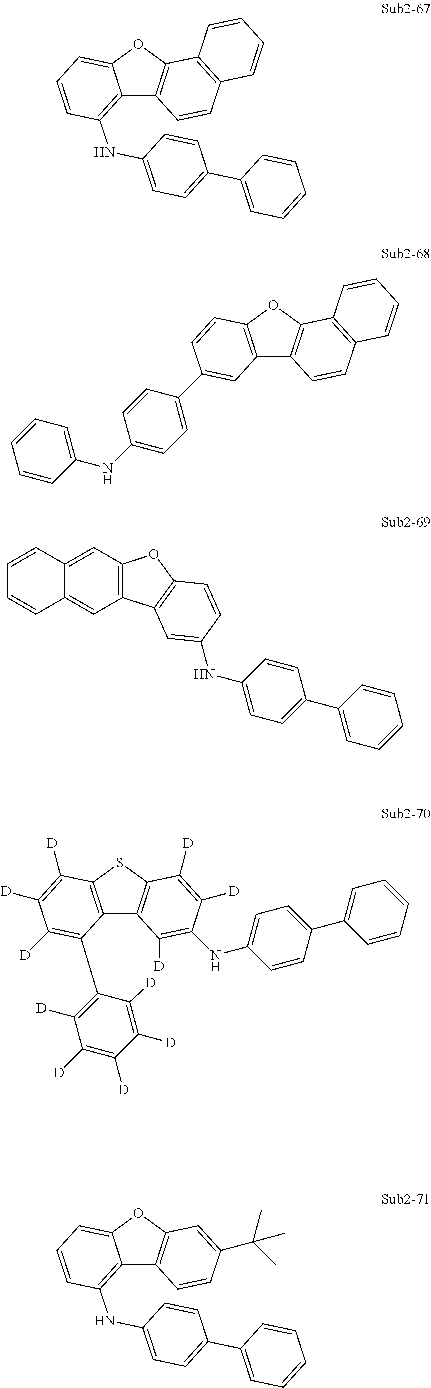 [SMILES: c1ccc(-c2ccc(Nc3cccc4oc5c6ccccc6ccc5c34)cc2)cc1 ; c1ccc(Nc2ccc(-c3ccc4oc5c6ccccc6ccc5c4c3)cc2)cc1 ; c1ccc(-c2ccc(Nc3ccc4oc5cc6ccccc6cc5c4c3)cc2)cc1 ; [2H]c1c([2H])c([2H])c(-c2c([2H])c([2H])c([2H])c3sc4c([2H])c([2H])c(Nc5ccc(-c6ccccc6)cc5)c([2H])c4c23)c([2H])c1[2H] ; CC(C)(C)c1ccc2c(c1)oc1cccc(Nc3ccc(-c4ccccc4)cc3)c12]

TABLE 2

| Com- | | Com- | |
|---|---|---|---|
| pound | FD-MS | pound | FD-MS |
| Sub2-1 | m/z = 321.15(C₂₄H₁₉N = 321.42) | Sub2-2 | m/z = 321.15(C₂₄H₁₉N = 321.42) |
| Sub2-3 | m/z = 321.15(C₂₄H₁₉N = 321.42) | Sub2-4 | m/z = 321.15(C₂₄H₁₉N = 321.42) |
| Sub2-5 | m/z = 339.26(C₂₄HD₁₈N = 339.53) | Sub2-6 | m/z = 473.21(C₃₆H₂₇N = 473.62) |
| Sub2-7 | m/z = 333.25(C₂₄H₃₁N = 333.52) | Sub2-8 | m/z = 397.28(C₂₉H₃₅N = 397.61) |
| Sub2-9 | m/z = 345.25(C₂₅H₃₁N = 345.53) | Sub2-10 | m/z = 363.29(C₂₆H₃₇N = 363.59) |
| Sub2-11 | m/z = 361.18(C₂₇H₂₃N = 361.49) | Sub2-12 | m/z = 361.18(C₂₇H₂₃N = 361.49) |
| Sub2-13 | m/Z = 377.28(C₂₇H₇D₁₆N = 377.59) | Sub2-14 | m/z = 437.21(C₃₃H₂₇N = 437.59) |
| Sub2-15 | m/z = 361.18(C₂₇H₂₃N = 361.49) | Sub2-16 | m/z = 375.2(C₂₈H₂₅N = 375.51) |
| Sub2-17 | m/z = 361.18(C₂₇H₂₃N = 361.49) | Sub2-18 | m/z = 401.21(C₃₀H₂₇N = 401.55) |
| Sub2-19 | m/z = 485.21(C₃₇H₂₇N = 485.63) | Sub2-20 | m/z = 561.25(C₄₃H₃₁N = 561.73) |
| Sub2-21 | m/z = 485.21(C₃₇H₂₇N = 485.63) | Sub2-22 | m/z = 485.21(C₃₇H₂₇N = 485.63) |
| Sub2-23 | m/z = 483.2(C₃₇H₂₅N = 483.61) | Sub2-24 | m/z = 483.2(C₃₇H₂₅N = 483.61) |
| Sub2-25 | m/z = 483.2(C₃₇H₂₅N = 483.61) | Sub2-26 | m/z = 559.23(C₄₃H₂₉N = 559.71) |
| Sub2-27 | m/z = 335.17(C₂₅H₂₁N = 335.45) | Sub2-28 | m/z = 485.21(C₃₇H₂₇N = 485.63) |
| Sub2-29 | m/z = 437.21(C₃₃H₂₇N = 437.59) | Sub2-30 | m/z = 437.21(C₃₃H₂₇N = 437.59) |
| Sub2-31 | m/z = 437.21(C₃₃H₂₇N = 437.59) | Sub2-32 | m/z = 483.2(C₃₇H₂₅N = 483.61) |
| Sub2-33 | m/z = 561.25(C₄₃H₃₁N = 561.73) | Sub2-34 | m/z = 589.42(C₄₃H₃D₂₈N = 589.9) |
| Sub2-35 | m/z = 559.23(C₄₃H₂₉N = 559.71) | Sub2-36 | m/z = 483.2(C₃₇H₂₅N = 483.61) |
| Sub2-37 | m/z = 351.11(C₂₄H₁₇NS = 351.47) | Sub2-38 | m/z = 351.11(C₂₄H₁₇NS = 351.47) |
| Sub2-39 | m/z = 351.11(C₂₄H₁₇NS = 351.47) | Sub2-40 | m/z = 441.12(C₃₀H₁₉NOS = 441.55) |
| Sub2-41 | m/z = 517.15(C₃₆H₂₃NOS = 517.65) | Sub2-42 | m/z = 351.11(C₂₄H₁₇NS = 351.47) |
| Sub2-43 | m/z = 427.14(C₃₀H₂₁NS = 427.56) | Sub2-44 | m/z = 391.14(C₂₇H₂₁NS = 391.53) |
| Sub2-45 | m/z = 335.13(C₂₄H₁₇NO = 335.41) | Sub2-46 | m/z = 335.13(C₂₄H₁₇NO = 335.41) |
| Sub2-47 | m/z = 451.19(C₃₃H₂₅NO = 451.57) | Sub2-48 | m/z = 335.13(C₂₄H₁₇NO = 335.41) |
| Sub2-49 | m/z = 351.23(C₂₄HD₁₆NO = 351.5) | Sub2-50 | m/z = 335.13(C₂₄H₁₇NO = 335.41) |
| Sub2-51 | m/z = 342.17(C₂₄H₁₀D₇NO = 342.45) | Sub2-52 | m/z = 411.16(C₃₀H₂₁NO = 411.5) |
| Sub2-53 | m/z = 375.16(C₂₇H₂₁NO = 375.47) | Sub2-54 | m/z = 375.16(C₂₇H₂₁NO = 375.47) |
| Sub2-55 | m/z = 375.16(C₂₇H₂₁NO = 375.47) | Sub2-56 | m/z = 458.24(C₃₃H₁₈D₇NO = 458.61) |
| Sub2-57 | m/z = 462.26(C₃₃H₁₄D₁₁NO = 462.64) | Sub2-58 | m/z = 411.16(C₃₀H₂₁NO = 411.5) |
| Sub2-59 | m/z = 335.13(C₂₄H₁₇NO = 335.41) | Sub2-60 | m/z = 411.16(C₃₀H₂₁NO = 411.5) |
| Sub2-61 | m/z = 411.16(C₃₀H₂₁NO = 411.5) | Sub2-62 | m/z = 431.29(C₃₀HD₂₀NO = 431.63) |
| Sub2-63 | m/z = 411.16(C₃₀H₂₁NO = 411.5) | Sub2-64 | m/z = 573.21(C₄₃H₂₇NO = 573.69) |
| Sub2-65 | m/z = 575.22(C₄₃H₂₉NO = 575.71) | Sub2-66 | m/z = 411.16(C₃₀H₂₁NO = 411.5) |
| Sub2-67 | m/z = 385.15(C₂₈H₁₉NO = 385.47) | Sub2-68 | m/z = 385.15(C₂₈H₁₉NO = 385.47) |
| Sub2-69 | m/z = 385.15(C₂₈H₁₉NO = 385.47) | Sub2-70 | m/z = 438.21(C₃₀H₁₀D₁₁NS = 438.63) |
| Sub2-71 | m/z = 391.19(C₂₈H₂₅NO = 391.51) | | |

### III. Synthesis of Final Product 1

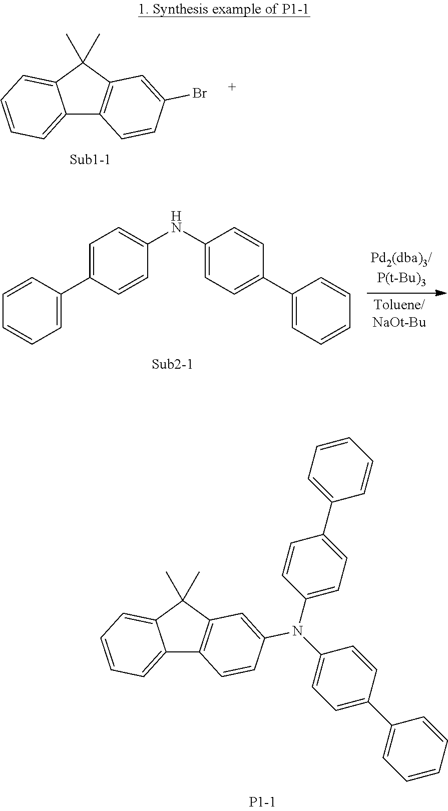 [SMILES: CC1(C)c2ccccc2-c2ccc(Br)cc21 ; c1ccc(-c2ccc(Nc3ccc(-c4ccccc4)cc3)cc2)cc1 ; CC1(C)c2ccccc2-c2ccc(N(c3ccc(-c4ccccc4)cc3)c3ccc(-c4ccccc4)cc3)cc21]

Sub1-1 (10.0 g, 36.6 mmol) is dissolved in toluene (185 mL) in a round bottom flask, Sub2-1 (11.8 g, 36.6 mmol), Pd₂(dba)₃ (1.01 g, 1.10 mmol), P(t-Bu)₃ (0.44 g, 2.20 mmol), NaOt-Bu (7.0 g, 73.2 mmol) are added and proceed with the reaction at 80° C. When the reaction is complete, extraction is performed with CH₂Cl₂ and water, and the organic layer is dried over MgSO₄ and concentrated. Afterwards, the produced organic material was recrystallized using a silicagel column to obtain 14.9 g of product. (yield 79%)

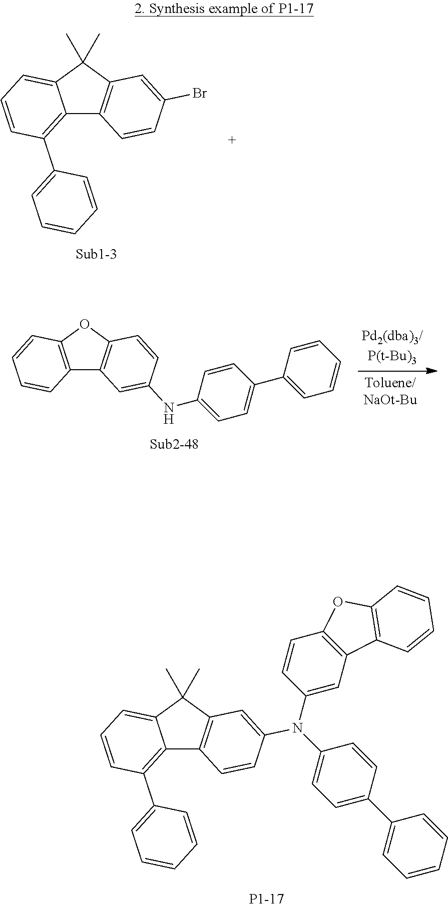 [SMILES: CC1(C)c2cc(Br)ccc2-c2c(-c3ccccc3)cccc21 ; c1ccc(-c2ccc(Nc3ccc4oc5ccccc5c4c3)cc2)cc1 ; CC1(C)c2cc(N(c3ccc(-c4ccccc4)cc3)c3ccc4oc5ccccc5c4c3)ccc2-c2c(-c3ccccc3)cccc21]

Sub1-3 (10.0 g, 28.6 mmol) is dissolved in toluene (145 mL) in a round bottom flask, Sub2-48 (9.6 g, 28.6 mmol), Pd₂(dba)₃ (0.79 g, 0.86 mmol), P(t-BU)₃ (0.35 g, 1.72 mmol), NaOt-Bu (5.5 g, 57.3 mmol) are added, and an experiment was performed in the same manner as in P1-1 to obtain 13.1 g of product. (yield 76%)

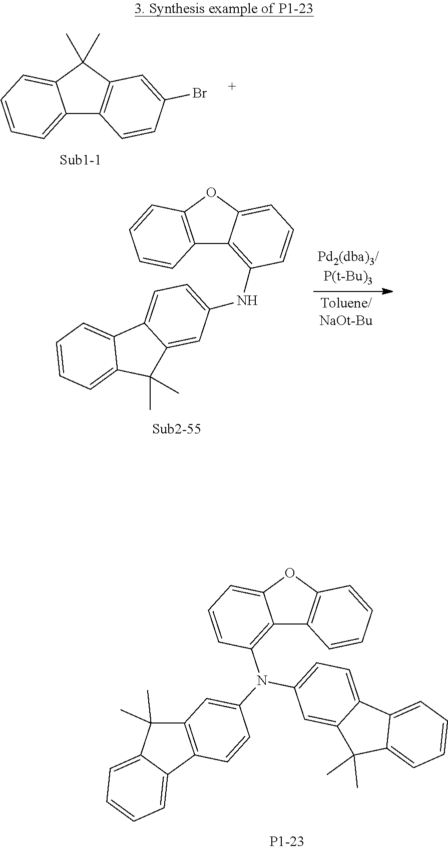 [SMILES: CC1(C)c2ccccc2-c2ccc(Br)cc21 ; CC1(C)c2ccccc2-c2ccc(Nc3cccc4oc5ccccc5c34)cc21 ; CC1(C)c2ccccc2-c2ccc(N(c3ccc4c(c3)C(C)(C)c3ccccc3-4)c3cccc4oc5ccccc5c34)cc21]

Sub1-1 (10.0 g, 36.6 mmol) is dissolved in toluene (185 mL) in a round bottom flask, Sub2-55 (13.7 g, 36.6 mmol), Pd₂(dba)₃ (1.01 g, 1.10 mmol), P(t-Bu)₃ (0.44 g, 2.20 mmol), NaOt-Bu (7.0 g, 73.2 mmol) are added, and an experiment was performed in the same manner as in P1-1 to obtain 15.0 g of product. (yield 72%)

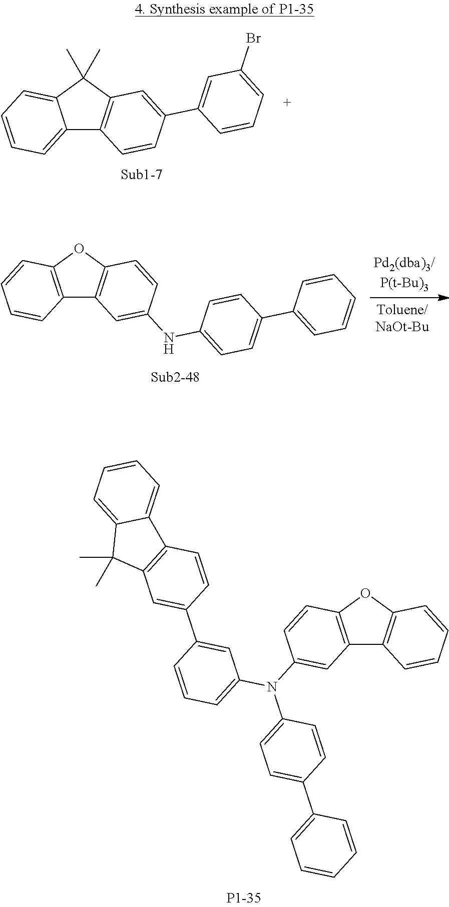 [SMILES: CC1(C)c2ccccc2-c2ccc(-c3cccc(Br)c3)cc21 ; c1ccc(-c2ccc(Nc3ccc4oc5ccccc5c4c3)cc2)cc1 ; CC1(C)c2ccccc2-c2ccc(-c3cccc(N(c4ccc(-c5ccccc5)cc4)c4ccc5oc6ccccc6c5c4)c3)cc21]

Sub1-7 (10.0 g, 28.6 mmol) is dissolved in toluene (145 mL) in a round bottom flask, Sub2-48 (9.6 g, 28.6 mmol), Pd₂(dba)₃ (0.79 g, 0.86 mmol), P(t-BU)₃ (0.35 g, 1.72 mmol), NaOt-Bu (5.5 g, 57.3 mmol) are added, and an experiment was performed in the same manner as in P1-1 to obtain 13.3 g of product. (yield 77%)

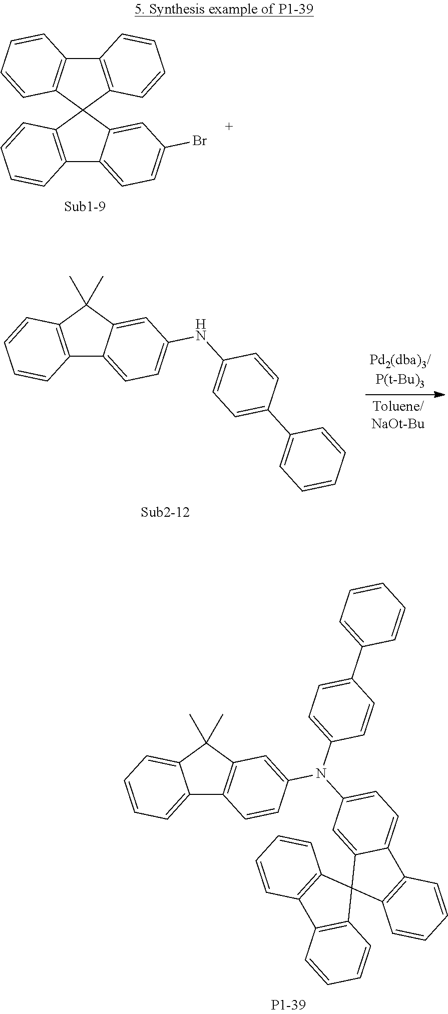 [SMILES: Brc1ccc2c(c1)C1(c3ccccc3-c3ccccc31)c1ccccc1-2 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

Sub1-9 (10.0 g, 25.3 mmol) is dissolved in toluene (130 mL) in a round bottom flask, Sub2-12 (9.1 g, 25.3 mmol), Pd₂(dba)₃ (0.69 g, 0.76 mmol), P(t-BU)₃ (0.31 g, 1.52 mmol), NaOt-Bu (4.9 g, 50.6 mmol) are added, and an experiment was performed in the same manner as in P1-1 to obtain 12.8 g of product. (yield 75%)

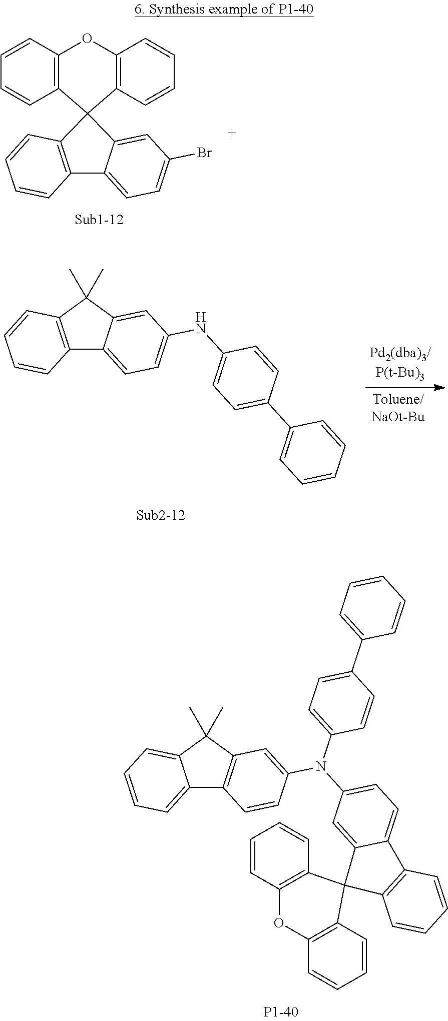 [SMILES: Brc1ccc2c(c1)C1(c3ccccc3Oc3ccccc31)c1ccccc1-2 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)C3(c5ccccc5Oc5ccccc53)c3ccccc3-4)cc21]

Sub1-12 (10.0 g, 24.3 mmol) is dissolved in toluene (125 mL) in a round bottom flask, Sub2-12 (8.8 g, 24.3 mmol), Pd₂(dba)₃ (0.67 g, 0.73 mmol), P(t-Bu)₃ (0.30 g, 1.46 mmol), NaOt-Bu (4.7 g, 48.6 mmol) are added, and an experiment was performed in the same manner as in P1-1 to obtain 12.8 g of product. (yield 76%)

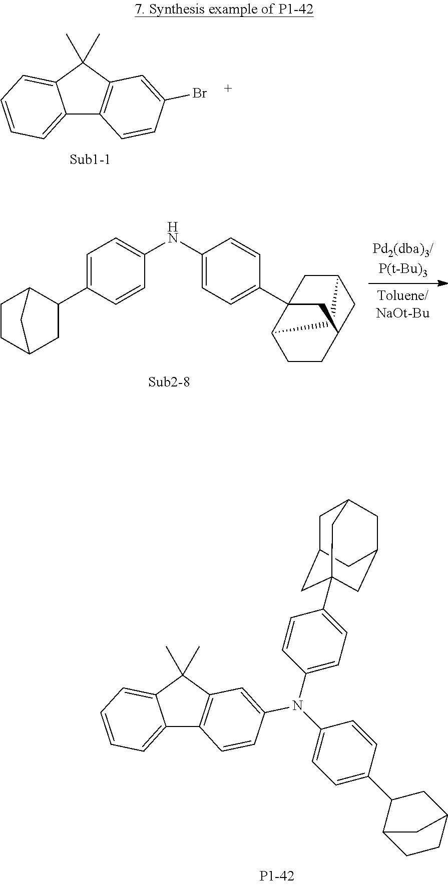 [SMILES: CC1(C)c2ccccc2-c2ccc(Br)cc21 ; c1cc(C2CC3CCC2C3)ccc1Nc1ccc(C23C[C@H]4CC[C@@H]2C[C@H](C4)C3)cc1 ; CC1(C)c2ccccc2-c2ccc(N(c3ccc(C4CC5CCC4C5)cc3)c3ccc(C45CC6CC(CC(C6)C4)C5)cc3)cc21]

Sub-1 (10.0 g, 36.6 mmol) is dissolved in toluene (185 mL) in a round bottom flask, Sub2-8 (14.6 g, 36.6 mmol), Pd₂(dba)₃ (1.01 g, 1.10 mmol), P(t-Bu)₃ (0.44 g, 2.20 mmol), NaOt-Bu (7.0 g, 73.2 mmol) are added, an experiment was performed in the same manner as in P1-1 to obtain 16.8 g of product. (yield 78%)

Meanwhile, the FD-MS values of compounds P1-1 to P1-52 of the present invention prepared according to the above synthesis examples are shown in Table 3.

TABLE 3

| Com- | | Com- | |
|---|---|---|---|
| pound | FD-MS | pound | FD-MS |
| P1-1 | m/z = 513.25(C₃₉H₃₁N = 513.68) | P1-2 | m/z = 513.25(C₃₉H₃₁N = 513.68) |
| P1-3 | m/z = 513.25(C₃₉H₃₁N = 513.68) | P1-4 | m/z = 513.25(C₃₉H₃₁N = 513.68) |
| P1-5 | m/z = 527.22(C₃₉H₂₉NO = 527.67) | P1-6 | m/z = 527.22(C₃₉H₂₉NO = 527.67) |
| P1-7 | m/z = 527.22(C₃₉H₂₉NO = 527.67) | P1-8 | m/z = 527.22(C₃₉H₂₉NO = 527.67) |
| P1-9 | m/z = 543.2(C₃₉H₂₉NS = 543.73) | P1-10 | m/z = 543.2(C₃₉H₂₉NS = 543.73) |
| P1-11 | m/z-543.2(C₃₉H₂₉NS = 543.73) | P1-12 | m/z = 543.2(C₃₉H₂₉NS = 543.73) |
| P1-13 | m/z = 553.28(C₄₂H₃₅N = 553.75) | P1-14 | m/z = 553.28(C₄₂H₃₅N = 553.75) |
| P1-15 | m/z = 553.28(C₄₂H₃₅N = 553.75) | P1-16 | m/z = 553.28(C₄₂H₃₅N = 553.75) |
| P1-17 | m/z = 603.26(C₄₅H₃₃NO = 603.76) | P1-18 | m/z = 603.26(C₄₅H₃₃NO = 603.76) |
| P1-19 | m/z = 705.34(C₅₄H₄₃N = 705.94) | P1-20 | m/z = 581.31(C₄₄H₃₉N = 581.8) |
| P1-21 | m/z = 567.26(C₄₂H₃₃NO = 567.73) | P1-22 | m/z = 567.26(C₄₂H₃₃NO = 567.73) |
| P1-23 | m/z = 567.26(C₄₂H₃₃NO-567.73) | P1-24 | m/z = 583.23(C₄₂H₃₃NS = 583.79) |
| P1-25 | m/z = 629.31(C₄₈H₃₉N = 629.85) | P1-26 | m/z = 629.31(C₄₈H₃₉N = 629.85) |
| P1-27 | m/z = 643.29(C₄₈H₃₇NO-643.83) | P1-28 | m/z = 629.31(C₄₈H₃₉N = 629.85) |
| P1-29 | m/z = 603.26(C₄₅H₃₃NO = 603.76) | P1-30 | m/z = 603.26(C₄₅H₃₃NO = 603.76) |
| P1-31 | m/z = 603.26(C₄₅H₃₃NO = 603.76) | P1-32 | m/z = 603.26(C₄₅H₃₃NO = 603.76) |
| P1-33 | m/z = 589.28(C₄₅H₃₅N = 589.78) | P1-34 | m/z = 589.28(C₄₅H₃₅N = 589.78) |
| P1-35 | m/z = 603.26(C₄₅H₃₃NO = 603.76) | P1-36 | m/z = 629.31(C₄₈H₃₉N = 629.85) |
| P1-37 | m/z = 753.34(C₅₈H₄₃N = 753.99) | P1-38 | m/z = 751.32(C₅₈H₄₁N = 751.97) |
| P1-39 | m/z = 675.29(C₅₂H₃₇N = 675.88) | P1-40 | m/z = 691.29(C₅₂H₃₇NO = 691.87) |
| P1-41 | m/z = 525.34(C₃₉H₄₃N = 525.78) | P1-42 | m/z = 589.37(C₄₄H₄₇N = 589.87) |
| P1-43 | m/z = 537.34(C₄₀H₄₃N = 537.79) | P1-44 | m/z = 555.39(C₄₁H₄₉N = 555.85) |
| P1-45 | m/z = 725.31(C₅₆H₃₉N = 725.93) | P1-46 | m/z = 741.3(C₅₆H₃₉NO = 741.93) |
| P1-47 | m/z = 577.24(C₄₃H₃₁NO = 577.73) | P1-48 | m/z = 527.26(C₄₀H₃₃N = 527.71) |
| P1-49 | m/z = 576.42(C₄₂H₁₂D₂₃N = 576.89) | P1-50 | m/z = 629.42(C₄₅H₇D₂₆NO = 629.92) |
| P1-51 | m/z = 788.56(C₅₈H₈D₃₅N = 789.2) | P1-52 | m/z = 702.46(C₅₂H₁₀D₂₇N = 703.04) |
| P1-53 | m/z = 635.36(C₄₈H₄₅N = 635.89) | P1-54 | m/z = 577.24(C₄₃H₃₁NO = 577.73) |
| P1-55 | m/z = 630.3(C₄₅H₂₂D₁₁NS = 630.89) | P1-56 | m/z = 583.29(C₄₃H₃₇NO = 583.77) |

### Synthesis Example 2

The compound represented by Formula 2 (Final Product 2) according to the present invention is synthesized by reacting Sub3 and Sub4 as shown in Reaction Scheme 2, but is not limited thereto.

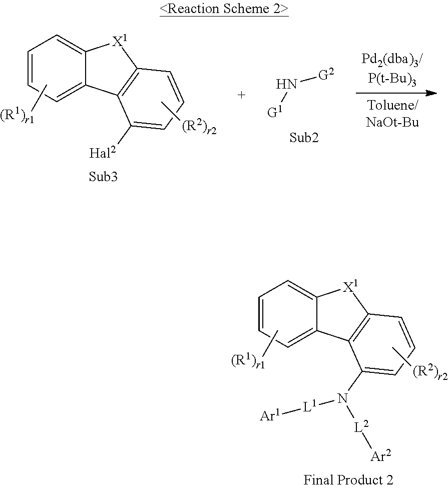

Wherein,
Hal² is Cl, Br or I,
G¹ is -L¹-Ar¹,
G² is -L²-Ar².

### I. Synthesis of Sub3

The compounds belonging to Sub3 in Reaction Scheme 2 may be, but are not limited to, the compounds below, and Table 4 shows the FD-MS values of the compounds belonging to Sub3.

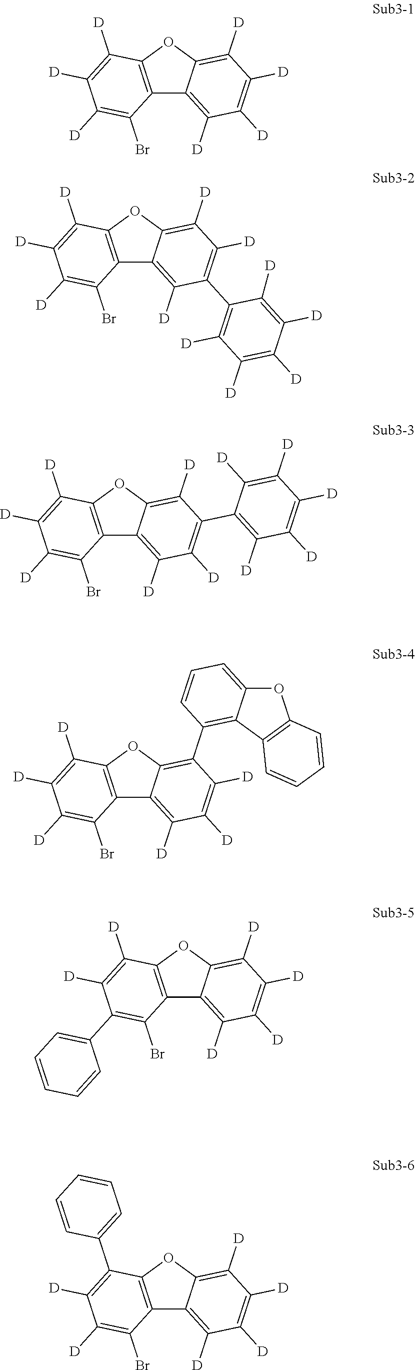

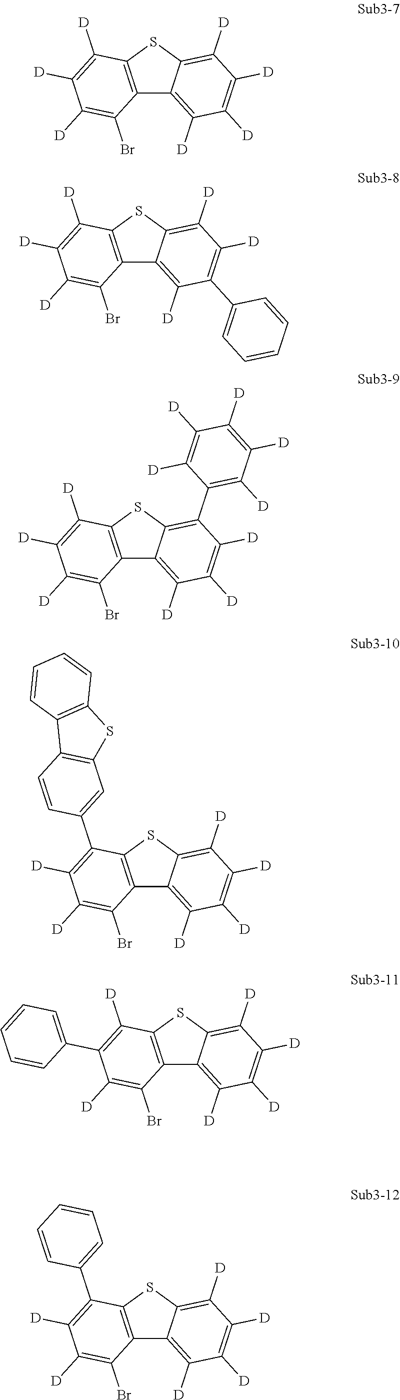

TABLE 4

| Com- | | Com- | |
|---|---|---|---|
| pound | FD-MS | pound | FD-MS |
| Sub3-1 | m/z = 253.01(C₁₂D₇BrO = 254.13) | Sub3-2 | m/z = 333.07(C₁₈D₁₁BrO = 334.26) |
| Sub3-3 | m/z = 333.07(C₁₈D₁₁BrO = 334.26) | Sub3-4 | m/z = 418.05(C₂₄H₇D₆BrO₂ = 419.31) |
| Sub3-5 | m/z = 328.04(C₁₈H₅D₆BrO = 329.23) | Sub3-6 | m/z = 328.04(C₁₈H₅D₆BrO = 329.23) |
| Sub3-7 | m/z = 268.99(C₁₂D₇BrS = 270.19) | Sub3-8 | m/z = 344.01(C₁₈H₅D₆BrS = 345.29) |
| Sub3-9 | m/z = 349.05(C₁₈D₁₁BrS = 350.32) | Sub3-10 | m/z = 450(C₂₄H₇D₆BrS₂ = 451.43) |
| Sub3-11 | m/z = 344.01(C₁₈H₅D₆BrS = 345.29) | Sub3-12 | m/z = 344.01(C₁₈H₅D₆BrS = 345.29) |

### II. Synthesis of Final Product 2

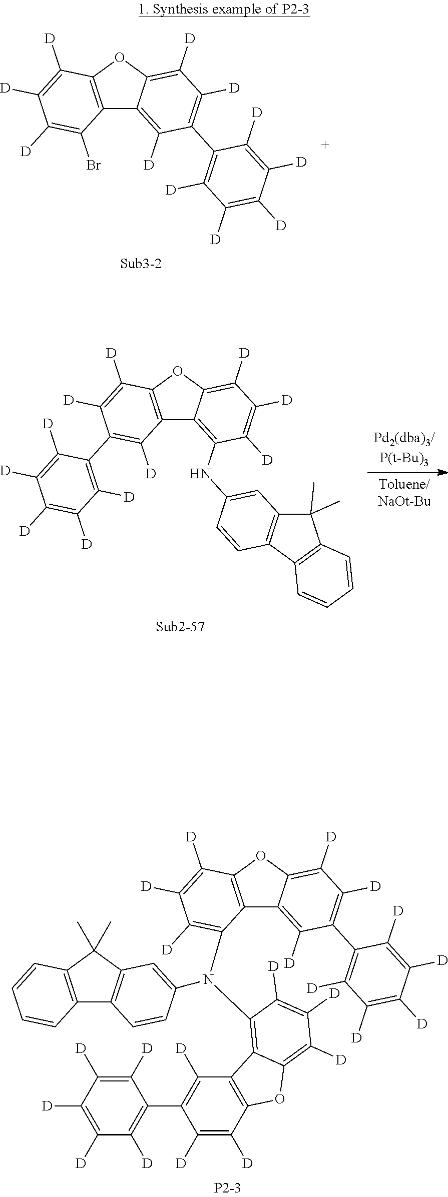 [SMILES: [2H]c1c([2H])c([2H])c(-c2c([2H])c([2H])c3oc4c([2H])c([2H])c([2H])c(Br)c4c3c2[2H])c([2H])c1[2H] ; [2H]c1c([2H])c([2H])c(-c2c([2H])c([2H])c3oc4c([2H])c([2H])c([2H])c(Nc5ccc6c(c5)C(C)(C)c5ccccc5-6)c4c3c2[2H])c([2H])c1[2H] ; [2H]c1c([2H])c([2H])c(-c2c([2H])c([2H])c3oc4c([2H])c([2H])c([2H])c(N(c5ccc6c(c5)C(C)(C)c5ccccc5-6)c5c([2H])c([2H])c([2H])c6oc7c([2H])c([2H])c(-c8c([2H])c([2H])c([2H])c([2H])c8[2H])c([2H])c7c56)c4c3c2[2H])c([2H])c1[2H]]

Sub3-2 (10.0 g, 29.9 mmol) is dissolved in toluene (150 mL) in a round bottom flask, Sub2-57 (13.8 g, 29.9 mmol), Pd₂(dba)₃ (0.82 g, 0.90 mmol), P(t-Bu)₃ (0.36 g, 1.80 mmol), NaOt-Bu (5.8 g, 59.8 mmol) are added and proceed with the reaction at 80° C. When the reaction is complete, extraction is performed with CH₂Cl₂ and water, and the organic layer is dried over MgSO₄ and concentrated. Afterwards, the produced organic material was recrystallized using a silicagel column to obtain 13.9 g of product. (yield 65%)

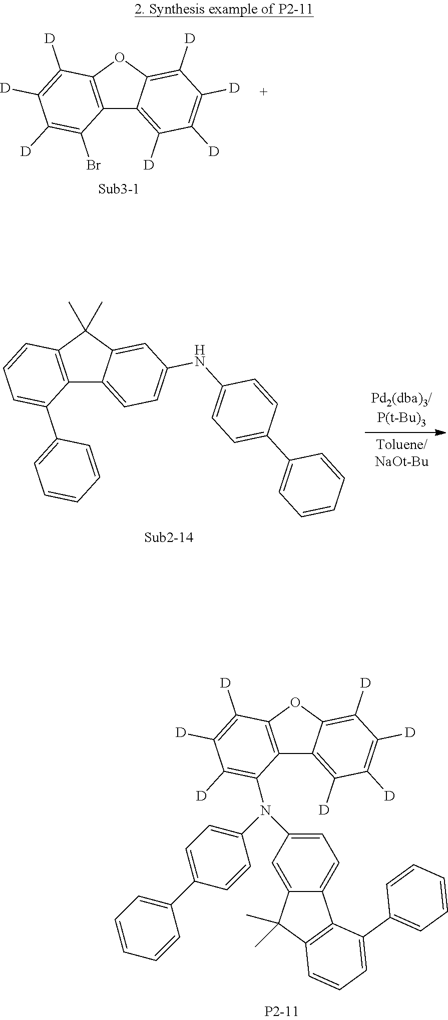 [SMILES: [2H]c1c([2H])c([2H])c2c(oc3c([2H])c([2H])c([2H])c(Br)c32)c1[2H] ; CC1(C)c2cc(Nc3ccc(-c4ccccc4)cc3)ccc2-c2c(-c3ccccc3)cccc21 ; [2H]c1c([2H])c([2H])c2c(oc3c([2H])c([2H])c([2H])c(N(c4ccc(-c5ccccc5)cc4)c4ccc5c(c4)C(C)(C)c4cccc(-c6ccccc6)c4-5)c32)c1[2H]]

Sub3-1 (10.0 g, 39.3 mmol) is dissolved in toluene (200 mL) in a round bottom flask, Sub2-14 (17.2 g, 39.3 mmol), Pd₂(dba)₃ (1.08 g, 1.18 mmol), P(t-Bu)₃ (0.48 g, 2.36 mmol), NaOt-Bu (7.6 g, 78.7 mmol) are added and the same experiment as P2-3 was performed to obtain 17.3 g of product. (yield 72%)

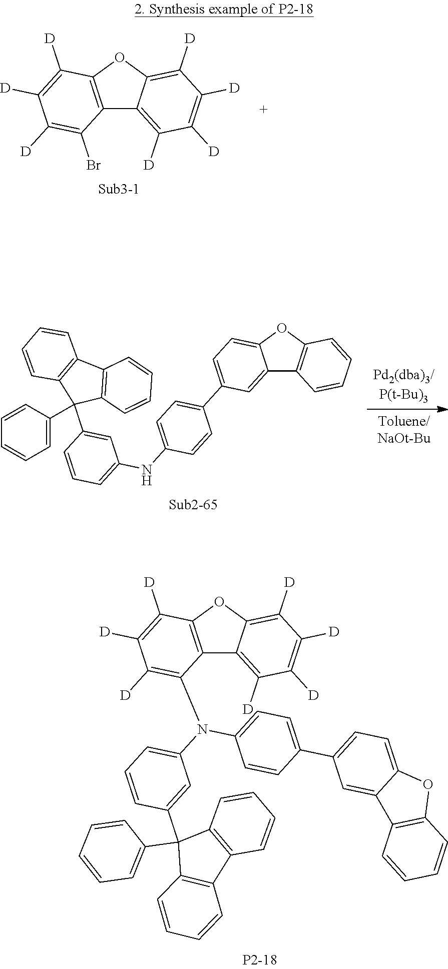 [SMILES: [2H]c1c([2H])c([2H])c2c(oc3c([2H])c([2H])c([2H])c(Br)c32)c1[2H] ; c1ccc(C2(c3cccc(Nc4ccc(-c5ccc6oc7ccccc7c6c5)cc4)c3)c3ccccc3-c3ccccc32)cc1 ; [2H]c1c([2H])c([2H])c2c(oc3c([2H])c([2H])c([2H])c(N(c4ccc(-c5ccc6oc7ccccc7c6c5)cc4)c4cccc(C5(c6ccccc6)c6ccccc6-c6ccccc65)c4)c32)c1[2H]]

Sub3-1 (10.0 g, 39.3 mmol) is dissolved in toluene (200 mL) in a round bottom flask, Sub2-65 (22.7 g, 39.3 mmol), Pd₂(dba)₃ (1.08 g, 1.18 mmol), P(t-Bu)₃ (0.48 g, 2.36 mmol), NaOt-Bu (7.6 g, 78.7 mmol) are added and the same experiment as P2-3 was performed to obtain 20.6 g of product. (yield 70%)

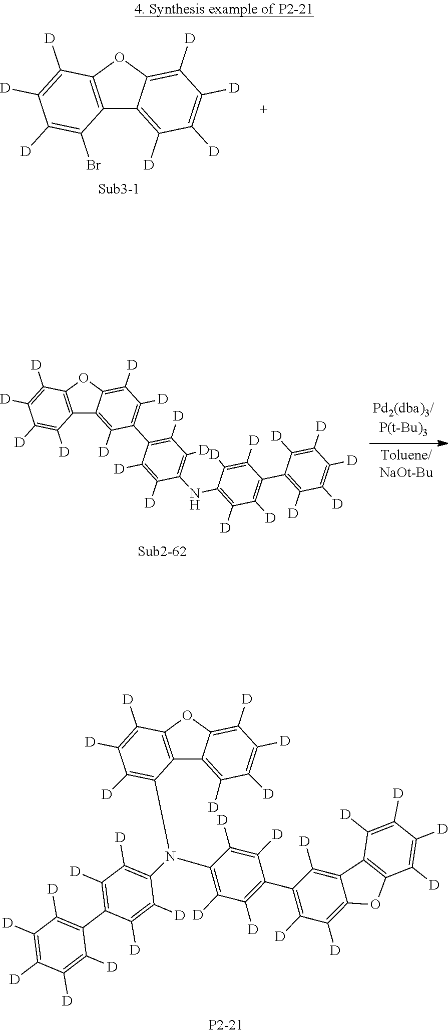 [SMILES: [2H]c1c([2H])c([2H])c2c(oc3c([2H])c([2H])c([2H])c(Br)c32)c1[2H] ; [2H]c1c([2H])c([2H])c(-c2c([2H])c([2H])c(Nc3c([2H])c([2H])c(-c4c([2H])c([2H])c5oc6c([2H])c([2H])c([2H])c([2H])c6c5c4[2H])c([2H])c3[2H])c([2H])c2[2H])c([2H])c1[2H] ; [2H]c1c([2H])c([2H])c(-c2c([2H])c([2H])c(N(c3c([2H])c([2H])c(-c4c([2H])c([2H])c5oc6c([2H])c([2H])c([2H])c([2H])c6c5c4[2H])c([2H])c3[2H])c3c([2H])c([2H])c([2H])c4oc5c([2H])c([2H])c([2H])c([2H])c5c34)c([2H])c2[2H])c([2H])c1[2H]]

Sub3-1 (10.0 g, 39.3 mmol) is dissolved in toluene (200 mL) in a round bottom flask, Sub2-62 (17.0 g, 39.3 mmol), Pd₂(dba)₃ (1.089 g, 1.18 mmol), P(t-Bu)₃ (0.48 g, 2.36 mmol), NaOt-Bu (7.6 g, 78.7 mmol) are added and the same experiment as P2-3 was performed to obtain 17.1 g of product. (yield 72%)

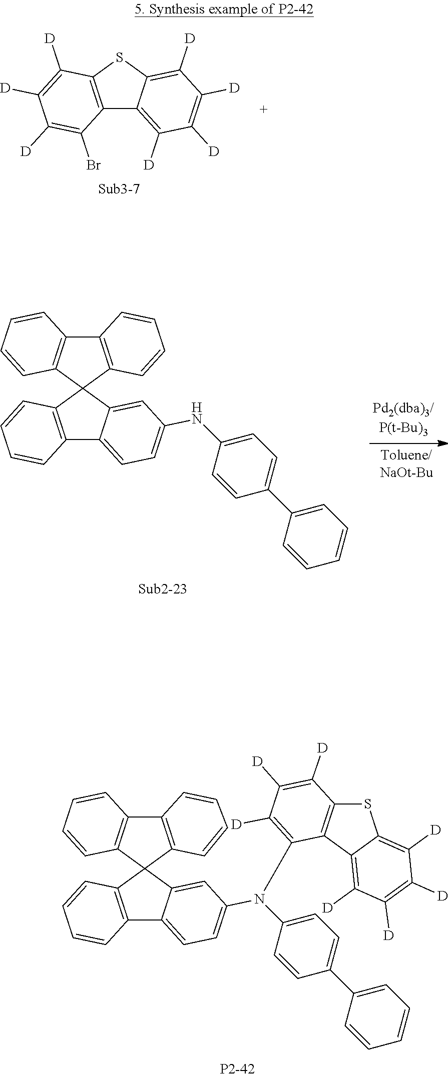 [SMILES: [2H]c1c([2H])c([2H])c2c(sc3c([2H])c([2H])c([2H])c(Br)c32)c1[2H] ; c1ccc(-c2ccc(Nc3ccc4c(c3)C3(c5ccccc5-c5ccccc53)c3ccccc3-4)cc2)cc1 ; [2H]c1c([2H])c([2H])c2c(sc3c([2H])c([2H])c([2H])c(N(c4ccc(-c5ccccc5)cc4)c4ccc5c(c4)C4(c6ccccc6-c6ccccc64)c4ccccc4-5)c32)c1[2H]]

Sub3-7 (10.0 g, 37.0 mmol) is dissolved in toluene (185 mL) in a round bottom flask, Sub2-23 (17.9 g, 37.0 mmol), Pd₂(dba)₃ (1.02 g, 1.11 mmol), P(t-Bu)₃ (0.45 g, 2.22 mmol), NaOt-Bu (7.1 g, 74.0 mmol) are added and the same experiment as P2-3 was performed to obtain 17.2 g of product. (yield 69%)

Meanwhile, the FD-MS values of compounds P2-1 to P2-52 of the present invention prepared according to the above synthesis examples are shown in Table 5.

TABLE 5

| Com- | | Com- | |
|---|---|---|---|
| pound | FD-MS | pound | FD-MS |
| P2-1 | m/z = 494.24(C₃₆H₁₈D₇NO = 494.64) | P2-2 | m/z = 508.22(C₃₆H₁₆D₇NO₂ = 508.63) |
| P2-3 | m/z = 715.4(C₅₁H₁₃D₂₂NO₂ = 715.98) | P2-4 | m/z = 515.26(C₃₆H₉D₁₄NO₂ = 515.67) |
| P2-5 | m/z = 534.27(C₃₉H₂₂D₇NO = 534.71) | P2-6 | m/z = 614.33(C₄₅H₂₂D₁₁NO = 614.83) |
| P2-7 | m/z = 584.25(C₄₂H₂₀D₇NO₂ = 584.73) | P2-8 | m/z = 654.36(C₄₈H₂₆D₁₁NO = 654.9) |
| P2-9 | m/z = 584.25(C₄₂H₂₀D₇NO₂ = 584.73) | P2-10 | m/z = 726.36(C₅₄H₂₆D₁₁NO = 726.96) |
| P2-11 | m/z = 610.3(C₄₅H₂₆D₇NO = 610.81) | P2-12 | m/z = 631.32(C₄₅H₁₇D₁₄NO₂ = 631.83) |
| P2-13 | m/z = 690.24(C₄₈H₂₂D₇NO₂S = 690.87) | P2-14 | m/z = 673.25(C₄₈H₂₃D₆NO₃ = 673.8) |
| P2-15 | m/z = 600.23(C₄₂H₂₀D₇NOS = 600.79) | P2-16 | m/z = 512.35(C₃₆D₂₅NO = 512.75) |
| P2-17 | m/z = 658.3(C₄₉H₂₆D₇NO = 658.85) | P2-18 | m/z = 748.31(C₅₅H₂₈D₇NO₂ = 748.93) |
| P2-19 | m/z = 584.25(C₄₂H₂₀D₇NO₂ = 584.73) | P2-20 | m/z = 614.2(C₄₂H₁₈D₇NO₂S = 614.77) |
| P2-21 | m/z = 604.37(C₄₂D₂₇NO₂ = 604.85) | P2-22 | m/z = 584.25(C₄₂H₂₀D₇NO₂ = 584.73) |
| P2-23 | m/z = 609.29(C₄₅H₂₇D₆NO = 609.8) | P2-24 | m/z = 658.3(C₄₉H₂₆D₇NO = 658.85) |
| P2-25 | m/z = 656.28(C₄₉H₂₄D₇NO = 656.84) | P2-26 | m/z = 656.28(C₄₉H₂₄D₇NO = 656.84) |
| P2-27 | m/z = 746.3(C₅₅H₂₆D₇NO₂ = 746.92) | P2-28 | m/z = 656.28(C₄₉H₂₄D₇NO = 656.84) |
| P2-29 | m/z = 656.28(C₄₉H₂₄D₇NO = 656.84) | P2-30 | m/z = 558.23(C₄₀H₁₈D₇NO₂ = 558.69) |
| P2-31 | m/z = 656.28(C₄₉H₂₄D₇NO = 656.84) | P2-32 | m/z = 658.3(C₄₉H₂₆D₇NO = 658.85) |
| P2-33 | m/z = 658.3(C₄₉H₂₆D₇NO = 658.85) | P2-34 | m/z = 732.32(C₅₅H₂₈D₇NO = 732.93) |
| P2-35 | m/z = 734.33(C₅₅H₃₀D₇NO = 734.95) | P2-36 | m/z = 583.24(C₄₂H₂₁D₆NO₂ = 583.72) |
| P2-37 | m/z = 510.21(C₃₆H₁₈D₇NS = 510.71) | P2-38 | m/z = 510.21(C₃₆H₁₈D₇NS = 510.71) |
| P2-39 | m/z = 550.25(C₃₉H₂₂D₇NS = 550.77) | P2-40 | m/z = 665.3(C₄₈H₃₁D₆NS = 665.93) |
| P2-41 | m/z = 626.28(C₄₅H₂₆D₇NS = 626.87) | P2-42 | m/z = 672.26(C₄₉H₂₄D₇NS = 672.9) |
| P2-43 | m/z = 749.3(C₅₅H₃₁D₆NS = 750) | P2-44 | m/z = 580.2(C₃₉H₂₀D₇NS₂ = 580.81) |
| P2-45 | m/z = 620.35(C₄₂D₂₇NOS = 620.91) | P2-46 | m/z = 600.23(C₄₂H₂₀D₇NOS = 600.79) |
| P2-47 | m/z = 620.23(C₄₂H₁₆D₁₁NS₂ = 620.87) | P2-48 | m/z = 855.29(C₆₁H₃₃D₆NS₂ = 856.15) |
| P2-49 | m/z = 564.26(C₄₀H₂₄D₈NS = 564.8) | P2-50 | m/z = 599.22(C₄₂H₂₁D₆NOS = 599.78) |
| P2-51 | m/z = 566.35(C₃₉H₆D₂₃NS = 566.87) | P2-52 | m/z = 599.22(C₄₂H₂₁D₆NOS = 599.78) |

Meanwhile, an exemplary synthesis example of the present invention represented by Formula 1 or Formula 2 has been described above, but these are all based on the Buchwald-Hartwig cross coupling reaction, Miyaura boration reaction, Suzuki cross-coupling reaction, Intramolecular acid-induced cyclization reaction (J. mater. Chem. 1999, 9, 2095), Pd(II)-catalyzed oxidative cyclization reaction (Org. Lett. 2011, 13, 5504), and PPh₃-mediated reductive cyclization reaction (J. Org. Chem. 2005, 70, 5014), and those skilled in the art will easily understand that the above reaction proceeds even if substituents other than those specified in the specific synthesis examples are bonded to.

### Manufacturing Evaluation of Organic Electronic Elements

### [Example 1] Red Organic Light Emitting Device

First, a hole injection layer was formed by vacuum depositing 4,4′,4″-Tris[2-naphthyl(phenyl)amino]triphenylamine (hereinafter abbreviated as 2-TNATA) to a thickness of 70 nm on the ITO layer (anode) formed on the glass substrate, N,N′-bis(1-naphthalenyl)-N,N′-bis-phenyl-(1,1′-biphenyl)-4,4′-diamine (hereinafter abbreviated as NPB) as a hole transport compound was vacuum deposited to a thickness of 70 nm on the hole injection layer to form a hole transport layer. Next, the compound P1-3 of the present invention was vacuum deposited to a thickness of 70 nm on the hole transport layer to form a first emitting-auxiliary layer, and then compound P2-11 of the present invention was vacuum deposited on the first emitting-auxiliary layer to a thickness of 5 nm to form a second emitting-auxiliary layer. Subsequently, on the second emitting-auxiliary layer, 4,4′-N,N′-dicarbazole-biphenyl (hereinafter abbreviated as CPB) was used as a host material and bis-(1-phenylisoquinolyl)iridium(III)acetylacetonate (hereinafter abbreviated as (piq)₂Ir(acac)) was used as a dopant material, and the emitting layer was formed by vacuum deposition to a thickness of 40 nm by doping at a weight ratio of 95:5. Next, 2,9-dimethyl-4,7-diphenyl-1,10-phenanthroline (hereinafter abbreviated as BCP) was vacuum deposited to a thickness of 30 nm on the emitting layer to form an electron transport layer. Afterwards, LiF, a halogenated alkali metal, was deposited on the electron transport layer to a thickness of 0.2 nm to form an electron injection layer, and then an organic electroluminescent device was manufactured by depositing Al on the electron injection layer to a thickness of 150 nm to form a cathode.

### [Example 2] to [Example 40] and [Comparative Example 1]

An organic light emitting device was manufactured in the same manner as in Example 1, except that the compounds of the present invention shown in Table 6 were used as the materials for the first and second emitting-auxiliary layers instead of P1-3 and P2-11.

To the organic electroluminescent device manufactured by the Examples and Comparative Example, Electroluminescence (EL) characteristics were measured with a PR-650 of Photoresearch Co., by applying a forward bias DC voltage. As a result of the measurement, T95 life was measured at a standard luminance of 2,500 cd/m² through life measuring apparatus manufactured by McScience. Table 6 shows the results of manufacturing evaluation of the element.

This measuring apparatus is unaffected by possible daily fluctuations in deposition rate, vacuum quality or other parameters, and can evaluate the performance of a new material compared to a comparative compound under the same conditions.

In the evaluation, since one batch contains 4 identically prepared OLEDs including the comparative compound, and the performance of a total of 12 OLEDs is evaluated in 3 batches, the experimental results obtained in this way show statistical significance.

TABLE 6

| | first | second | | Current | | |
|---|---|---|---|---|---|---|
| | emitting- | emitting- | | Density | | |
| | auxiliary | auxiliary | Volt- | (mA/ | Efficiency | |
| | layer | layer | tage | cm²) | (cd/A) | T(95) |
| Comparative | Compound | Compound | 5.1 | 8.7 | 28.9 | 123.4 |
| example (1) | (P1-42) | (P1-18) | | | | |
| Example | Compound | Compound | 4.9 | 7.3 | 34.3 | 138.6 |
| (1) | (P1-3) | (P2-11) | | | | |
| Example | Compound | Compound | 4.9 | 7.2 | 34.6 | 133.7 |
| (2) | (P1-3) | (P2-23) | | | | |
| Example | Compound | Compound | 4.9 | 7.2 | 34.5 | 136.5 |
| (3) | (P1-3) | (P2-24) | | | | |
| Example | Compound | Compound | 4.9 | 7.1 | 35.1 | 130.7 |
| (4) | (P1-3) | (P2-40) | | | | |
| Example | Compound | Compound | 5.0 | 7.5 | 33.4 | 144.0 |
| (5) | (P1-3) | (P2-52) | | | | |
| Example | Compound | Compound | 4.6 | 6.9 | 36.1 | 143.0 |
| (6) | (P1-7) | (P2-11) | | | | |
| Example | Compound | Compound | 4.6 | 6.9 | 36.5 | 137.9 |
| (7) | (P1-7) | (P2-23) | | | | |
| Example | Compound | Compound | 4.6 | 6.9 | 36.4 | 140.9 |
| (8) | (P1-7) | (P2-24) | | | | |
| Example | Compound | Compound | 4.6 | 6.8 | 37.0 | 134.8 |
| (9) | (P1-7) | (P2-40) | | | | |
| Example | Compound | Compound | 4.7 | 7.1 | 35.2 | 148.6 |
| (10) | (P1-7) | (P2-52) | | | | |
| Example | Compound | Compound | 4.6 | 6.8 | 36.7 | 141.1 |
| (11) | (P1-11) | (P2-11) | | | | |
| Example | Compound | Compound | 4.6 | 6.8 | 37.0 | 136.0 |
| (12) | (P1-11) | (P2-23) | | | | |
| Example | Compound | Compound | 4.6 | 6.8 | 36.9 | 139.0 |
| (13) | (P1-11) | (P2-24) | | | | |
| Example | Compound | Compound | 4.5 | 6.7 | 37.6 | 133.0 |
| (14) | (P1-11) | (P2-40) | | | | |
| Example | Compound | Compound | 4.6 | 7.0 | 35.7 | 146.6 |
| (15) | (P1-11) | (P2-52) | | | | |
| Example | Compound | Compound | 4.5 | 6.8 | 36.9 | 142.3 |
| (16) | (P1-14) | (P2-11) | | | | |
| Example | Compound | Compound | 4.5 | 6.7 | 37.3 | 137.2 |
| (17) | (P1-14) | (P2-23) | | | | |
| Example | Compound | Compound | 4.5 | 6.7 | 37.2 | 140.2 |
| (18) | (P1-14) | (P2-24) | | | | |
| Example | Compound | Compound | 4.5 | 6.6 | 37.8 | 134.2 |
| (19) | (P1-14) | (P2-40) | | | | |
| example | compound | compound | 4.5 | 6.9 | 36.0 | 147.8 |
| (20) | (P1-14) | (P2-52) | | | | |
| Example | compound | compound | 4.7 | 7.0 | 35.7 | 144.3 |
| (21) | (P1-30) | (P2-11) | | | | |
| Example | Compound | Compound | 4.6 | 6.9 | 36.0 | 139.1 |
| (22) | (P1-30) | (P2-23) | | | | |
| Example | Compound | Compound | 4.7 | 7.0 | 35.9 | 142.1 |
| (23) | (P1-30) | (P2-24) | | | | |
| Example | Compound | Compound | 4.6 | 6.8 | 36.5 | 136.0 |
| (24) | (P1-30) | (P2-40) | | | | |
| Example | Compound | Compound | 4.7 | 7.2 | 34.7 | 149.8 |
| (25) | (P1-30) | (P2-52) | | | | |
| Example | Compound | Compound | 4.8 | 7.2 | 34.9 | 139.4 |
| (26) | (P1-36) | (P2-11) | | | | |
| Example | Compound | Compound | 4.7 | 7.1 | 35.3 | 134.5 |
| (27) | (P1-36) | (P2-23) | | | | |
| Example | Compound | Compound | 4.8 | 7.1 | 35.2 | 137.3 |
| (28) | (P1-36) | (P2-24) | | | | |
| Example | Compound | Compound | 4.7 | 7.0 | 35.8 | 131.4 |
| (29) | (P1-36) | (P2-40) | | | | |
| Example | Compound | Compound | 4.8 | 7.3 | 34.1 | 144.8 |
| (30) | (P1-36) | (P2-52) | | | | |
| Example | Compound | Compound | 4.7 | 7.1 | 35.3 | 140.3 |
| (31) | (P1-42) | (P2-11) | | | | |
| Example | Compound | Compound | 4.7 | 7.0 | 35.7 | 135.3 |
| (32) | (P1-42) | (P2-23) | | | | |
| Example | Compound | Compound | 4.7 | 7.0 | 35.6 | 138.2 |
| (33) | (P1-42) | (P2-24) | | | | |
| Example | Compound | Compound | 4.7 | 6.9 | 36.2 | 132.2 |
| (34) | (P1-42) | (P2-40) | | | | |
| Example | Compound | Compound | 4.8 | 7.3 | 34.4 | 145.7 |
| (35) | (P1-42) | (P2-52) | | | | |
| Example | Compound | Compound | 5.0 | 7.4 | 33.9 | 137.9 |
| (36) | (P1-48) | (P2-11) | | | | |
| Example | Compound | Compound | 4.9 | 7.3 | 34.2 | 133.0 |
| (37) | (P1-48) | (P2-23) | | | | |
| Example | Compound | Compound | 5.0 | 7.3 | 34.1 | 135.9 |
| (38) | (P1-48) | (P2-24) | | | | |
| Example | Compound | Compound | 4.9 | 7.2 | 34.7 | 130.0 |
| (39) | (P1-48) | (P2-40) | | | | |
| Example | Compound | Compound | 5.0 | 7.6 | 33.0 | 143.3 |
| (40) | (P1-48) | (P2-52) | | | | |

### [Example 41] Green Organic Light Emitting Device

First, 2-TNATA was vacuum deposited to a thickness of 70 nm on an ITO layer (anode) formed on a glass substrate to form a hole injection layer, and then NPB was vacuum deposited to a thickness of 70 nm as a hole transport compound on the hole injection layer to form a hole transport layer. Subsequently, the compound P1-1 of the present invention was vacuum deposited to a thickness of 30 nm on the hole transport layer to form a first emitting-auxiliary layer, and then Compound P2-3 of the present invention was vacuum deposited on the first emitting-auxiliary layer to a thickness of 5 nm to form a second emitting-auxiliary layer. Subsequently, on the second emitting-auxiliary layer, CBP was used as a host material and tris(2-phenylpyridine)-iridium was used as a dopant material, and an emitting layer was formed by vacuum deposition to a thickness of 40 nm by doping at a weight ratio of 95:5. Next, BCP was vacuum deposited to a thickness of 30 nm on the emitting layer to form an electron transport layer. Afterwards, LiF, a halogenated alkali metal, was deposited on the electron transport layer to a thickness of 0.2 nm to form an electron injection layer, and then Al was deposited on the electron injection layer to a thickness of 150 nm to form a cathode, thereby an organic electroluminescent device was manufactured.

### [Example 42] to [Example 94] and [Comparative Example 2] to [Comparative Example 5]

An organic light emitting device was manufactured in the same manner as in Example 41, except that the compounds of the present invention shown in Table 7 were used as the materials for the first and second emitting-auxiliary layers instead of P1-1 and P2-3.

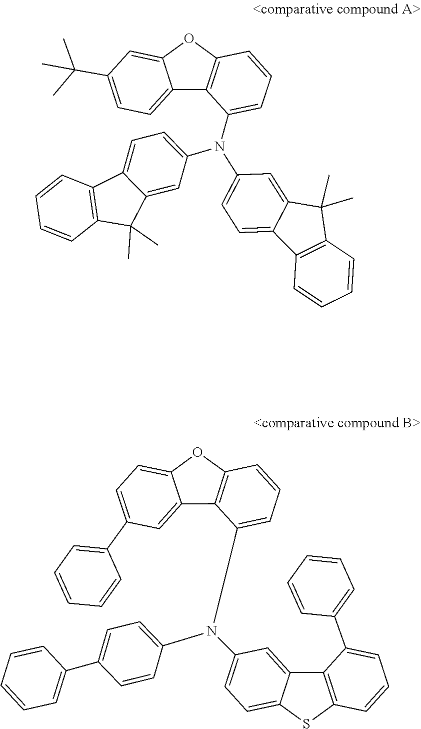 [SMILES: CC(C)(C)c1ccc2c(c1)oc1cccc(N(c3ccc4c(c3)C(C)(C)c3ccccc3-4)c3ccc4c(c3)C(C)(C)c3ccccc3-4)c12 ; c1ccc(-c2ccc(N(c3ccc4sc5cccc(-c6ccccc6)c5c4c3)c3cccc4oc5ccc(-c6ccccc6)cc5c34)cc2)cc1]

To the organic electroluminescent device manufactured by the Examples and Comparative Example, Electroluminescence (EL) characteristics were measured with a PR-650 of Photoresearch Co., by applying a forward bias DC voltage. As a result of the measurement, T95 life was measured at a standard luminance of 5,000 cd/m² through life measuring apparatus manufactured by McScience. Table 7 shows the results of manufacturing evaluation of the element.

This measuring apparatus is unaffected by possible daily fluctuations in deposition rate, vacuum quality or other parameters, and can evaluate the performance of a new material compared to a comparative compound under the same conditions.

In the evaluation, since one batch contains 4 identically prepared OLEDs including the comparative compound, and the performance of a total of 12 OLEDs is evaluated in 3 batches, the experimental results obtained in this way show statistical significance.

TABLE 7

| | first | second | | Current | | |
|---|---|---|---|---|---|---|
| | emitting- | emitting- | | Density | Effi- | |
| | auxiliary | auxiliary | Volt- | (mA/ | ciency | |
| | layer | layer | age | cm²) | (cd/A) | T(95) |
| Comparative | Comparative | Compound | 5.2 | 6.3 | 39.4 | 102.1 |
| example (2) | Compound A | (P1-18) | | | | |
| Comparative | Comparative | Compound | 5.4 | 6.5 | 38.6 | 96.8 |
| example (3) | compound B | (P1-18) | | | | |
| Comparative | Compound | Compound | 5.1 | 5.9 | 42.3 | 110.6 |
| example (4) | (P1-14) | (P1-18) | | | | |
| Comparative | Compound | Comparative | 5.2 | 6.2 | 40.1 | 105.4 |
| example (5) | (P1-14) | compound A | | | | |
| Example | Compound | Compound | 4.8 | 5.0 | 49.9 | 128.3 |
| (41) | (P1-1) | (P2-3) | | | | |
| Example | Compound | Compound | 4.8 | 5.1 | 48.8 | 127.9 |
| (42) | (P1-1) | (P2-6) | | | | |
| Example | Compound | Compound | 4.8 | 5.1 | 49.3 | 133.9 |
| (43) | (P1-1) | (P2-7) | | | | |
| Example | Compound | Compound | 4.7 | 5.0 | 49.7 | 126.6 |
| (44) | (P1-1) | (P2-8) | | | | |
| Example | Compound | Compound | 4.9 | 5.2 | 48.0 | 127.4 |
| (45) | (P1-1) | (P2-12) | | | | |
| Example | Compound | Compound | 4.8 | 5.1 | 48.6 | 129.3 |
| (46) | (P1-1) | (P2-18) | | | | |
| Example | Compound | Compound | 4.8 | 5.1 | 49.0 | 134.9 |
| (47) | (P1-1) | (P2-21) | | | | |
| Example | Compound | Compound | 4.9 | 5.3 | 47.5 | 129.8 |
| (48) | (P1-1) | (P2-27) | | | | |
| Example | Compound | Compound | 4.8 | 5.1 | 49.4 | 132.0 |
| (49) | (P1-1) | (P2-46) | | | | |
| Example | Compound | Compound | 4.6 | 4.9 | 51.4 | 122.0 |
| (50) | (P1-14) | (P2-3) | | | | |
| Example | Compound | Compound | 4.8 | 5.1 | 48.8 | 127.9 |
| (51) | (P1-14) | (P2-6) | | | | |
| Example | Compound | Compound | 4.7 | 4.9 | 50.7 | 127.3 |
| (52) | (P1-14) | (P2-7) | | | | |
| Example | Compound | Compound | 4.7 | 5.0 | 49.7 | 126.6 |
| (53) | (P1-14) | (P2-8) | | | | |
| Example | compound | compound | 4.7 | 5.1 | 49.4 | 121.1 |
| (54) | (P1-14) | (P2-12) | | | | |
| Example | compound | compound | 4.7 | 5.0 | 50.0 | 122.9 |
| (55) | (P1-14) | (P2-18) | | | | |
| Example | compound | compound | 4.7 | 5.0 | 50.4 | 128.2 |
| (56) | (P1-14) | (P2-21) | | | | |
| Example | Compound | Compound | 4.8 | 5.1 | 48.9 | 123.4 |
| (57) | (P1-14) | (P2-27) | | | | |
| Example | Compound | Compound | 4.7 | 4.9 | 50.9 | 125.5 |
| (58) | (P1-14) | (P2-46) | | | | |
| Example | Compound | Compound | 4.7 | 4.8 | 51.8 | 127.2 |
| (59) | (P1-29) | (P2-3) | | | | |
| Example | Compound | Compound | 4.7 | 5.0 | 50.2 | 121.6 |
| (60) | (P1-29) | (P2-6) | | | | |
| Example | Compound | Compound | 4.7 | 4.9 | 51.2 | 132.8 |
| (61) | (P1-29) | (P2-7) | | | | |
| Example | Compound | Compound | 4.6 | 4.9 | 51.1 | 120.3 |
| (62) | (P1-29) | (P2-8) | | | | |
| Example | Compound | Compound | 4.8 | 5.0 | 49.9 | 126.4 |
| (63) | (P1-29) | (P2-12) | | | | |
| Example | Compound | Compound | 4.8 | 5.0 | 50.5 | 128.2 |
| (64) | (P1-29) | (P2-18) | | | | |
| Example | Compound | Compound | 4.7 | 4.9 | 50.9 | 133.8 |
| (65) | (P1-29) | (P2-21) | | | | |
| Example | Compound | Compound | 4.8 | 5.1 | 49.3 | 128.7 |
| (66) | (P1-29) | (P2-27) | | | | |
| Example | Compound | Compound | 4.7 | 4.9 | 51.3 | 130.9 |
| (67) | (P1-29) | (P2-46) | | | | |
| Example | Compound | Compound | 4.8 | 5.1 | 49.4 | 123.3 |
| (68) | (P1-37) | (P2-3) | | | | |
| Example | Compound | Compound | 4.7 | 4.9 | 50.7 | 126.9 |
| (69) | (P1-37) | (P2-6) | | | | |
| Example | Compound | Compound | 4.9 | 5.1 | 48.8 | 128.7 |
| (70) | (P1-37) | (P2-7) | | | | |
| Example | Compound | Compound | 4.7 | 4.8 | 51.6 | 125.5 |
| (71) | (P1-37) | (P2-8) | | | | |
| Example | Compound | Compound | 4.9 | 5.3 | 47.5 | 122.5 |
| (72) | (P1-37) | (P2-12) | | | | |
| Example | Compound | Compound | 4.9 | 5.2 | 48.1 | 124.3 |
| (73) | (P1-37) | (P2-18) | | | | |
| Example | Compound | Compound | 4.9 | 5.2 | 48.5 | 129.7 |
| (74) | (P1-37) | (P2-21) | | | | |
| Example | Compound | Compound | 4.9 | 5.3 | 47.0 | 124.8 |
| (75) | (P1-37) | (P2-27) | | | | |
| Example | Compound | Compound | 4.8 | 5.1 | 48.9 | 126.9 |
| (76) | (P1-37) | (P2-46) | | | | |
| Example | Compound | Compound | 4.9 | 5.2 | 48.5 | 124.9 |
| (77) | (P1-39) | (P2-3) | | | | |
| Example | Compound | Compound | 4.8 | 5.2 | 48.3 | 123.0 |
| (78) | (P1-39) | (P2-6) | | | | |
| Example | Compound | Compound | 4.9 | 5.2 | 47.9 | 130.3 |
| (79) | (P1-39) | (P2-7) | | | | |
| Example | Compound | Compound | 4.8 | 5.1 | 49.2 | 121.6 |
| (80) | (P1-39) | (P2-8) | | | | |
| Example | Compound | Compound | 5.0 | 5.4 | 46.6 | 124.0 |
| (81) | (P1-39) | (P2-12) | | | | |
| Example | Compound | Compound | 5.0 | 5.3 | 47.2 | 125.9 |
| (82) | (P1-39) | (P2-18) | | | | |
| Example | Compound | Compound | 4.9 | 5.3 | 47.6 | 131.3 |
| (83) | (P1-39) | (P2-21) | | | | |
| Example | Compound | Compound | 5.0 | 5.4 | 46.1 | 126.4 |
| (84) | (P1-39) | (P2-27) | | | | |
| Example | Compound | Compound | 4.9 | 5.2 | 48.0 | 128.5 |
| (85) | (P1-39) | (P2-46) | | | | |
| Example | Compound | Compound | 4.7 | 4.9 | 50.9 | 125.9 |
| (86) | (P1-40) | (P2-3) | | | | |
| example | compound | compound | 4.9 | 5.3 | 47.3 | 124.5 |
| (87) | (P1-40) | (P2-6) | | | | |
| example | compound | compound | 4.8 | 5.0 | 50.2 | 131.4 |
| (88) | (P1-40) | (P2-7) | | | | |
| example | compound | compound | 4.9 | 5.2 | 48.2 | 123.2 |
| (89) | (P1-40) | (P2-8) | | | | |
| example | compound | compound | 4.8 | 5.1 | 48.9 | 125.0 |
| (90) | (P1-40) | (P2-12) | | | | |
| example | compound | compound | 4.8 | 5.0 | 49.5 | 126.9 |
| (91) | (P1-40) | (P2-18) | | | | |
| example | compound | compound | 4.8 | 5.0 | 50.0 | 132.3 |
| (92) | (P1-40) | (P2-21) | | | | |
| example | compound | compound | 4.8 | 5.2 | 48.4 | 127.4 |
| (93) | (P1-40) | (P2-27) | | | | |
| example | compound | compound | 4.8 | 5.0 | 50.4 | 129.5 |
| (94) | (P1-40) | (P2-46) | | | | |

As can be seen from the results of Table 6 and Table 7, when a red or green organic light emitting device was manufactured by using the material for an organic light emitting device of the present invention as a material of the emitting-auxiliary layer, it can be confirmed that the compound of the present invention has an effect on improving the overall performance of the device, and in particular, it can be confirmed that the lifespan is significantly improved, compared to the comparative example.

First, in the case of Comparative Examples 1 to 6, as the second emitting-auxiliary layer, a compound with an amino group bonded to the position 1 of benzofuran or dibenzothiophene was used, and the compound of the present invention is different in that it is composed of a compound represented by Formula 2. To explain in more detail, in the case of the compound represented by Formula 2, it is the same in that it is a compound with an amino group bonded to the position 1 of dibenzofuran or dibenzothiophene. but the difference is in that the dibenzofuran or dibenzothiophene must be substituted with deuterium. When deuterium is substituted in this way, the second emitting-auxiliary layer can be affected by the deterioration phenomenon or exciton occurring in the emitting layer, and the stability against such deterioration phenomenon or exciton is increased by deuterium, resulting in an increase in lifespan. In addition, when an amino group is bonded to position 1 of dibenzofuran or dibenzothiophene, it shows better lifespan than when an amino group is bonded at other positions, in particular, when deuterium is further substituted at position 1 of dibenzofuran or dibenzothiophene, the synergistic effect appears to result in a very remarkable lifespan.

Specifically, as can be seen in Comparative Example 3, if the first emitting-auxiliary layer does not include a compound in which an amino group is bonded to the position 2 of fluorene, the hole transfer characteristics are significantly reduced, which reduces the driving voltage and efficiency of the entire device. Therefore, when an amino group is bonded to the position 2 of fluorene, it can be considered to be very excellent in terms of driving voltage and efficiency.

In conclusion, as described above, a device consisting of a first emitting-auxiliary layer represented by Formula 1 and a second emitting-auxiliary layer represented by Formula 2 shows very excellent characteristics in terms of driving voltage, efficiency, and lifespan, in particular, it can be seen that it is significantly superior in terms of lifespan.

Although exemplary embodiments of the present invention have been described for illustrative purposes, those skilled in the art will appreciate that various modifications, additions and substitutions are possible, without departing from the scope and spirit of the invention as disclosed in the accompanying claims. Therefore, the embodiment disclosed in the present invention is intended to illustrate the scope of the technical idea of the present invention, and the scope of the present invention is not limited by the embodiment. The scope of the present invention shall be construed on the basis of the accompanying claims, and it shall be construed that all of the technical ideas included within the scope equivalent to the claims belong to the present invention.

What is claimed is:

1. An organic electronic element comprising a first electrode; a second electrode; and an organic material layer formed between the first electrode and the second electrode;
wherein the organic material layer comprises: a hole transport layer formed between the first electrode and the emitting layer, and a plurality of emitting-auxiliary layers formed between the hole transport layer and the emitting layer,
wherein the plurality of emitting-auxiliary layers comprises a first emitting-auxiliary layer and a second emitting-auxiliary layer,
wherein the first emitting-auxiliary layer is adjacent to the hole transport layer, and the second emitting-auxiliary layer is adjacent to the emitting layer,
wherein the first emitting-auxiliary layer comprises a compound represented by Formula 1, and the second emitting-auxiliary layer comprises a compound represented by Formula 2: 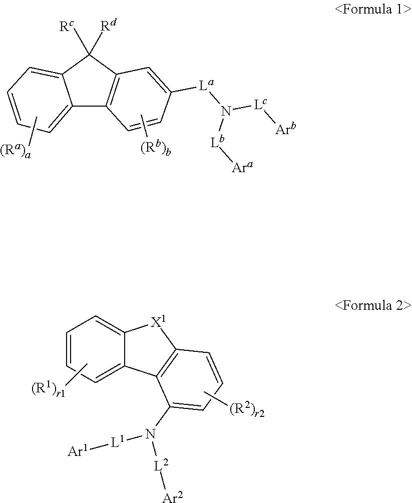
wherein:
R^{a}, R^{b}, R¹ and R² are each independently selected from the group consisting of hydrogen; deuterium; a C₆-C₆₀ aryl group; a fluorenyl group; a C₂-C₆₀ heterocyclic group including at least one heteroatom of O, N, S, Si and P; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group, or an adjacent plurality of R^{a} and a plurality of R^{b} may be bonded to each other to form a ring,
R^{c} and R^{d} are each independently selected from the group consisting of a C₆-C₆₀ aryl group; a fluorenyl group; a C₂-C₆₀ heterocyclic group including at least one heteroatom of O, N, S, Si and P; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group, or R^{c} and R^{d} can be bonded to each other to form a spiro ring,
L^{a}, L^{b}, L^{c}, L¹ and L² are each independently selected from the group consisting of a single bond; a C₆-C₆₀ arylene group; a fluorenylene group; a C₂-C₆₀ heterocyclic group including at least one heteroatom of O, N, S, Si and P; and a fused ring group of a C₃-C₆₀ aliphatic ring and a C₆-C₆₀ aromatic ring,
Ar^{a}, Ar^{b}, Ar¹ and Ar² are each independently selected from the group consisting of a C₆-C₆₀ aryl group; fluorenyl group; a C₂-C₆₀ heterocyclic group including at least one heteroatom of O, N, S, Si and P; a C₃-C₆₀ cycloalkyl group; a fused ring group of a C₃-C₆₀ aliphatic ring and a C₆-C₆₀ aromatic ring; a C₁-C₅₀ alkyl group; a C₂-C₂₀ alkenyl group; a C₂-C₂₀ alkynyl group; a C₁-C₃₀ alkoxyl group; and a C₆-C₃₀ aryloxy group,
X¹ is O or S,
a and r1 are independently an integer of 0 to 4, b and r2 are independently an integer of 0 to 3, wherein r1+r2≥1,
wherein the aryl group, arylene group, heterocyclic group, fluorenyl group, fluorenylene group, cycloalkyl group, fused ring group, alkyl group, alkenyl group, alkynyl group, alkoxy group and aryloxy group may be substituted with one or more substituents selected from the group consisting of deuterium; halogen; a silane group; a siloxane group; a boron group; a germanium group; a cyano group; a nitro group; a C₁-C₂₀ alkylthio group; a C₁-C₂₀ alkoxyl group; a C₁-C₂₀ alkyl group; a C₂-C₂₀ alkenyl group; a C₂-C₂₀ alkynyl group; a C₆-C₂₀ aryl group; a C₆-C₂₀ aryl group substituted with deuterium; a fluorenyl group; a C₂-C₂₀ heterocyclic group; a C₃-C₂₀ cycloalkyl group; a C₇-C₂₀ arylalkyl group; and a C₈-C₂₀ arylalkenyl group, wherein the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof,
with the proviso that Formula 2 comprises at least one deuterium.

2. The organic electronic element according to claim 1, wherein Formula 1 is represented by any of Formulas 1-1 to 1-4: 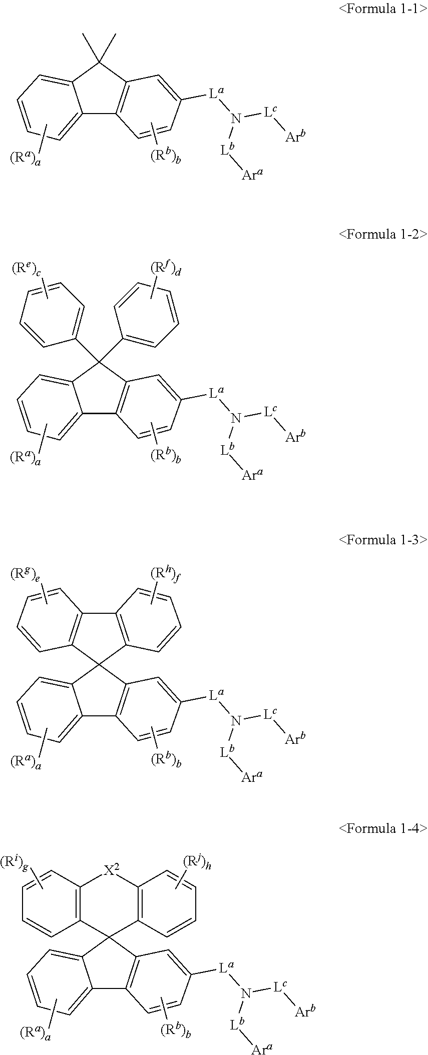
wherein:
R^{a}, R^{b}, a, b, L^{a}, L^{b}, L^{c}, Ar^{a} and Ar^{b} are the same as defined for Formula 1,
R^{e}, R^{f}, R^{g}, R^{h}, Rⁱ and R^{j} are the same as the definition of R^{a} of Formula 1,
X² is O or S,
c and d are independently an integer of 0 to 5, and
e, f, g and h are independently an integer of 0 to 4.

3. The organic electronic element according to claim 1, wherein at least one of R¹ and R² is deuterium or a substituent comprising deuterium.

4. The organic electronic element according to claim 1, wherein the compound of Formula 1 is selected from the following:

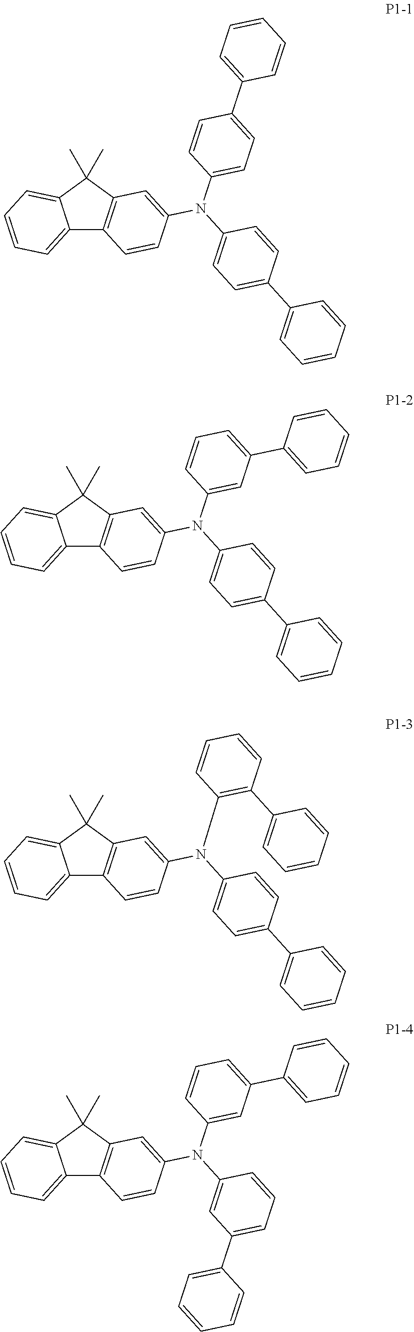

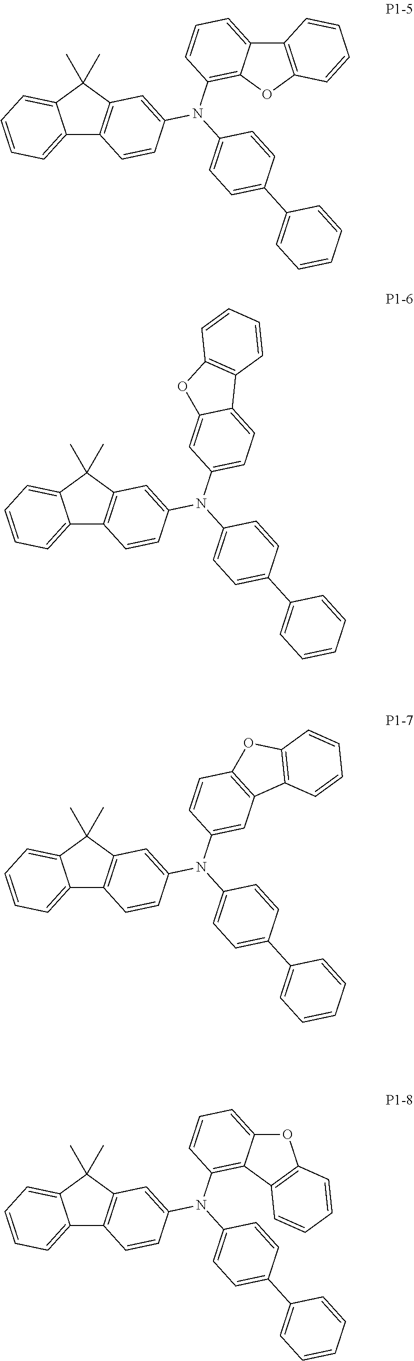 [SMILES: CC1(C)c2ccccc2-c2ccc(N(c3ccc(-c4ccccc4)cc3)c3cccc4c3oc3ccccc34)cc21 ; CC1(C)c2ccccc2-c2ccc(N(c3ccc(-c4ccccc4)cc3)c3ccc4c(c3)oc3ccccc34)cc21 ; CC1(C)c2ccccc2-c2ccc(N(c3ccc(-c4ccccc4)cc3)c3ccc4oc5ccccc5c4c3)cc21 ; CC1(C)c2ccccc2-c2ccc(N(c3ccc(-c4ccccc4)cc3)c3cccc4oc5ccccc5c34)cc21]

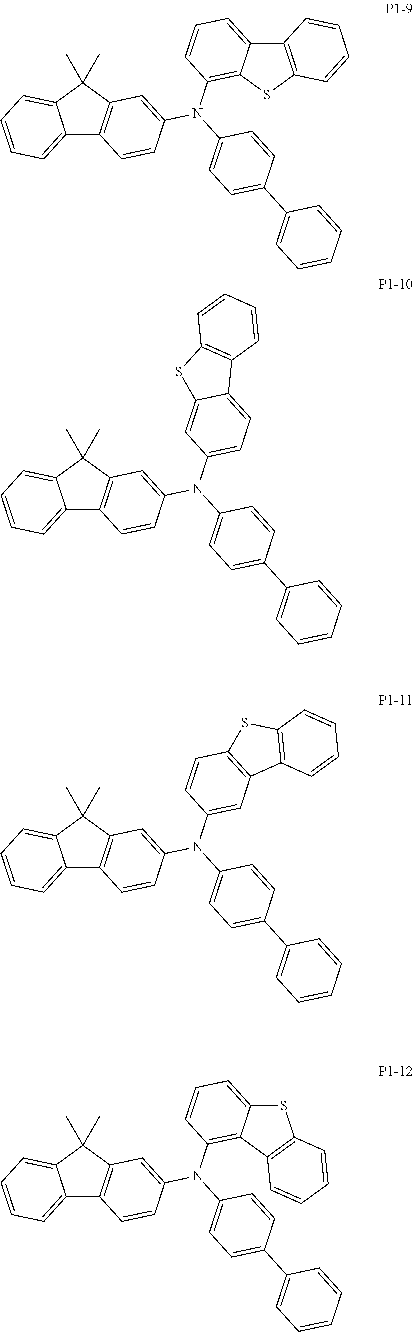 [SMILES: CC1(C)c2ccccc2-c2ccc(N(c3ccc(-c4ccccc4)cc3)c3cccc4c3sc3ccccc34)cc21 ; CC1(C)c2ccccc2-c2ccc(N(c3ccc(-c4ccccc4)cc3)c3ccc4c(c3)sc3ccccc34)cc21 ; CC1(C)c2ccccc2-c2ccc(N(c3ccc(-c4ccccc4)cc3)c3ccc4sc5ccccc5c4c3)cc21 ; CC1(C)c2ccccc2-c2ccc(N(c3ccc(-c4ccccc4)cc3)c3cccc4sc5ccccc5c34)cc21]

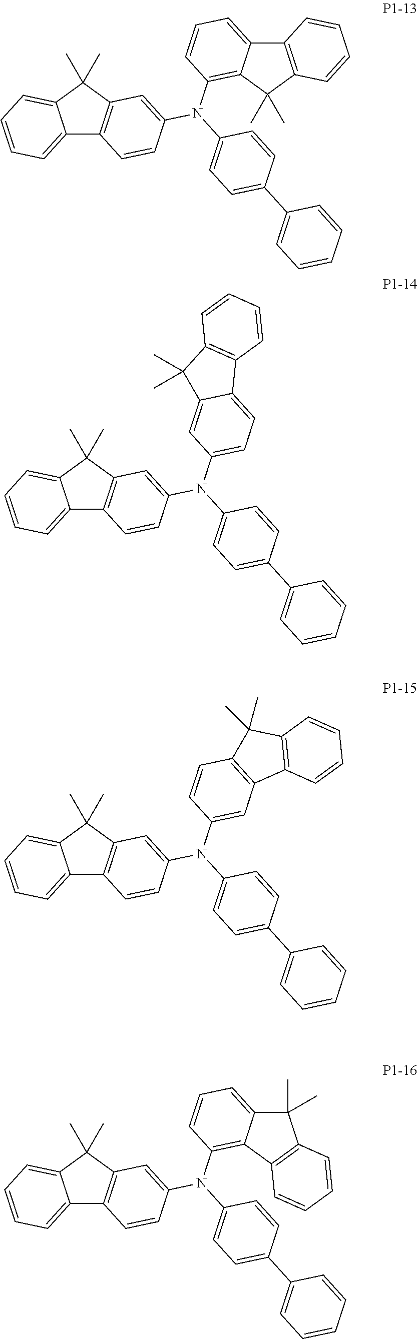 [SMILES: CC1(C)c2ccccc2-c2ccc(N(c3ccc(-c4ccccc4)cc3)c3cccc4c3C(C)(C)c3ccccc3-4)cc21 ; CC1(C)c2ccccc2-c2ccc(N(c3ccc(-c4ccccc4)cc3)c3ccc4c(c3)C(C)(C)c3ccccc3-4)cc21 ; CC1(C)c2ccccc2-c2cc(N(c3ccc(-c4ccccc4)cc3)c3ccc4c(c3)C(C)(C)c3ccccc3-4)ccc21 ; CC1(C)c2ccccc2-c2ccc(N(c3ccc(-c4ccccc4)cc3)c3cccc4c3-c3ccccc3C4(C)C)cc21]

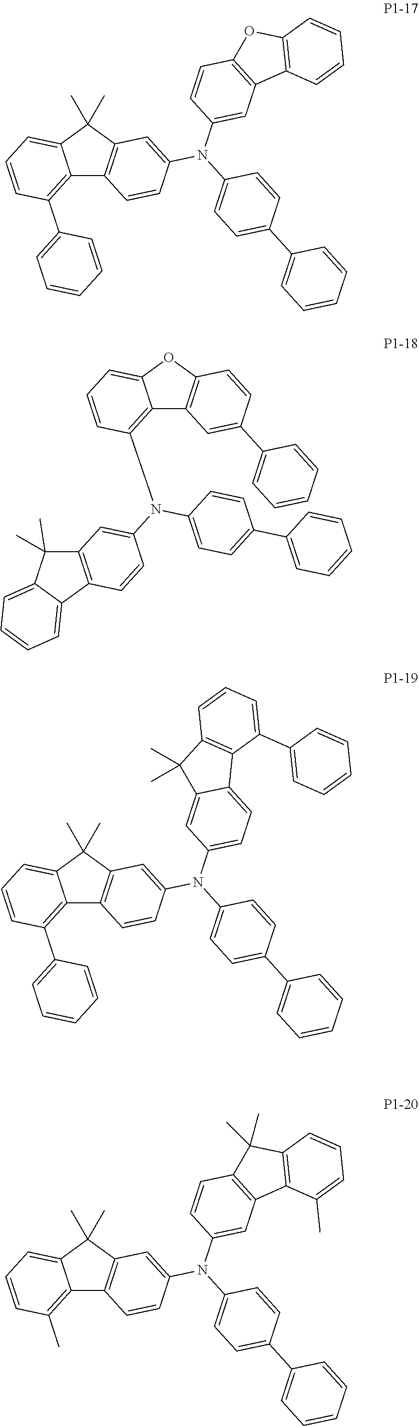 [SMILES: CC1(C)c2cc(N(c3ccc(-c4ccccc4)cc3)c3ccc4oc5ccccc5c4c3)ccc2-c2c(-c3ccccc3)cccc21 ; CC1(C)c2ccccc2-c2ccc(N(c3ccc(-c4ccccc4)cc3)c3cccc4oc5ccc(-c6ccccc6)cc5c34)cc21 ; CC1(C)c2cc(N(c3ccc(-c4ccccc4)cc3)c3ccc4c(c3)C(C)(C)c3cccc(-c5ccccc5)c3-4)ccc2-c2c(-c3ccccc3)cccc21 ; Cc1cccc2c1-c1cc(N(c3ccc(-c4ccccc4)cc3)c3ccc4c(c3)C(C)(C)c3cccc(C)c3-4)ccc1C2(C)C]

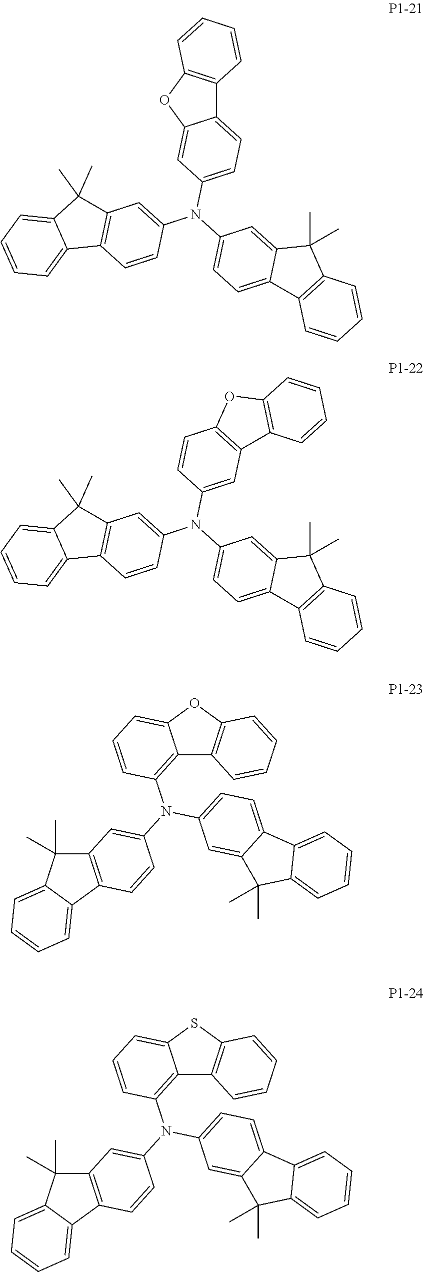 [SMILES: CC1(C)c2ccccc2-c2ccc(N(c3ccc4c(c3)C(C)(C)c3ccccc3-4)c3ccc4c(c3)oc3ccccc34)cc21 ; CC1(C)c2ccccc2-c2ccc(N(c3ccc4c(c3)C(C)(C)c3ccccc3-4)c3ccc4oc5ccccc5c4c3)cc21 ; CC1(C)c2ccccc2-c2ccc(N(c3ccc4c(c3)C(C)(C)c3ccccc3-4)c3cccc4oc5ccccc5c34)cc21 ; CC1(C)c2ccccc2-c2ccc(N(c3ccc4c(c3)C(C)(C)c3ccccc3-4)c3cccc4sc5ccccc5c34)cc21]

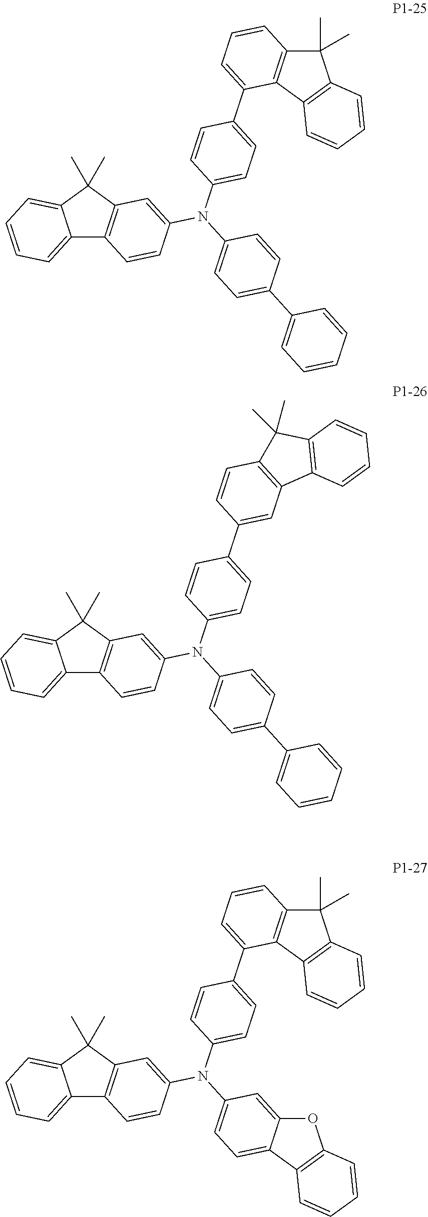

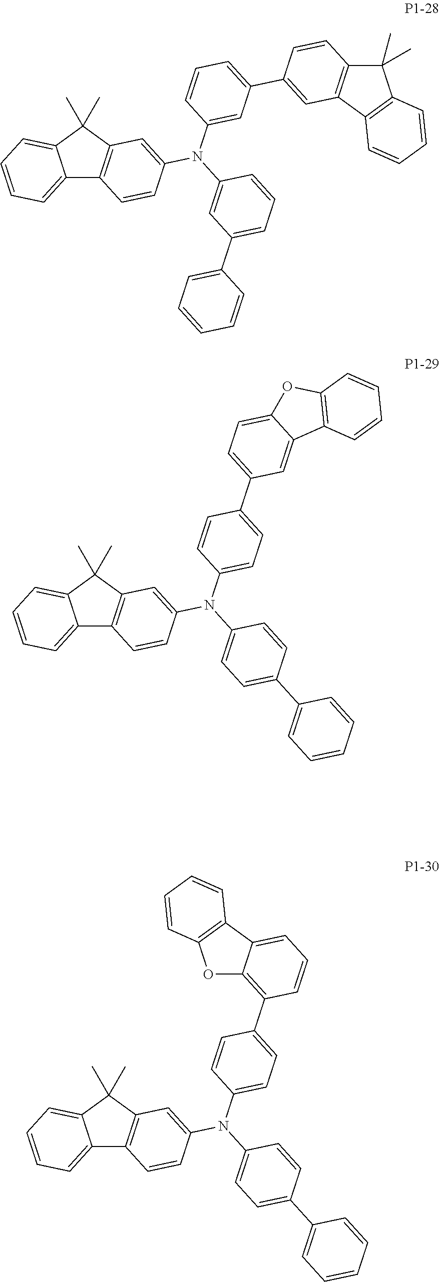 [SMILES: CC1(C)c2ccccc2-c2cc(-c3cccc(N(c4cccc(-c5ccccc5)c4)c4ccc5c(c4)C(C)(C)c4ccccc4-5)c3)ccc21 ; CC1(C)c2ccccc2-c2ccc(N(c3ccc(-c4ccccc4)cc3)c3ccc(-c4ccc5oc6ccccc6c5c4)cc3)cc21 ; CC1(C)c2ccccc2-c2ccc(N(c3ccc(-c4ccccc4)cc3)c3ccc(-c4cccc5c4oc4ccccc45)cc3)cc21]

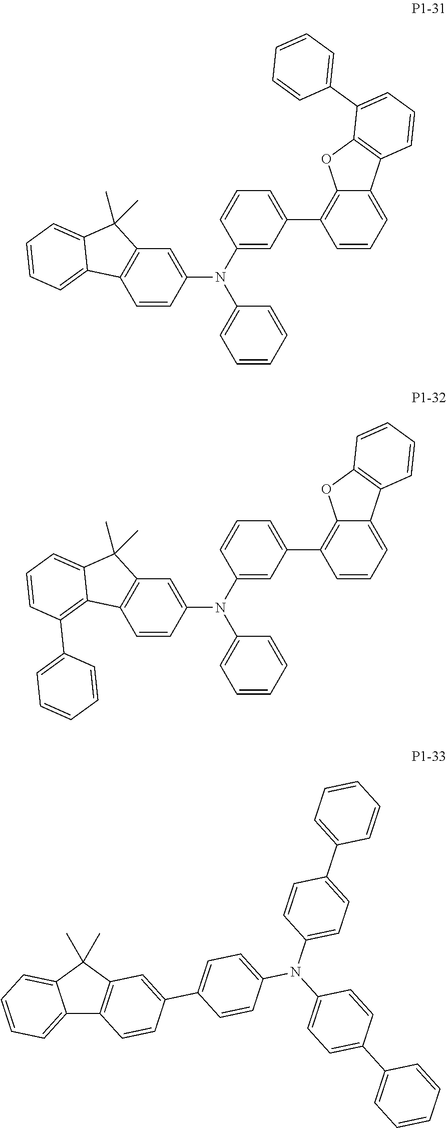 [SMILES: CC1(C)c2ccccc2-c2ccc(N(c3ccccc3)c3cccc(-c4cccc5c4oc4c(-c6ccccc6)cccc45)c3)cc21 ; CC1(C)c2cc(N(c3ccccc3)c3cccc(-c4cccc5c4oc4ccccc45)c3)ccc2-c2c(-c3ccccc3)cccc21 ; CC1(C)c2ccccc2-c2ccc(-c3ccc(N(c4ccc(-c5ccccc5)cc4)c4ccc(-c5ccccc5)cc4)cc3)cc21]

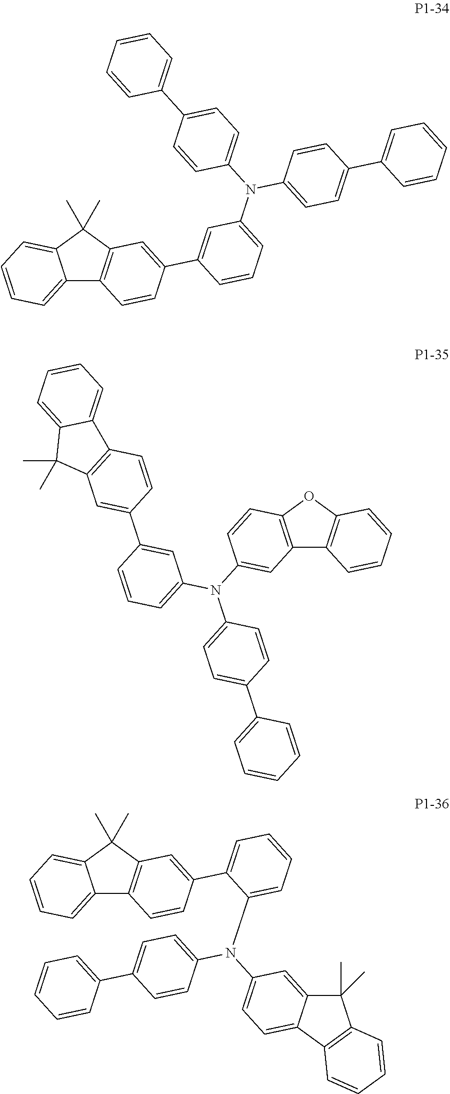 [SMILES: CC1(C)c2ccccc2-c2ccc(-c3cccc(N(c4ccc(-c5ccccc5)cc4)c4ccc(-c5ccccc5)cc4)c3)cc21 ; CC1(C)c2ccccc2-c2ccc(-c3cccc(N(c4ccc(-c5ccccc5)cc4)c4ccc5oc6ccccc6c5c4)c3)cc21 ; CC1(C)c2ccccc2-c2ccc(-c3ccccc3N(c3ccc(-c4ccccc4)cc3)c3ccc4c(c3)C(C)(C)c3ccccc3-4)cc21]

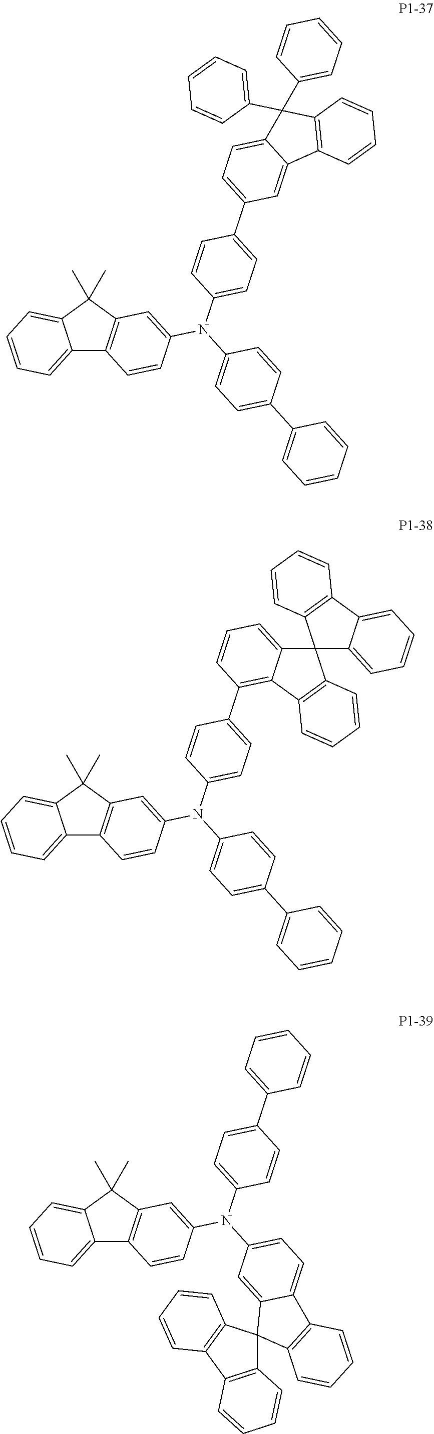 [SMILES: CC1(C)c2ccccc2-c2ccc(N(c3ccc(-c4ccccc4)cc3)c3ccc(-c4ccc5c(c4)-c4ccccc4C5(c4ccccc4)c4ccccc4)cc3)cc21 ; CC1(C)c2ccccc2-c2ccc(N(c3ccc(-c4ccccc4)cc3)c3ccc(-c4cccc5c4-c4ccccc4C54c5ccccc5-c5ccccc54)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

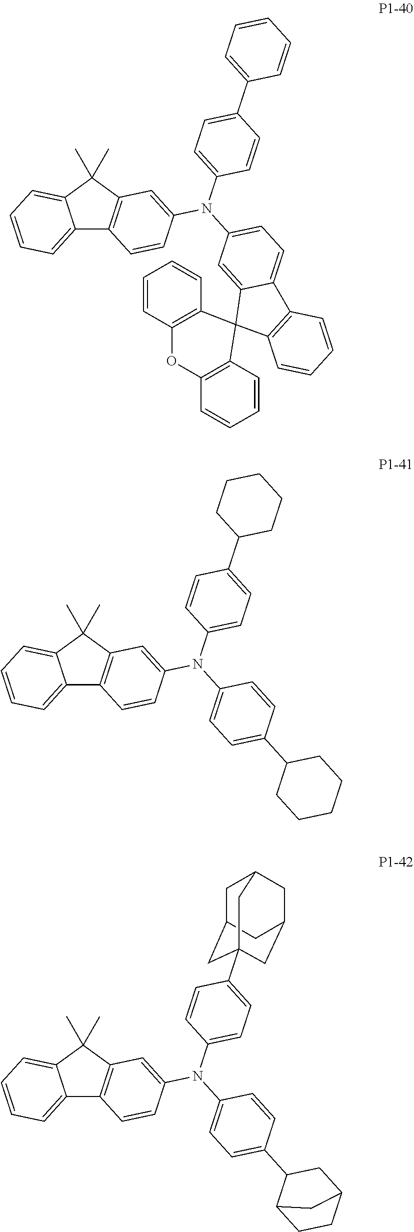 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; CC1(C)c2ccccc2-c2ccc(N(c3ccc(C4CCCCC4)cc3)c3ccc(C4CCCCC4)cc3)cc21 ; CC1(C)c2ccccc2-c2ccc(N(c3ccc(C4CC5CCC4C5)cc3)c3ccc(C45CC6CC(CC(C6)C4)C5)cc3)cc21]

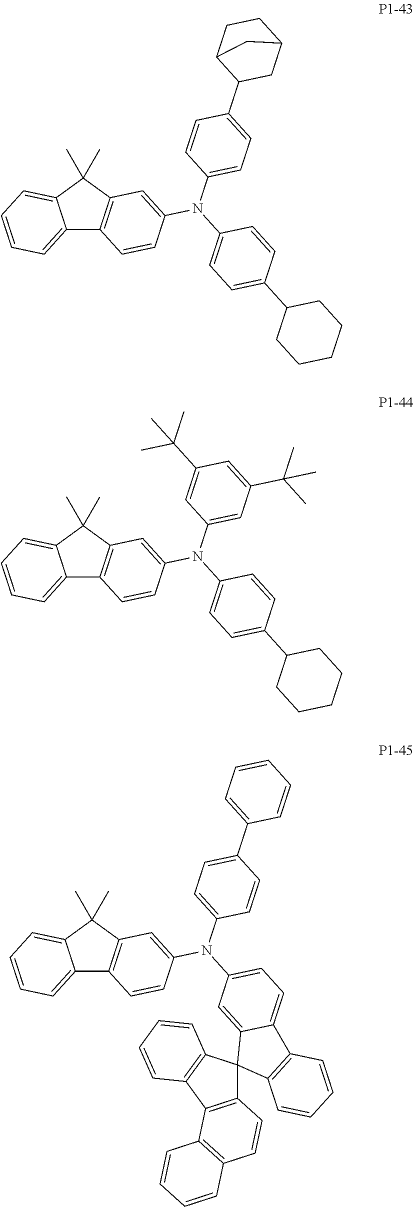 [SMILES: CC1(C)c2ccccc2-c2ccc(N(c3ccc(C4CCCCC4)cc3)c3ccc(C4CC5CCC4C5)cc3)cc21 ; CC(C)(C)c1cc(N(c2ccc(C3CCCCC3)cc2)c2ccc3c(c2)C(C)(C)c2ccccc2-3)cc(C(C)(C)C)c1 ; CC1(C)c2ccccc2-c2ccc(N(c3ccc(-c4ccccc4)cc3)c3ccc4c(c3)C3(c5ccccc5-4)c4ccccc4-c4c3ccc3ccccc43)cc21]

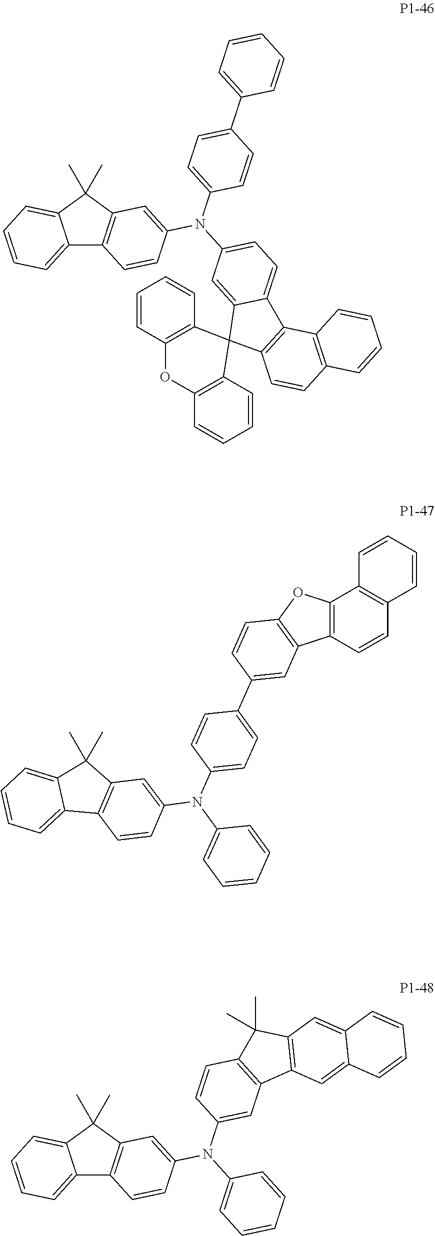 [SMILES: CC1(C)c2ccccc2-c2ccc(N(c3ccc(-c4ccccc4)cc3)c3ccc4c(c3)C3(c5ccccc5Oc5ccccc53)c3ccc5ccccc5c3-4)cc21 ; CC1(C)c2ccccc2-c2ccc(N(c3ccccc3)c3ccc(-c4ccc5oc6c7ccccc7ccc6c5c4)cc3)cc21 ; CC1(C)c2ccccc2-c2ccc(N(c3ccccc3)c3ccc4c(c3)-c3cc5ccccc5cc3C4(C)C)cc21]

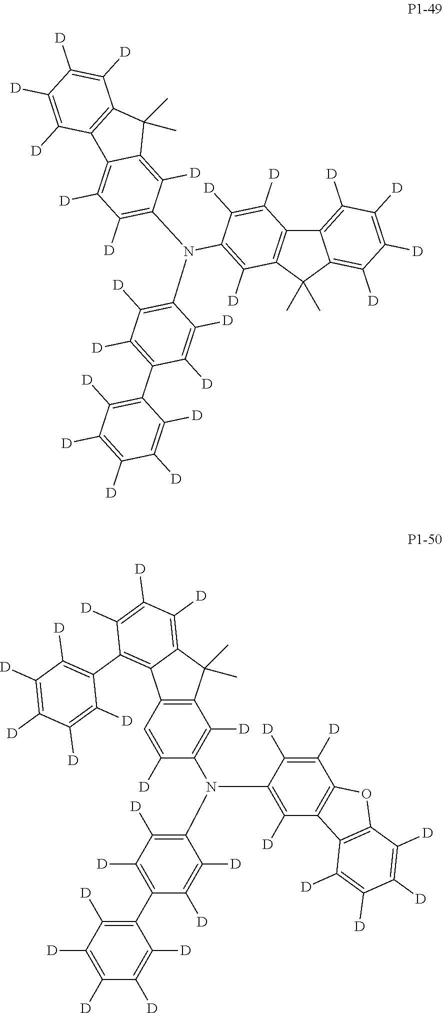 [SMILES: [2H]c1c([2H])c([2H])c(-c2c([2H])c([2H])c(N(c3c([2H])c([2H])c4c(c3[2H])C(C)(C)c3c([2H])c([2H])c([2H])c([2H])c3-4)c3c([2H])c([2H])c4c(c3[2H])C(C)(C)c3c([2H])c([2H])c([2H])c([2H])c3-4)c([2H])c2[2H])c([2H])c1[2H] ; [2H]c1cc2c(c([2H])c1N(c1c([2H])c([2H])c(-c3c([2H])c([2H])c([2H])c([2H])c3[2H])c([2H])c1[2H])c1c([2H])c([2H])c3oc4c([2H])c([2H])c([2H])c([2H])c4c3c1[2H])C(C)(C)c1c([2H])c([2H])c([2H])c(-c3c([2H])c([2H])c([2H])c([2H])c3[2H])c1-2]

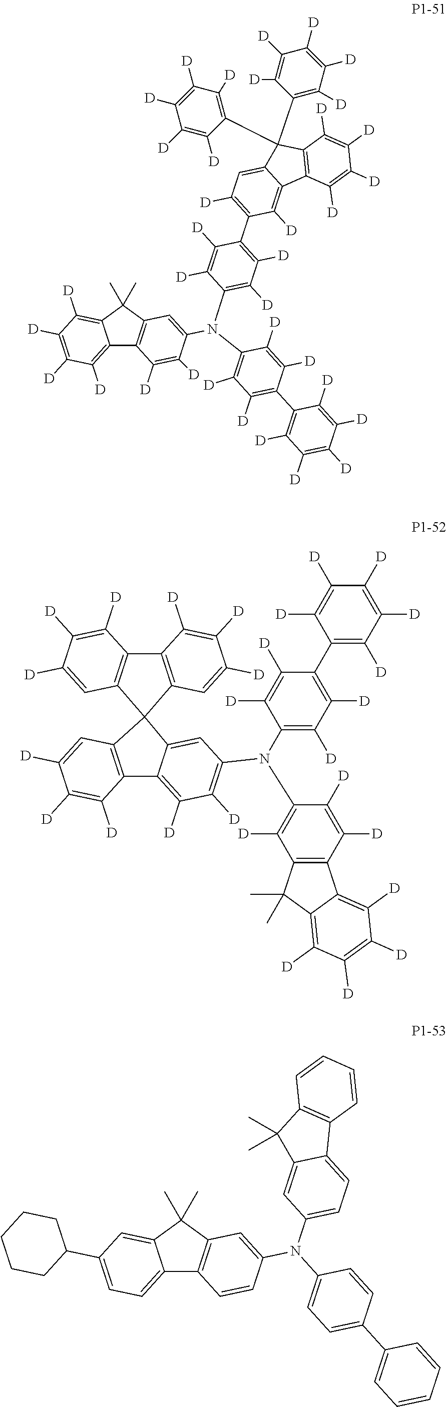

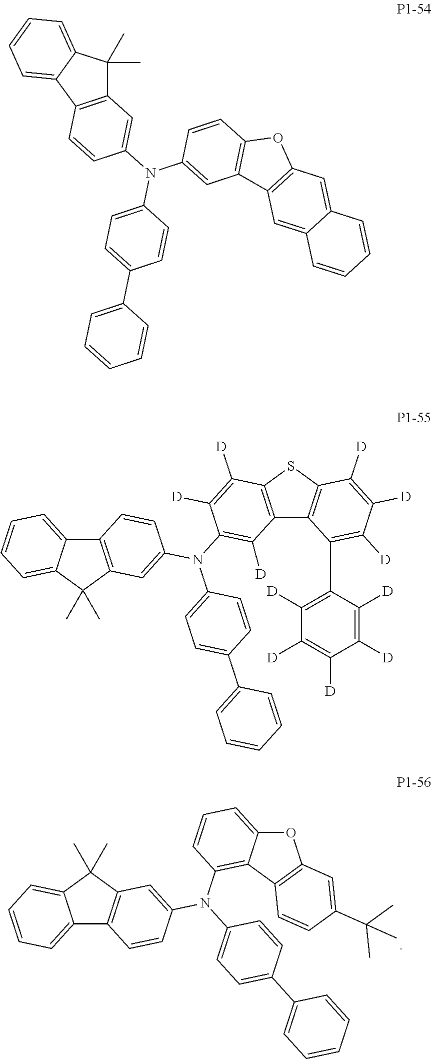 [SMILES: CC1(C)c2ccccc2-c2ccc(N(c3ccc(-c4ccccc4)cc3)c3ccc4oc5cc6ccccc6cc5c4c3)cc21 ; [2H]c1c([2H])c([2H])c(-c2c([2H])c([2H])c([2H])c3sc4c([2H])c([2H])c(N(c5ccc(-c6ccccc6)cc5)c5ccc6c(c5)C(C)(C)c5ccccc5-6)c([2H])c4c23)c([2H])c1[2H] ; CC(C)(C)c1ccc2c(c1)oc1cccc(N(c3ccc(-c4ccccc4)cc3)c3ccc4c(c3)C(C)(C)c3ccccc3-4)c12]

5. The organic electronic element according to claim 1, wherein the compound of Formula 2 is selected from the following compounds:

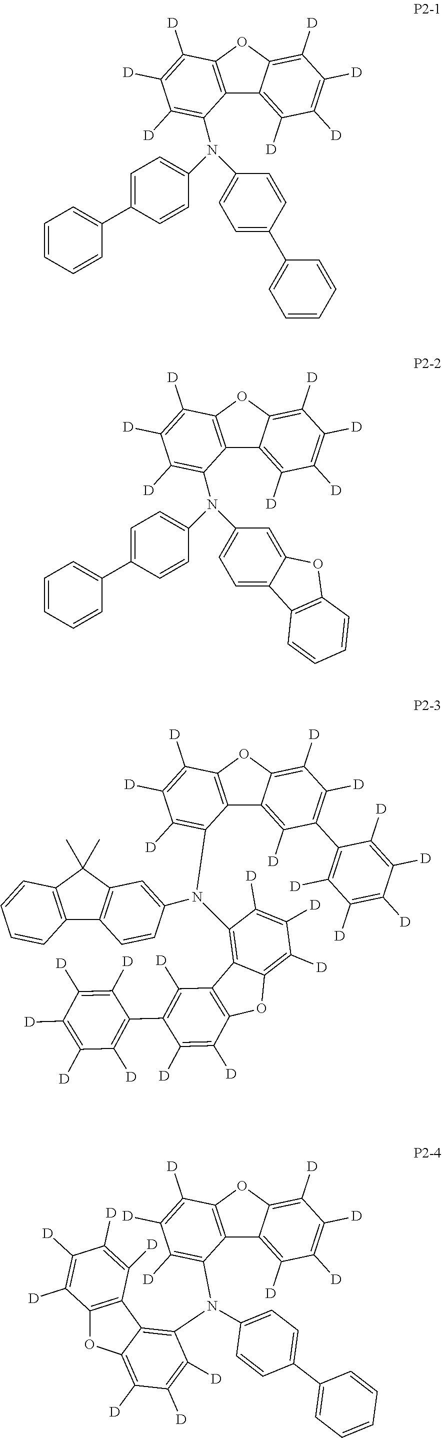

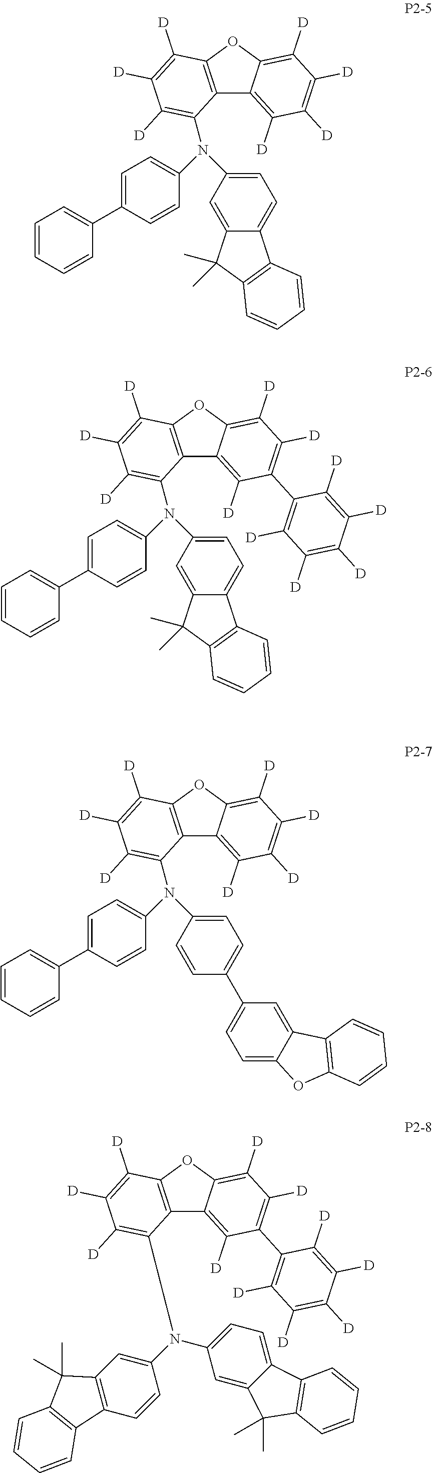

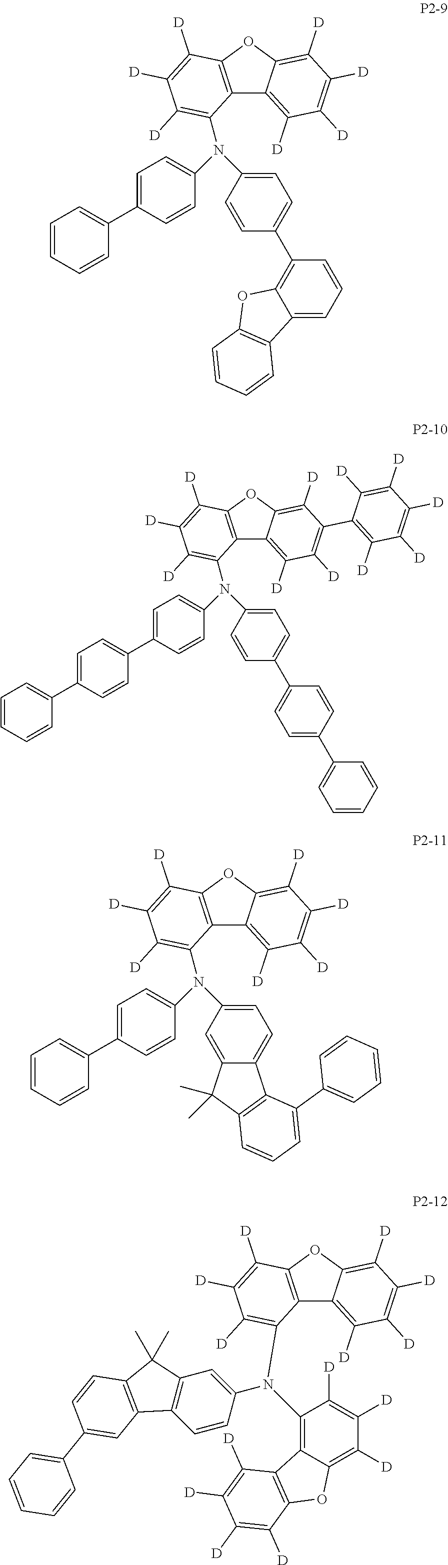

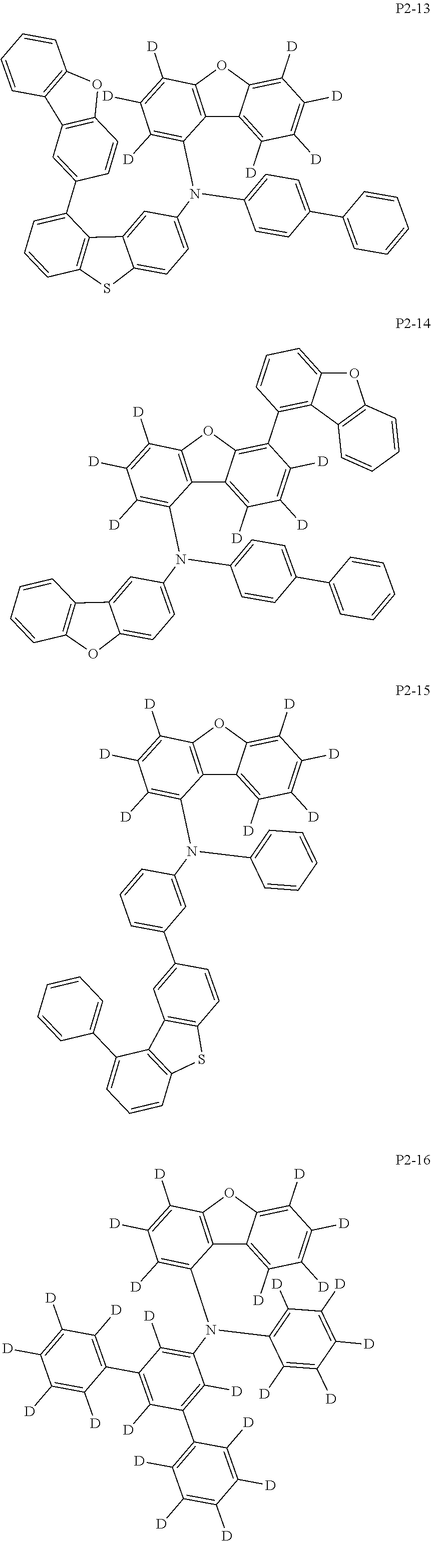

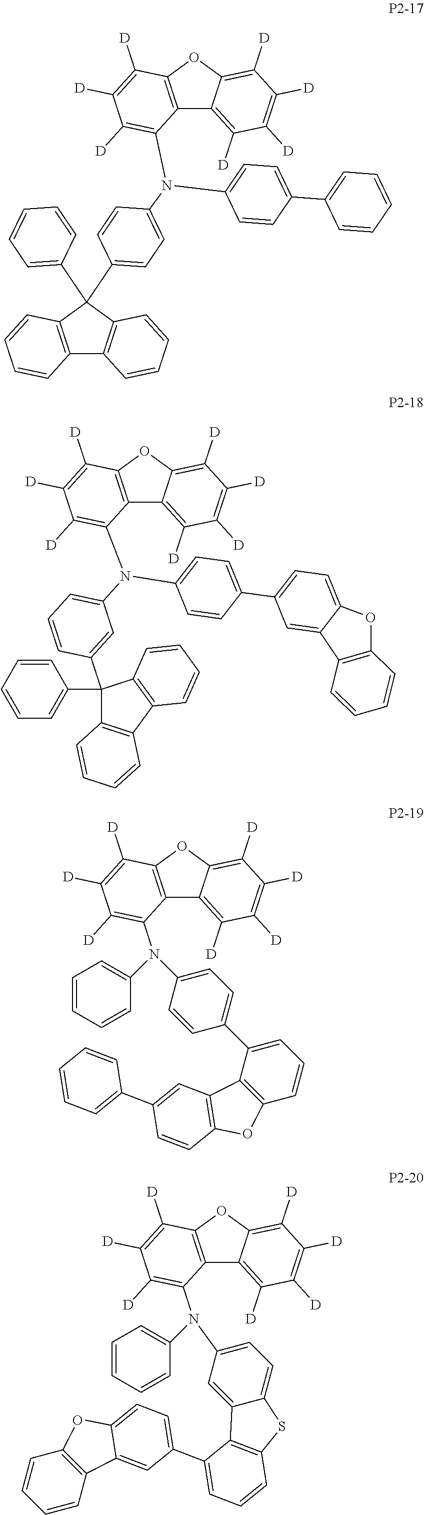

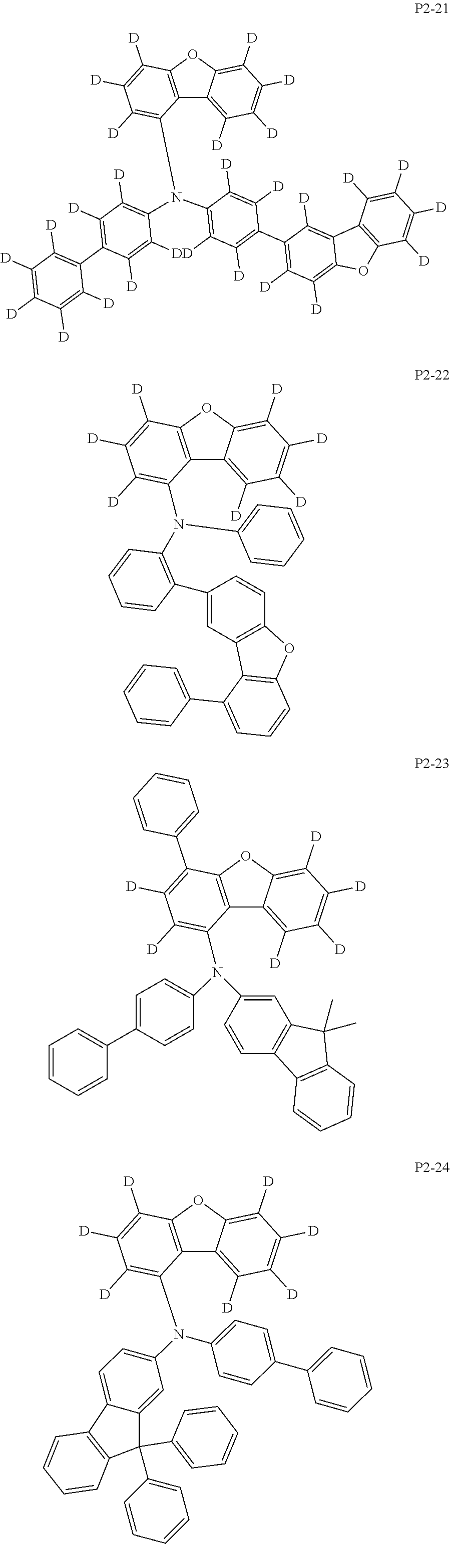

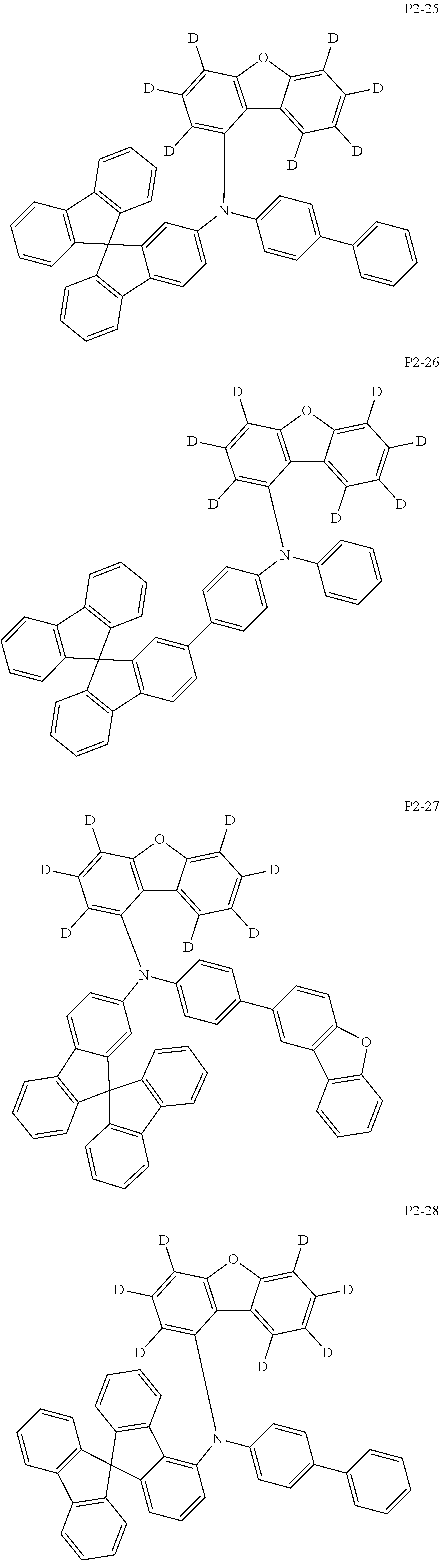

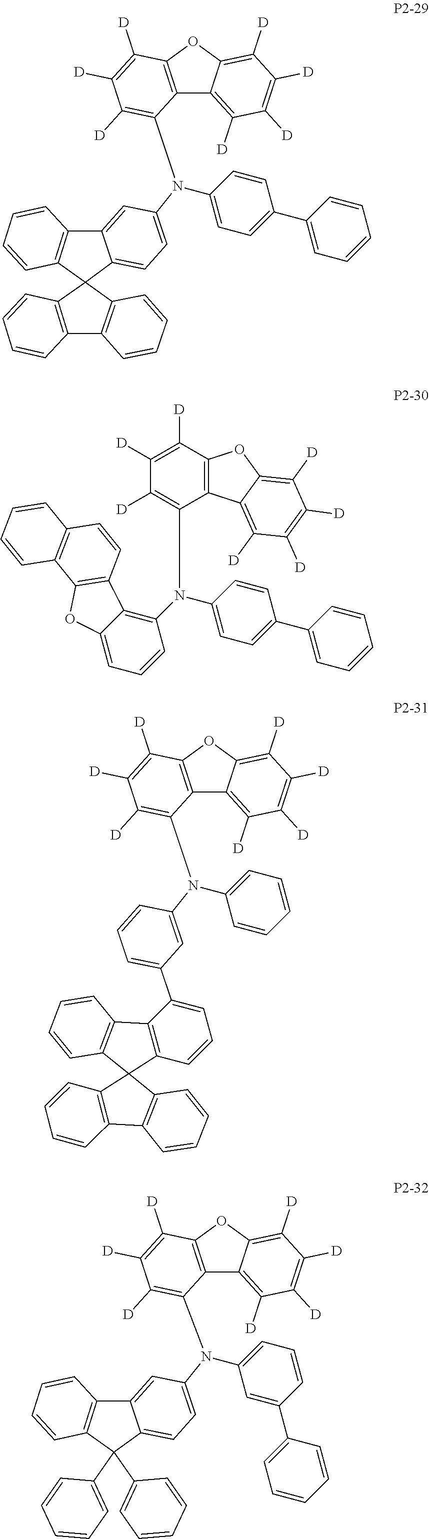 [SMILES: [2H]c1c([2H])c([2H])c2c(oc3c([2H])c([2H])c([2H])c(N(c4ccc(-c5ccccc5)cc4)c4ccc5c(c4)-c4ccccc4C54c5ccccc5-c5ccccc54)c32)c1[2H] ; [2H]c1c([2H])c([2H])c2c(oc3c([2H])c([2H])c([2H])c(N(c4ccc(-c5ccccc5)cc4)c4cccc5oc6c7ccccc7ccc6c45)c32)c1[2H] ; [2H]c1c([2H])c([2H])c2c(oc3c([2H])c([2H])c([2H])c(N(c4ccccc4)c4cccc(-c5cccc6c5-c5ccccc5C65c6ccccc6-c6ccccc65)c4)c32)c1[2H] ; [2H]c1c([2H])c([2H])c2c(oc3c([2H])c([2H])c([2H])c(N(c4cccc(-c5ccccc5)c4)c4ccc5c(c4)-c4ccccc4C5(c4ccccc4)c4ccccc4)c32)c1[2H]]

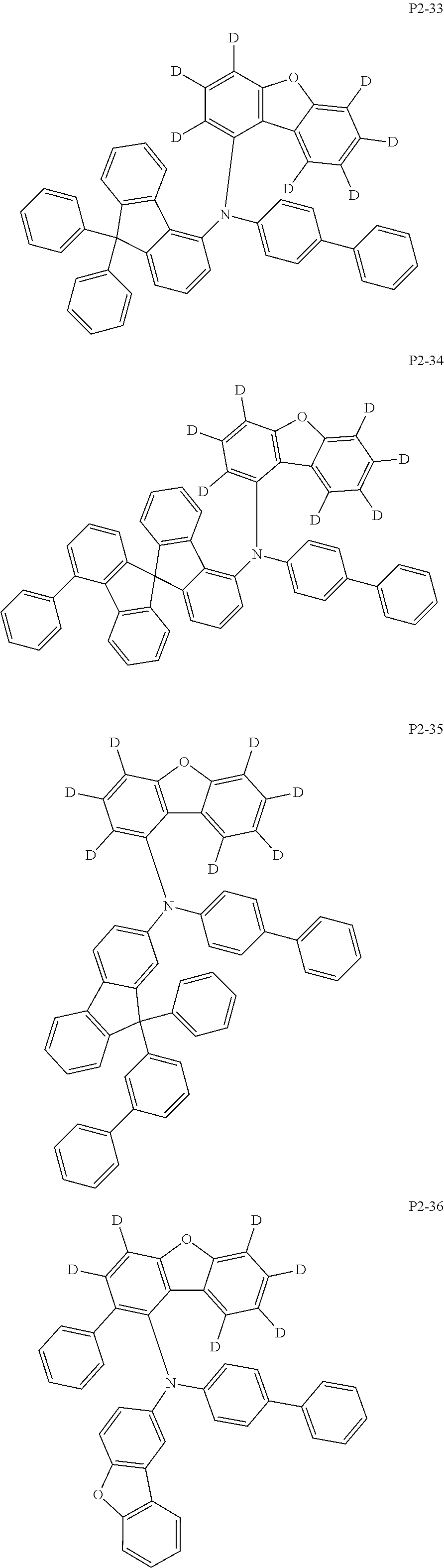

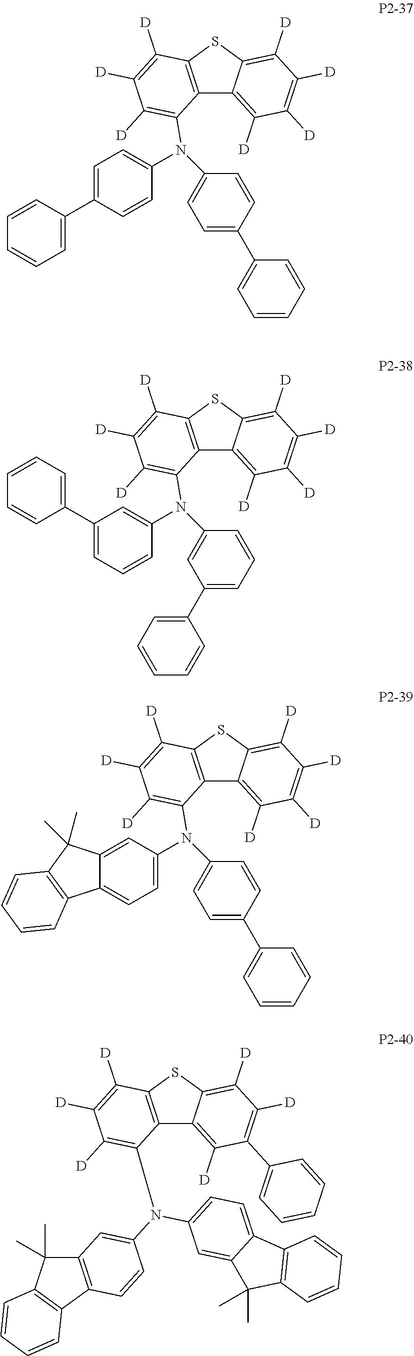

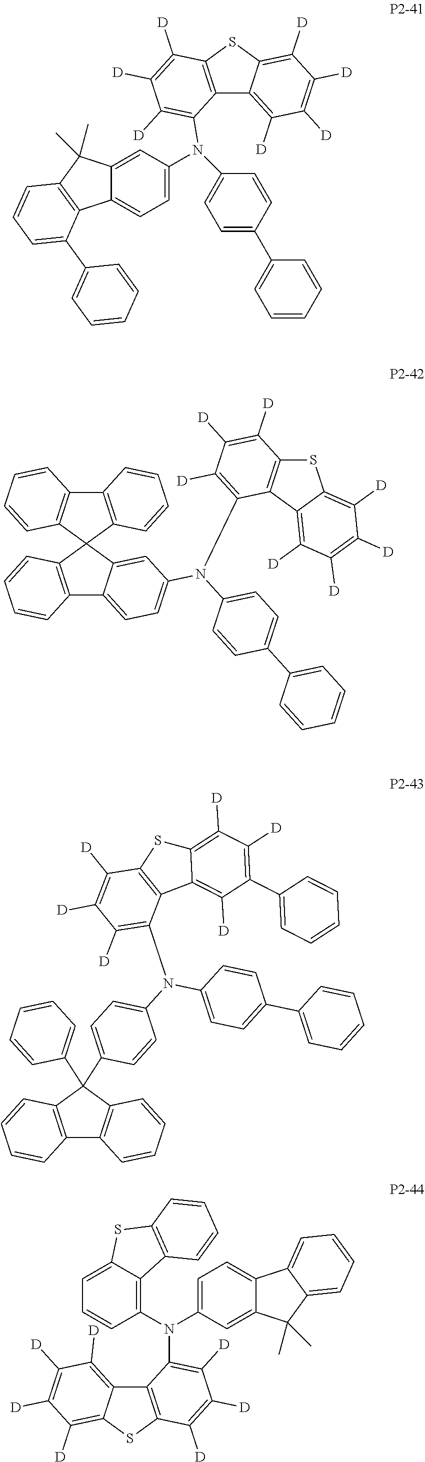 [SMILES: [2H]c1c([2H])c([2H])c2c(sc3c([2H])c([2H])c([2H])c(N(c4ccc(-c5ccccc5)cc4)c4ccc5c(c4)C(C)(C)c4cccc(-c6ccccc6)c4-5)c32)c1[2H] ; [2H]c1c([2H])c([2H])c2c(sc3c([2H])c([2H])c([2H])c(N(c4ccc(-c5ccccc5)cc4)c4ccc5c(c4)C4(c6ccccc6-c6ccccc64)c4ccccc4-5)c32)c1[2H] ; [2H]c1c(-c2ccccc2)c([2H])c2c(sc3c([2H])c([2H])c([2H])c(N(c4ccc(-c5ccccc5)cc4)c4ccc(C5(c6ccccc6)c6ccccc6-c6ccccc65)cc4)c32)c1[2H] ; [2H]c1c([2H])c([2H])c2c(sc3c([2H])c([2H])c([2H])c(N(c4ccc5c(c4)C(C)(C)c4ccccc4-5)c4cccc5sc6ccccc6c45)c32)c1[2H]]

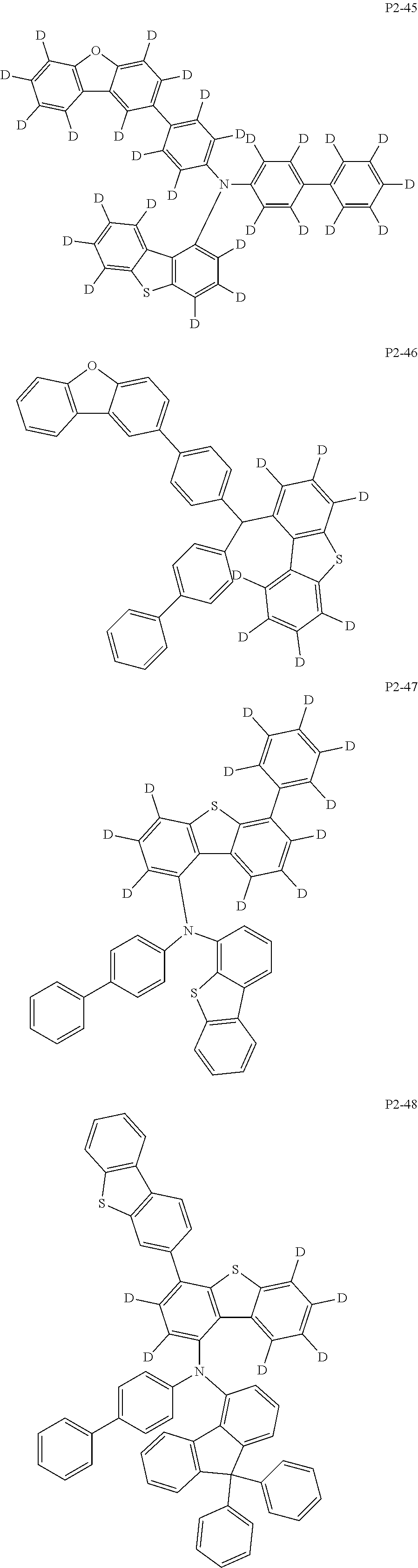

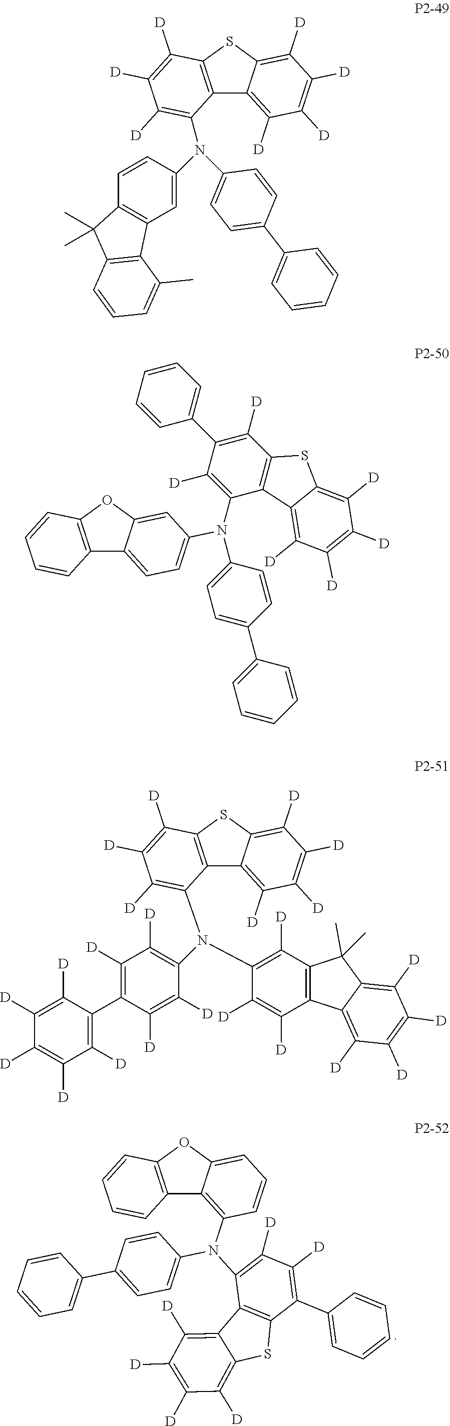

6. The organic electronic element according to claim 1, further comprising a light efficiency enhancing layer formed on at least one surface of the first electrode and the second electrode, the surface being opposite to the organic material layer.

7. The organic electronic element of claim 1, wherein the organic material layer comprises 2 or more stacks comprising a hole transport layer, an emitting layer and an electron transport layer sequentially formed on the first electrode.

8. The organic electronic element of claim 7, wherein the organic material layer further comprise a charge generation layer formed between the 2 or more stacks.

9. An electronic device comprising a display device comprising the organic electronic element of claim 1; and a control unit for driving the display device.

10. An electronic device according to claim 9, wherein the organic electronic element is at least one of an OLED, an organic solar cell, an organic photo conductor (OPC), organic transistor (organic TFT) and an element for monochromic or white illumination.
